(19) United States
(12) Patent Application Publication
(10) Pub. No.: US 2020/0066995 A1
(43) Pub. Date: Feb. 27, 2020

(54) ORGANIC LIGHT-EMITTING DEVICE

(71) Applicants: Samsung Electronics Co., Ltd., Suwon-si (KR); Samsung SDI Co., Ltd., Yongin-si (KR)

(72) Inventors: Sooghang IHN, Hwaseong-si (KR); Soonok JEON, Suwon-si (KR); Yeonsook CHUNG, Seoul (KR); Hosuk KANG, Suwon-si (KR); Hasup LEE, Seoul (KR); Sunghan KIM, Seongnam-si (KR); Wook KIM, Suwon-si (KR); Myungsun SIM, Suwon-si (KR)

(21) Appl. No.: 16/415,614

(22) Filed: May 17, 2019

(30) Foreign Application Priority Data
Aug. 23, 2018 (KR) 10-2018-0098764

(51) Int. Cl. H01L 51/00

(52) U.S. Cl. CPC H01L 51/0072; H01L 51/0052; H01L 51/5016; H01L 51/0067; H01L 51/0073

(57) ABSTRACT

An organic light-emitting device comprising: a first electrode; a second electrode facing the first electrode; and an organic layer disposed between the first electrode and the second electrode, wherein the organic layer comprises an emission layer, the emission layer comprises a thermally activated delayed fluorescence emitter and a host, the emission layer does not comprise a phosphorescence emitter, and the thermally activated delayed fluorescence emitter comprises a compound represented by Formula 1:

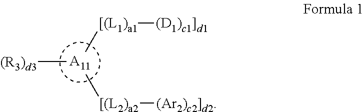

### CROSS-REFERENCE TO RELATED APPLICATION

This application claims priority to Korean Patent Application No. 10-2018-0098764, filed on Aug. 23, 2018, in the Korean Intellectual Property Office, and all the benefits accruing therefrom under 35 U.S.C. § 119, the contents of which in their entirety are herein incorporated by reference.

### BACKGROUND

### 1. Field

One or more embodiments relate to an organic light-emitting device.

### 2. Description of the Related Art

Organic light-emitting devices are self-emission devices that produce full-color images, and also have wide viewing angles, high contrast ratios, short response times, and excellent characteristics in terms of brightness, driving voltage, and response speed, compared to devices in the art.

In an example, an organic light-emitting device includes an anode, a cathode, and an organic layer that is disposed between the anode and the cathode and includes an emission layer. A hole transport region may be between the anode and the emission layer, and an electron transport region may be between the emission layer and the cathode. Holes provided from the anode may move toward the emission layer through the hole transport region, and electrons provided from the cathode may move toward the emission layer through the electron transport region. Carriers, such as holes and electrons, recombine in an emission layer region to produce excitons. These excitons transit from an excited state to a ground state, thereby generating light.

### SUMMARY

Aspects of the present disclosure provide an organic light-emitting device having high efficiency and a long lifespan.

Additional aspects will be set forth in part in the description which follows and, in part, will be apparent from the description, or may be learned by practice of the presented embodiments.

An aspect of the present disclosure provides an organic light-emitting device including a first electrode, a second electrode facing the first electrode, and an organic layer disposed between the first electrode and the second electrode,
wherein the organic layer comprises an emission layer,
the emission layer comprises a thermally activated delayed fluorescence emitter and a host,
the emission layer does not comprise a phosphorescence emitter, and the thermally activated delayed fluorescence emitter comprises a compound represented by Formula 1:

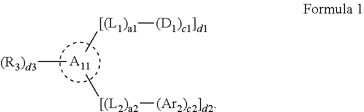

### In Formula 1,

ring A₁₁ is a pyridine group, a pyrimidine group, a pyrazine group, a pyridazine group, a triazine group, or a tetrazine group,
L₁ and L₂ are each independently be:
a single bond; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₀₁)(Q₁₀₂)(Q₁₀₃), or a combination thereof,
a1 and a2 are each independently an integer from 1 to 5,
D₁ is a hole-transporting group,
Ar₂ is a dibenzofuran group, a dibenzothiophene group, or a biphenyl group, each unsubstituted or substituted with at least one R₁₀,
c1 and c2 are each independently an integer from 1 to 5,
R₃ and R₁₀ are each independently:
a hydrogen, a deuterium, a C₁-C₂₀ alkyl group, or a C₁-C₂₀ alkoxy group; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₁₁)(Q₁₁₂)(O₁₁₃), or a combination thereof,
d₁ to d₃ are each independently an integer from 1 to 4, and
Q₁₀₁ to Q₁₀₃ and Q₁₁₁ to Q₁₁₃ are each independently a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

### BRIEF DESCRIPTION OF THE DRAWING

These and/or other aspects will become apparent and more readily appreciated from the following description of the embodiments, taken in conjunction with the FIGURE, which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

An organic light-emitting device according to an embodiment may include a first electrode, a second electrode facing the first electrode, and an organic layer disposed between the first electrode and the second electrode, wherein the organic layer may include an emission layer. The emission layer may include a thermally activated delayed fluorescence emitter and a host.

The emission layer may not include a phosphorescence emitter. That is, the emission layer may not include a compound capable of emitting light due to a phosphorescence emission mechanism.

In one embodiment, the emission layer is a fluorescence emission layer that emits delayed fluorescence from the thermally activated delayed fluorescence emitter, which is distinctly different from a phosphorescence emission layer that emits phosphorescence from a phosphorescence emitter (for example, a transition metal-containing organometallic compound) included therein.

The thermally activated delayed fluorescence emitter may include a compound represented by Formula 1:

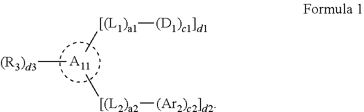

In Formula 1, ring A₁₁ may be a pyridine group, a pyrimidine group, a pyrazine group, a pyridazine group, a triazine group, or a tetrazine group.

In an exemplary embodiment, ring A₁₁ in Formula 1 may be a triazine group, but embodiments of the present disclosure are not limited thereto.

In Formula 1, L₁ and L₂ may each independently be:
a single bond; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₀₁)(Q₁₀₂)(Q₁₀₃), or a combination thereof, and Q₁₀₁ to Q₁₀₃ are each independently the same as described above.

In an exemplary embodiment, L₁ and L₂ may each independently be:
a single bond; or
a benzene group, a fluorene group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, an acridine group, or a dihydroacridine group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, but embodiments of the present disclosure are not limited thereto.

In one embodiment, L₁ and L₂ may each independently be a single bond or groups represented by Formulae 2-1 to 2-9.

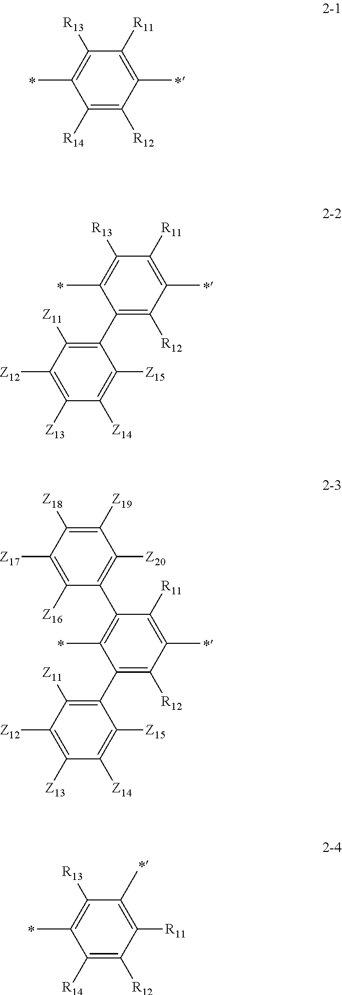

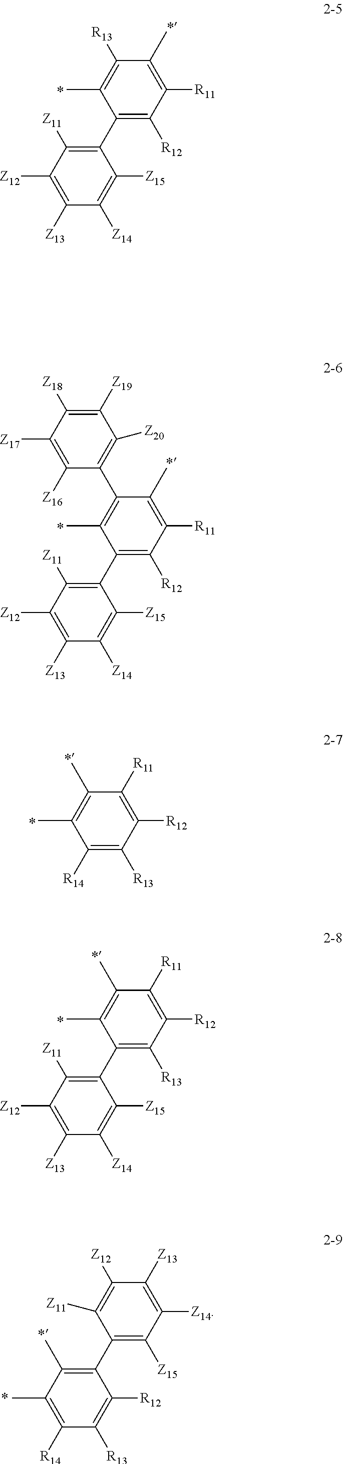

### In Formulae 2-1 to 2-9,

R₁₁ to R₁₄ may each independently be a hydrogen, a deuterium, a C₁-C₁₀ alkyl group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, or a (C₁-C₁₀ alkyl)phenyl group, Z₁₁ to Z₂₀ may each independently be a hydrogen, a C₁-C₁₀ alkyl group, a phenyl group, a biphenyl group, or a terphenyl group,
* indicates a binding site to D₁ or Ar₂ in Formula 1, and
** indicates a binding site to ring A₁₁ in Formula 1.

In Formula 1, a1 and a2 each indicate the number of L₁ and the number of L₂, respectively, and may each independently be an integer from 1 to 5. When a1 is 2 or greater, a plurality of L₁ may be identical to or different from each other, and when a2 is 2 or greater, a plurality of L₂ may be identical to or different from each other. In an exemplary embodiment, a1 and a2 may each independently be 1 or 2.

In Formula 1, D₁ may be a hole-transporting group. In an exemplary embodiment, D₁ in Formula 1 may be a nitrogen-containing hole-transporting group.

In one embodiment, D₁ in Formula 1 may be a nitrogen-containing hole-transporting group, wherein N in D₁ and C in ring A₁₁ may be linked to each other via a single bond, or N in D₁ and C in L₁ may be linked to each other via a single bond.

In one embodiment, D₁ in Formula 1 may be a group represented by Formula 3-1:

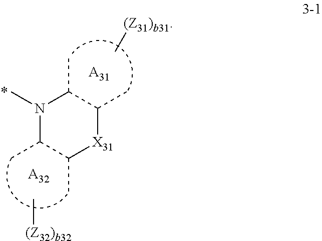

In Formula 3-1, ring A₃₁ and ring A₃₂ may each independently be a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group.

In an exemplary embodiment, ring A₃₁ and ring A₃₂ may each independently be a benzene group, a carbazole group, a dibenzofuran group, or a dibenzothiophene group.

In one embodiment, ring A₃₁, ring A₃₂, or a combination thereof may be a benzene group.

In Formula 3-1, X₃₁ may be a single bond, N(Z₃₃), C(Z₃₄)(Z₃₅), O, or S. In an exemplary embodiment, X₃₁ may be a single bond, but embodiments of the present disclosure are not limited thereto.

In Formula 3-1, Z₃₁ to Z₃₅ may each independently be:
a hydrogen, a deuterium, a C₁-C₂₀ alkyl group, or a C₁-C₂₀ alkoxy group; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₂₁)(Q₁₂₂)(Q₁₂₃), or a combination thereof.

In an exemplary embodiment, Z₃₁ to Z₃₅ may each independently be:
a hydrogen, a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, but embodiments of the present disclosure are not limited thereto.

In Formula 3-1, b31 and b32 each indicate the number of Z₃₁ and the number of Z₃₂, respectively, and may each independently be 1, 2, 3, or 4. When b31 is 2 or greater, a plurality of Z₃₁ may be identical to or different from each other, and when b32 is 2 or greater, a plurality of Z₃₂ may be identical to or different from each other. In an exemplary embodiment, b31 and b32 may each independently be 1 or 2.

Q₁₂₁ to Q₁₂₃ may each independently be a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

In Formula 3-1, * indicates a binding site to L₁ or ring A₁₁ in Formula 1.

In one embodiment, D₁ in Formula 1 may be a group represented by Formulae 3-1(1) to 3-1(3):

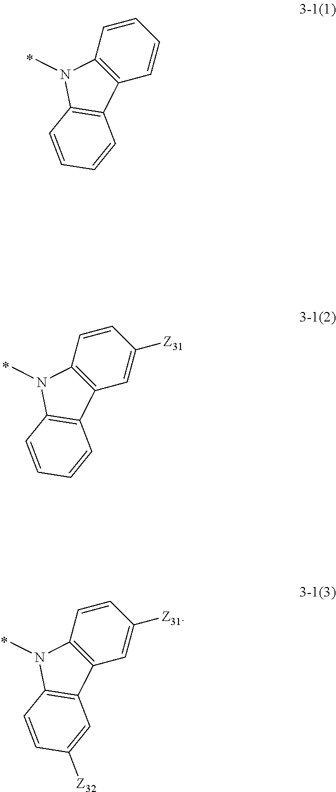

In Formulae 3-1(1) to 3-1(3), Z₃₁ and Z₃₂ may each independently be:
a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, and
* indicates a binding site to L₁ or ring A₁₁ in Formula 1.

In Formula 1, Ar₂ may be a dibenzofuran group, a dibenzothiophene group, or a biphenyl group, each unsubstituted or substituted with at least one R₁₀, wherein R₁₀ is the same as described above.

In one embodiment, Ar₂ in Formula 1 may be a group represented by Formulae 4-1 to 4-31:

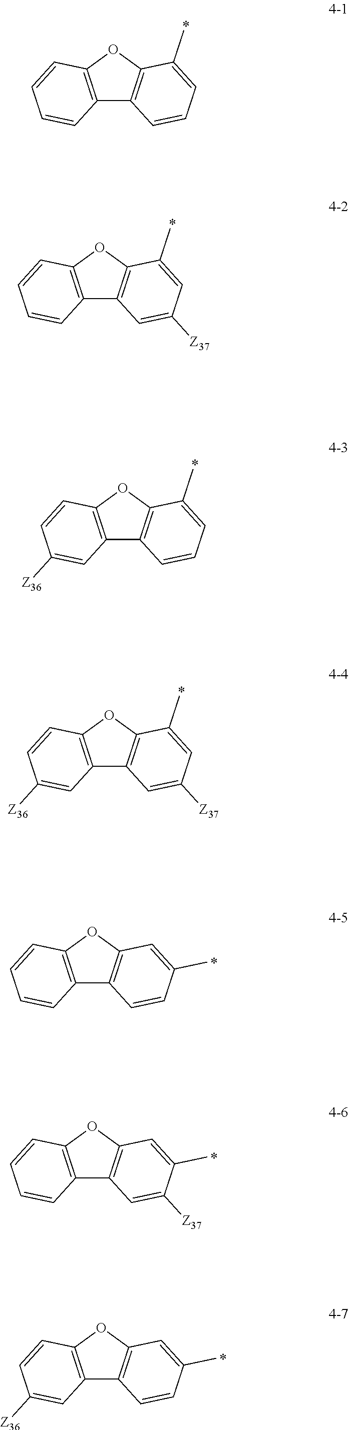

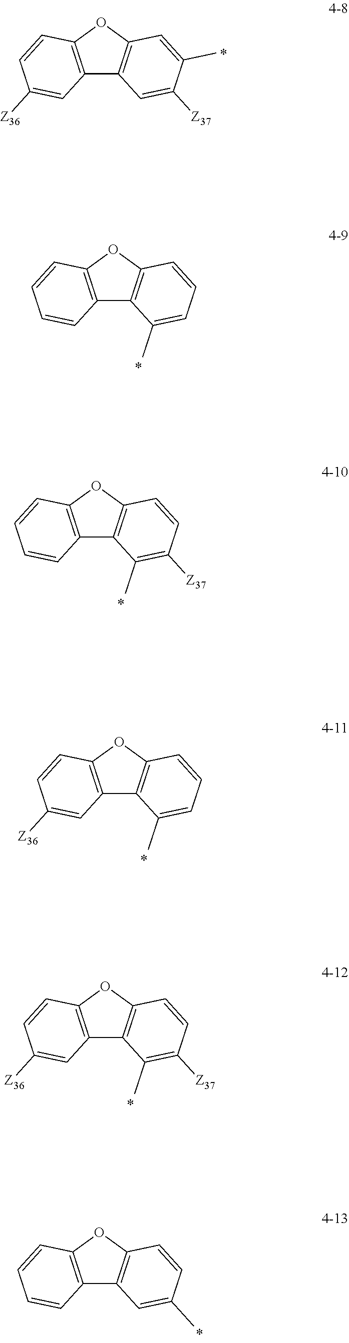

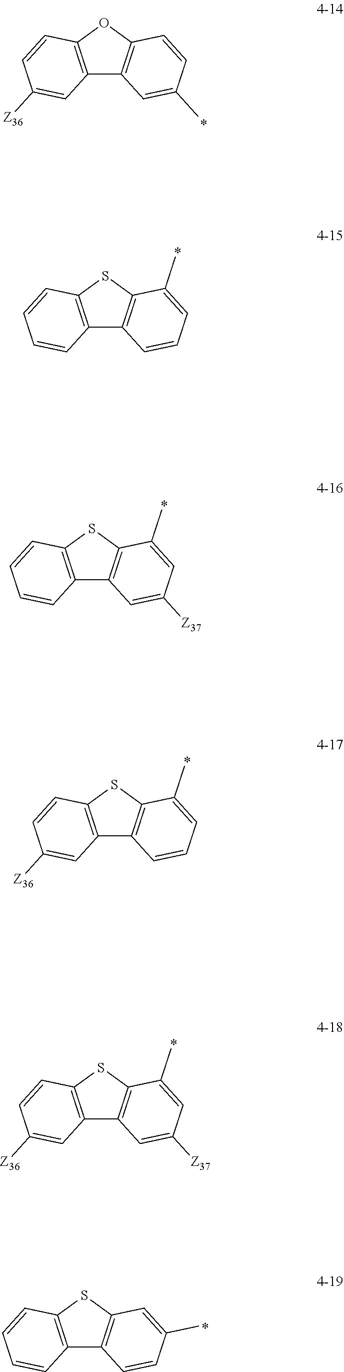

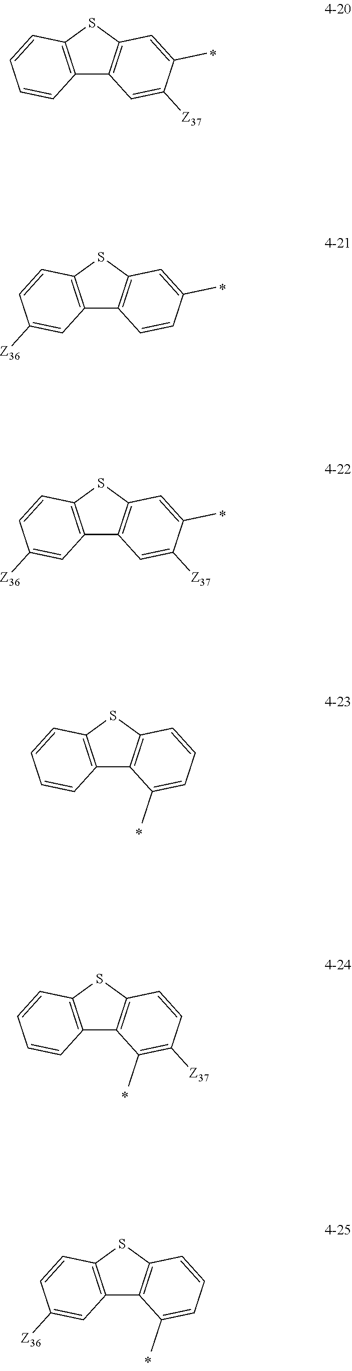

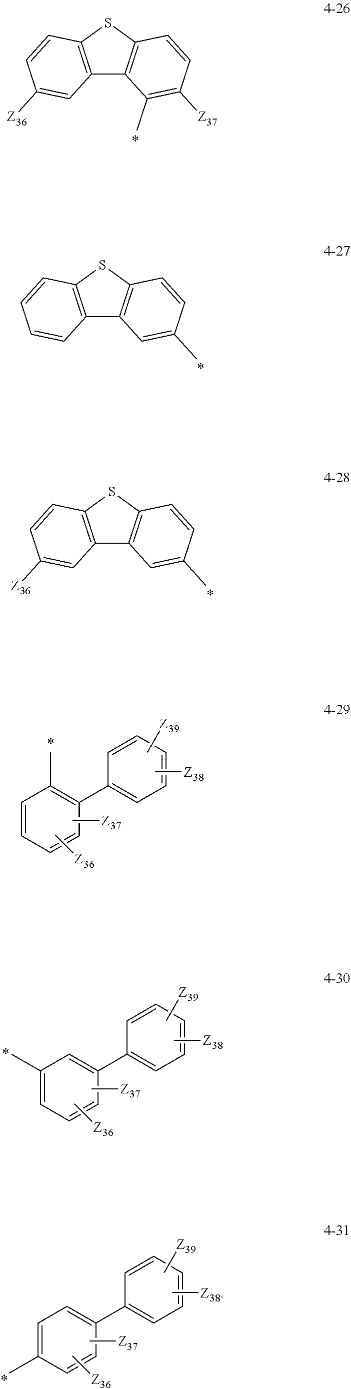

In Formulae 4-1 to 4-31, Z₃₆ to Z₃₉ are each independently defined the same as R₁₀, wherein Z₃₆ and Z₃₇ in Formulae 4-1 to 4-28 may not be hydrogen.

In an exemplary embodiment, in Formulae 4-1 to 4-31, Z₃₆ to Z₃₉ may each independently be:
a hydrogen, a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof wherein Z₃₆ and Z₃₇ in Formulae 4-1 to 4-28 may not be hydrogen.

In Formulae 3-1(1) to 3-1(3), * indicates a binding site to L₂ or ring A₁₁ in Formula 1.

In Formula 1, c1 and c2 each indicate the number of D₁ and the number of Ar₂, respectively, and may each independently be an integer from 1 to 5. When c1 is 2 or greater, a plurality of D₁ may be identical to or different from each other, and when c2 is 2 or greater, a plurality of Ar₂ may be identical to or different from each other. In an exemplary embodiment, c1 and c2 may each independently be 1 or 2, but embodiments of the present disclosure are not limited thereto.

In Formula 1, R₃ and R₁₀ may each independently be:
a hydrogen, a deuterium, a C₁-C₂₀ alkyl group, or a C₁-C₂₀ alkoxy group; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₁₁)(Q₁₁₂)(Q₁₁₃), or a combination thereof.

Q₁₁₁ to Q₁₁₃ are each independently the same as described above.

In one embodiment, in Formula 1, R₃ and R₁₀ may each independently be:
a hydrogen, a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof.

In one or more embodiments, in Formula 1, R₃ and R₁₀ may each independently be:
a hydrogen, a deuterium or a C₁-C₁₀ alkyl group; or
a phenyl group, a fluorenyl group, a carbazolyl group, a dibenzofuranyl group, a dibenzothiophenyl group, a biphenyl group, a terphenyl group, and a tetraphenyl group, each unsubstituted or substituted with a deuterium, a C₁-C₁₀ alkyl group, a phenyl group, a fluorenyl group, a carbazolyl group, a dibenzofuranyl group, a dibenzothiophenyl group, a biphenyl group, a terphenyl group, a tetraphenyl group, a (C₁-C₁₀ alkyl)phenyl group, or a combination thereof.

In Formula 1, d1 to d3 each indicate the number of *-(L₁)ₐ₁(D₁)_{c1}, the number of *-(L₂)ₐ₂-(Ar₂)_{c2}, and the number of R₃, respectively, and may each independently be an integer from 1 to 4. When d1 is 2 or greater, a plurality of *-(L₁)ₐ₁-(D₁)_{c1} may be identical to or different from each other, when d2 is 2 or greater, a plurality of *-(L₂)ₐ₂-(Ar₂)_{c2} may be identical to or different from each other, and when d3 is 2 or greater, a plurality of R₃ may be identical to or different from each other.

In one embodiment, d1 and d2 may each independently be 1 or 2.

Q₁₀₁ to Q₁₀₃ and Q₁₁₁ to Q₁₁₃ may each independently be a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

In one embodiment, the thermally activated delayed fluorescence emitter may include a compound represented by Formulae 1-1 to 1-5:

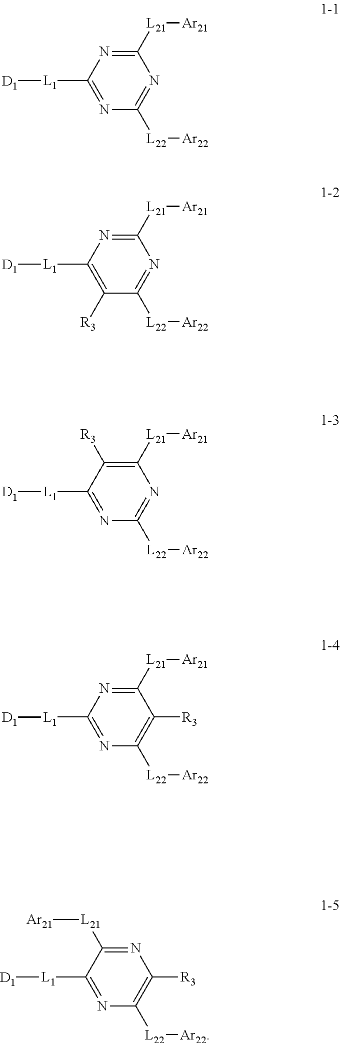

In Formulae 1-1 to 1-5,
L₁, D₁, and R₃ are each independently the same as described above,
L₁₁ and L₁₂ are each independently defined the same as L₁,
D₁₁ and D₁₂ are each independently defined the same as D₁,
L₂₁ and L₂₂ are each independently defined the same as L₂, and
Ar₂₁ and Ar₂₂ are each independently defined the same as Ar₂.

In one or more embodiments, the thermally activated delayed fluorescence emitter may include Compounds TD1 to TD59, but embodiments of the present disclosure are not limited thereto:

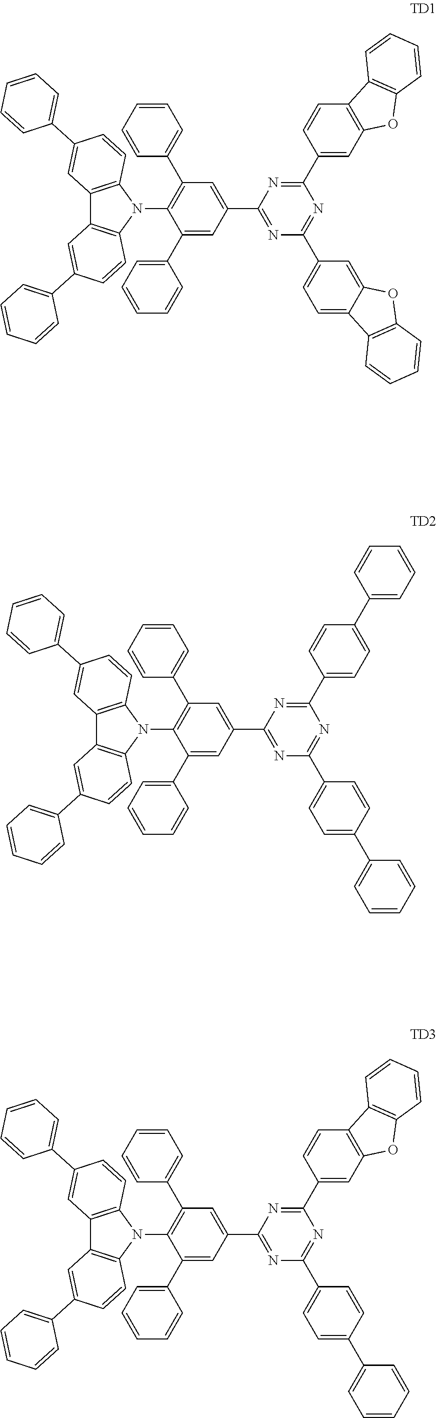 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4ccc5c(c4)oc4ccccc45)n3)cc2)cc1]

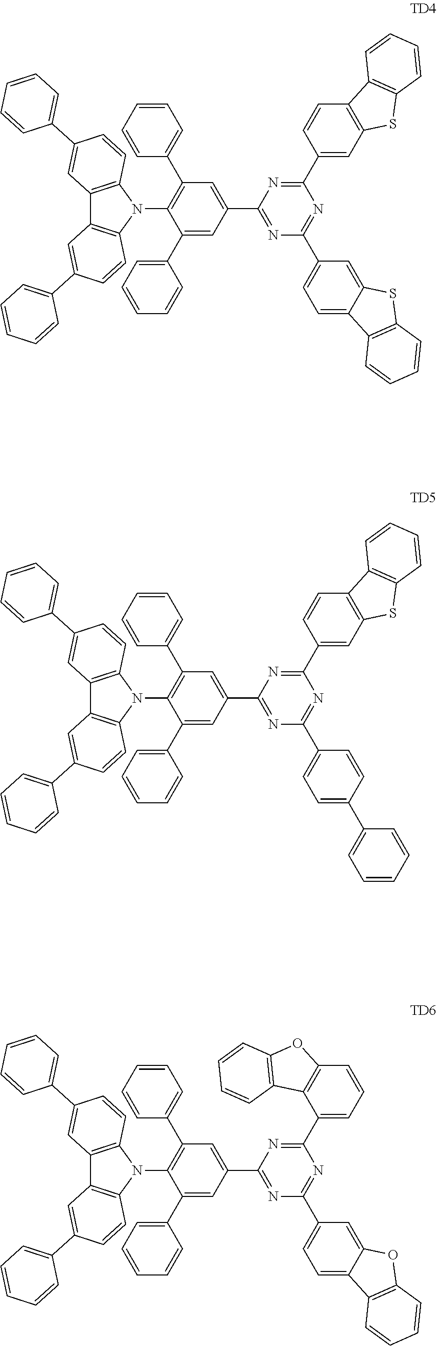 [SMILES: c1ccc(-c2ccc3c(c2)c2cc(-c4ccccc4)ccc2n3-c2c(-c3ccccc3)cc(-c3nc(-c4ccc5c(c4)sc4ccccc45)nc(-c4ccc5c(c4)sc4ccccc45)n3)cc2-c2ccccc2)cc1 ; c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4ccc5c(c4)sc4ccccc45)n3)cc2)cc1 ; c1ccc(-c2ccc3c(c2)c2cc(-c4ccccc4)ccc2n3-c2c(-c3ccccc3)cc(-c3nc(-c4ccc5c(c4)oc4ccccc45)nc(-c4cccc5oc6ccccc6c45)n3)cc2-c2ccccc2)cc1]

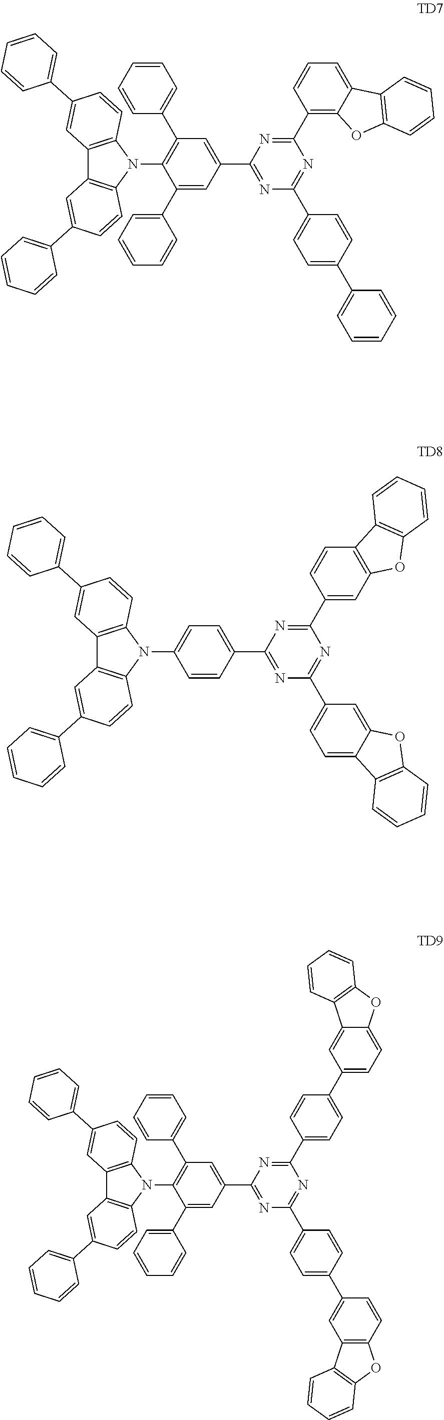 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5c4oc4ccccc45)n3)cc2)cc1 ; c1ccc(-c2ccc3c(c2)c2cc(-c4ccccc4)ccc2n3-c2ccc(-c3nc(-c4ccc5c(c4)oc4ccccc45)nc(-c4ccc5c(c4)oc4ccccc45)n3)cc2)cc1 ; c1ccc(-c2ccc3c(c2)c2cc(-c4ccccc4)ccc2n3-c2c(-c3ccccc3)cc(-c3nc(-c4ccc(-c5ccc6oc7ccccc7c6c5)cc4)nc(-c4ccc(-c5ccc6oc7ccccc7c6c5)cc4)n3)cc2-c2ccccc2)cc1]

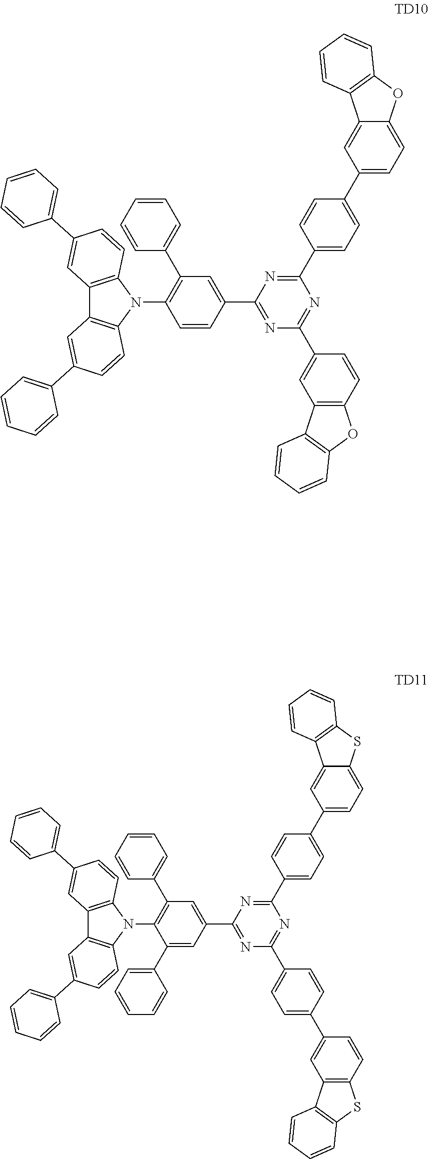 [SMILES: c1ccc(-c2ccc3c(c2)c2cc(-c4ccccc4)ccc2n3-c2ccc(-c3nc(-c4ccc(-c5ccc6oc7ccccc7c6c5)cc4)nc(-c4ccc5oc6ccccc6c5c4)n3)cc2-c2ccccc2)cc1 ; c1ccc(-c2ccc3c(c2)c2cc(-c4ccccc4)ccc2n3-c2c(-c3ccccc3)cc(-c3nc(-c4ccc(-c5ccc6sc7ccccc7c6c5)cc4)nc(-c4ccc(-c5ccc6sc7ccccc7c6c5)cc4)n3)cc2-c2ccccc2)cc1]

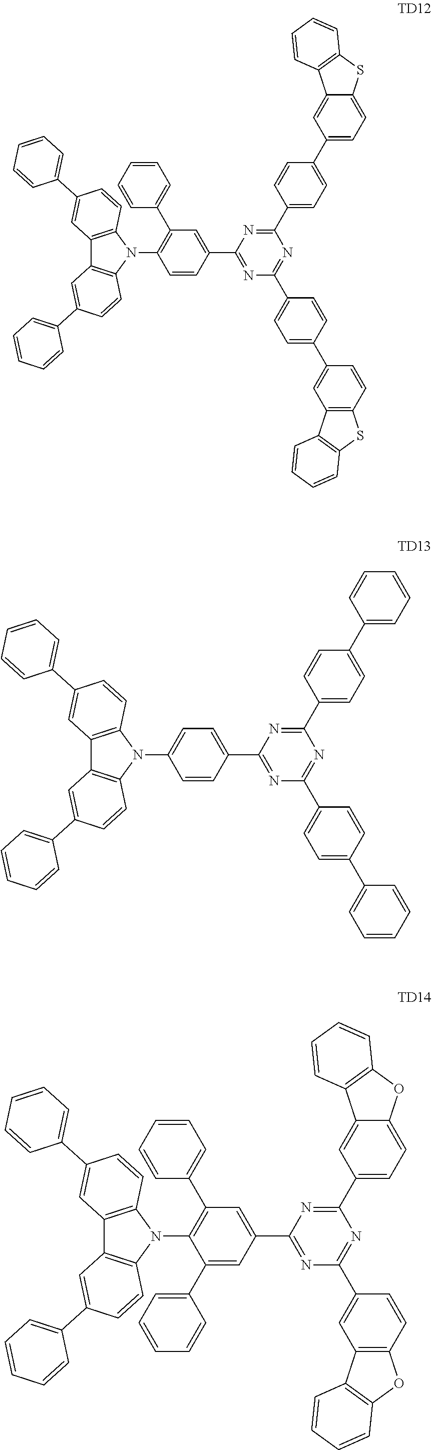 [SMILES: c1ccc(-c2ccc3c(c2)c2cc(-c4ccccc4)ccc2n3-c2ccc(-c3nc(-c4ccc(-c5ccc6sc7ccccc7c6c5)cc4)nc(-c4ccc(-c5ccc6sc7ccccc7c6c5)cc4)n3)cc2-c2ccccc2)cc1 ; c1ccc(-c2ccc(-c3nc(-c4ccc(-c5ccccc5)cc4)nc(-c4ccc(-n5c6ccc(-c7ccccc7)cc6c6cc(-c7ccccc7)ccc65)cc4)n3)cc2)cc1 ; c1ccc(-c2ccc3c(c2)c2cc(-c4ccccc4)ccc2n3-c2c(-c3ccccc3)cc(-c3nc(-c4ccc5oc6ccccc6c5c4)nc(-c4ccc5oc6ccccc6c5c4)n3)cc2-c2ccccc2)cc1]

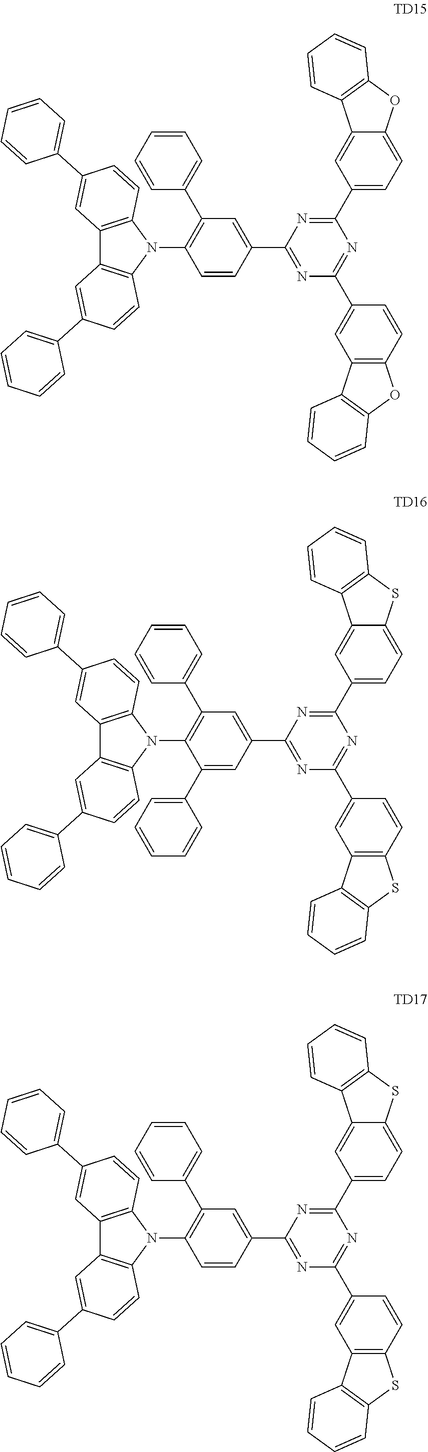 [SMILES: c1ccc(-c2ccc3c(c2)c2cc(-c4ccccc4)ccc2n3-c2ccc(-c3nc(-c4ccc5oc6ccccc6c5c4)nc(-c4ccc5oc6ccccc6c5c4)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5sc6ccccc6c5c4)nc(-c4ccc5sc6ccccc6c5c4)n3)cc2-c2ccccc2)cc1 ; c1ccc(-c2ccc3c(c2)c2cc(-c4ccccc4)ccc2n3-c2ccc(-c3nc(-c4ccc5sc6ccccc6c5c4)nc(-c4ccc5sc6ccccc6c5c4)n3)cc2-c2ccccc2)cc1]

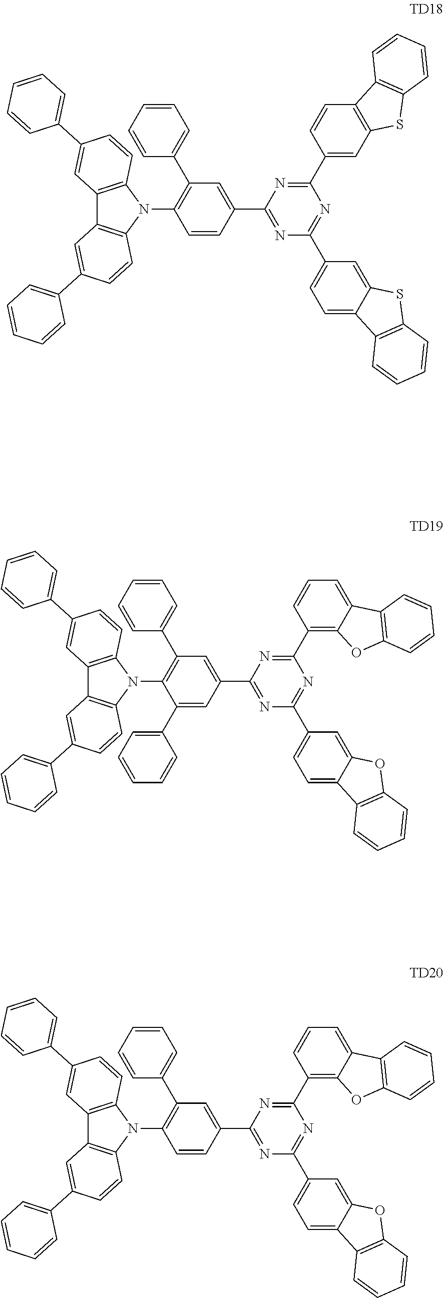 [SMILES: c1ccc(-c2ccc3c(c2)c2cc(-c4ccccc4)ccc2n3-c2ccc(-c3nc(-c4ccc5c(c4)sc4ccccc45)nc(-c4ccc5c(c4)sc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5c(c4)oc4ccccc45)nc(-c4cccc5c4oc4ccccc45)n3)cc2-c2ccccc2)cc1 ; c1ccc(-c2ccc3c(c2)c2cc(-c4ccccc4)ccc2n3-c2ccc(-c3nc(-c4ccc5c(c4)oc4ccccc45)nc(-c4cccc5c4oc4ccccc45)n3)cc2-c2ccccc2)cc1]

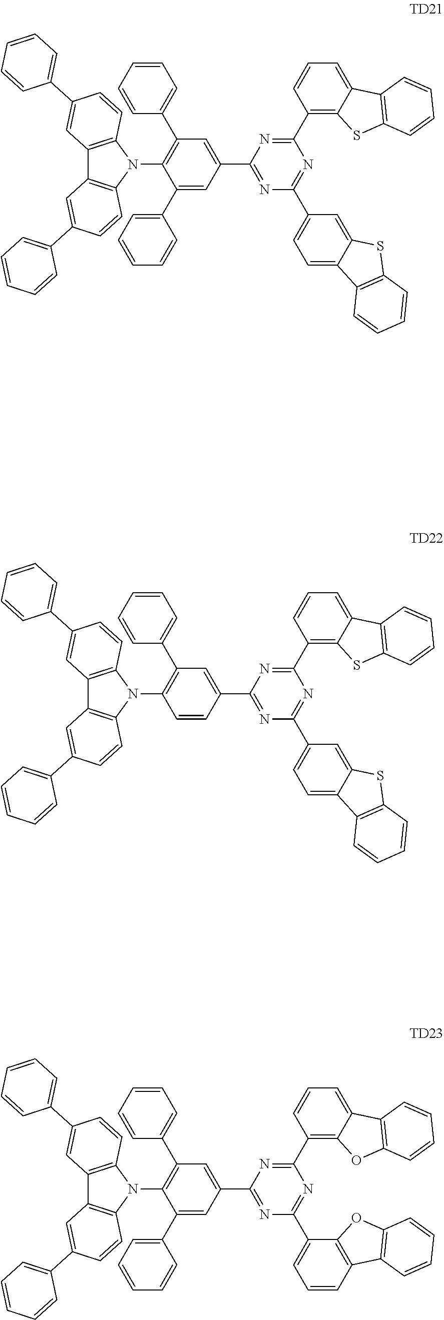 [SMILES: c1ccc(-c2ccc3c(c2)c2cc(-c4ccccc4)ccc2n3-c2c(-c3ccccc3)cc(-c3nc(-c4ccc5c(c4)sc4ccccc45)nc(-c4cccc5c4sc4ccccc45)n3)cc2-c2ccccc2)cc1 ; c1ccc(-c2ccc3c(c2)c2cc(-c4ccccc4)ccc2n3-c2ccc(-c3nc(-c4ccc5c(c4)sc4ccccc45)nc(-c4cccc5c4sc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4cccc5c4oc4ccccc45)nc(-c4cccc5c4oc4ccccc45)n3)cc2-c2ccccc2)cc1]

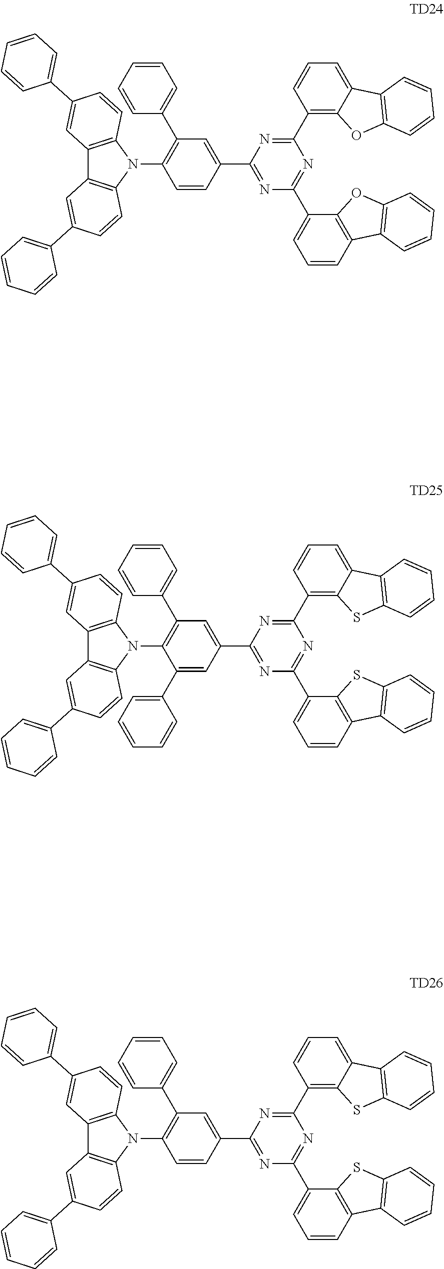 [SMILES: c1ccc(-c2ccc3c(c2)c2cc(-c4ccccc4)ccc2n3-c2ccc(-c3nc(-c4cccc5c4oc4ccccc45)nc(-c4cccc5c4oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4cccc5c4sc4ccccc45)nc(-c4cccc5c4sc4ccccc45)n3)cc2-c2ccccc2)cc1 ; c1ccc(-c2ccc3c(c2)c2cc(-c4ccccc4)ccc2n3-c2ccc(-c3nc(-c4cccc5c4sc4ccccc45)nc(-c4cccc5c4sc4ccccc45)n3)cc2-c2ccccc2)cc1]

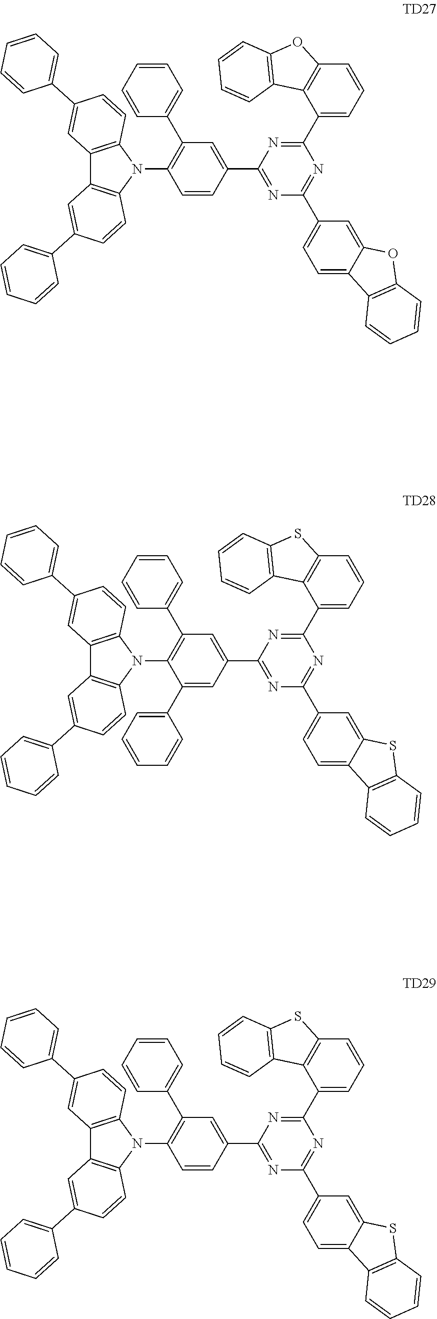 [SMILES: c1ccc(-c2ccc3c(c2)c2cc(-c4ccccc4)ccc2n3-c2ccc(-c3nc(-c4ccc5c(c4)oc4ccccc45)nc(-c4cccc5oc6ccccc6c45)n3)cc2-c2ccccc2)cc1 ; c1ccc(-c2ccc3c(c2)c2cc(-c4ccccc4)ccc2n3-c2c(-c3ccccc3)cc(-c3nc(-c4ccc5c(c4)sc4ccccc45)nc(-c4cccc5sc6ccccc6c45)n3)cc2-c2ccccc2)cc1 ; c1ccc(-c2ccc3c(c2)c2cc(-c4ccccc4)ccc2n3-c2ccc(-c3nc(-c4ccc5c(c4)sc4ccccc45)nc(-c4cccc5sc6ccccc6c45)n3)cc2-c2ccccc2)cc1]

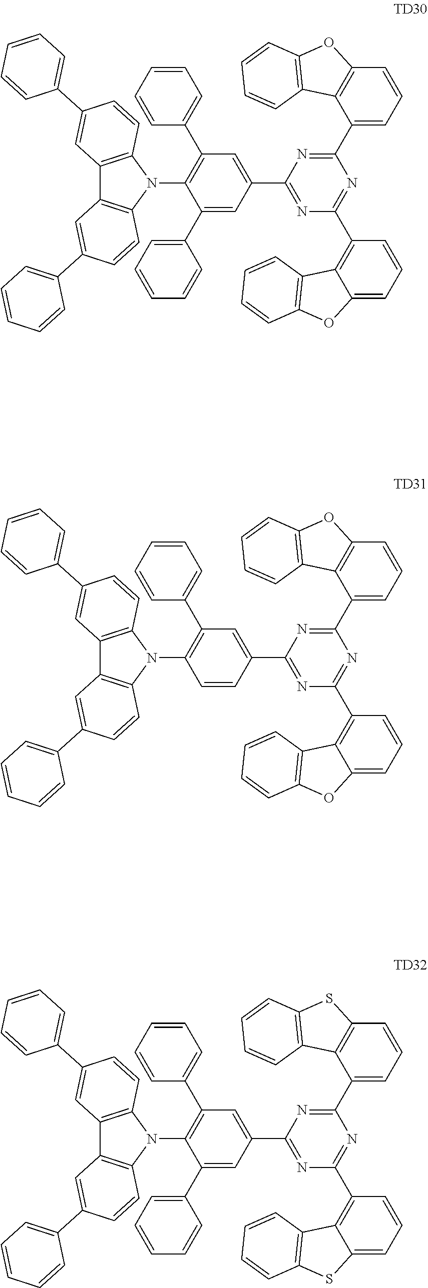 [SMILES: c1ccc(-c2ccc3c(c2)c2cc(-c4ccccc4)ccc2n3-c2c(-c3ccccc3)cc(-c3nc(-c4cccc5oc6ccccc6c45)nc(-c4cccc5oc6ccccc6c45)n3)cc2-c2ccccc2)cc1 ; c1ccc(-c2ccc3c(c2)c2cc(-c4ccccc4)ccc2n3-c2ccc(-c3nc(-c4cccc5oc6ccccc6c45)nc(-c4cccc5oc6ccccc6c45)n3)cc2-c2ccccc2)cc1 ; c1ccc(-c2ccc3c(c2)c2cc(-c4ccccc4)ccc2n3-c2c(-c3ccccc3)cc(-c3nc(-c4cccc5sc6ccccc6c45)nc(-c4cccc5sc6ccccc6c45)n3)cc2-c2ccccc2)cc1]

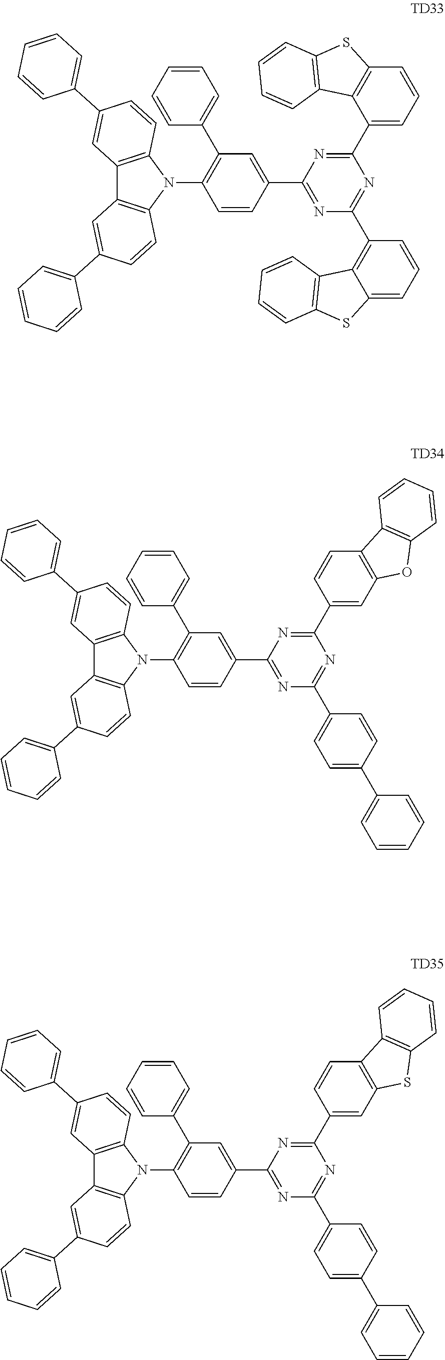 [SMILES: c1ccc(-c2ccc3c(c2)c2cc(-c4ccccc4)ccc2n3-c2ccc(-c3nc(-c4cccc5sc6ccccc6c45)nc(-c4cccc5sc6ccccc6c45)n3)cc2-c2ccccc2)cc1 ; c1ccc(-c2ccc(-c3nc(-c4ccc(-n5c6ccc(-c7ccccc7)cc6c6cc(-c7ccccc7)ccc65)c(-c5ccccc5)c4)nc(-c4ccc5c(c4)oc4ccccc45)n3)cc2)cc1 ; c1ccc(-c2ccc(-c3nc(-c4ccc(-n5c6ccc(-c7ccccc7)cc6c6cc(-c7ccccc7)ccc65)c(-c5ccccc5)c4)nc(-c4ccc5c(c4)sc4ccccc45)n3)cc2)cc1]

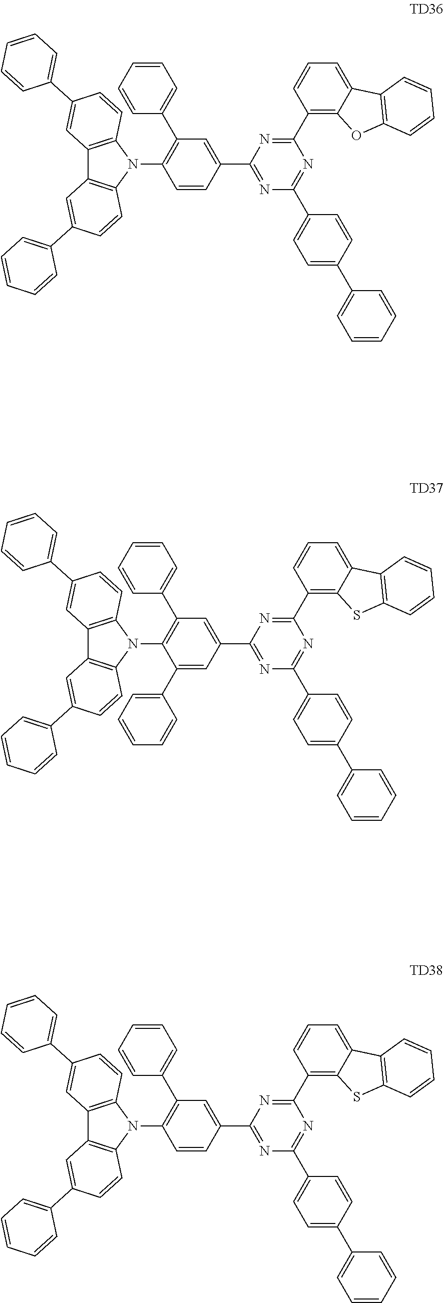 [SMILES: c1ccc(-c2ccc(-c3nc(-c4ccc(-n5c6ccc(-c7ccccc7)cc6c6cc(-c7ccccc7)ccc65)c(-c5ccccc5)c4)nc(-c4cccc5c4oc4ccccc45)n3)cc2)cc1 ; c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5c4sc4ccccc45)n3)cc2)cc1 ; c1ccc(-c2ccc(-c3nc(-c4ccc(-n5c6ccc(-c7ccccc7)cc6c6cc(-c7ccccc7)ccc65)c(-c5ccccc5)c4)nc(-c4cccc5c4sc4ccccc45)n3)cc2)cc1]

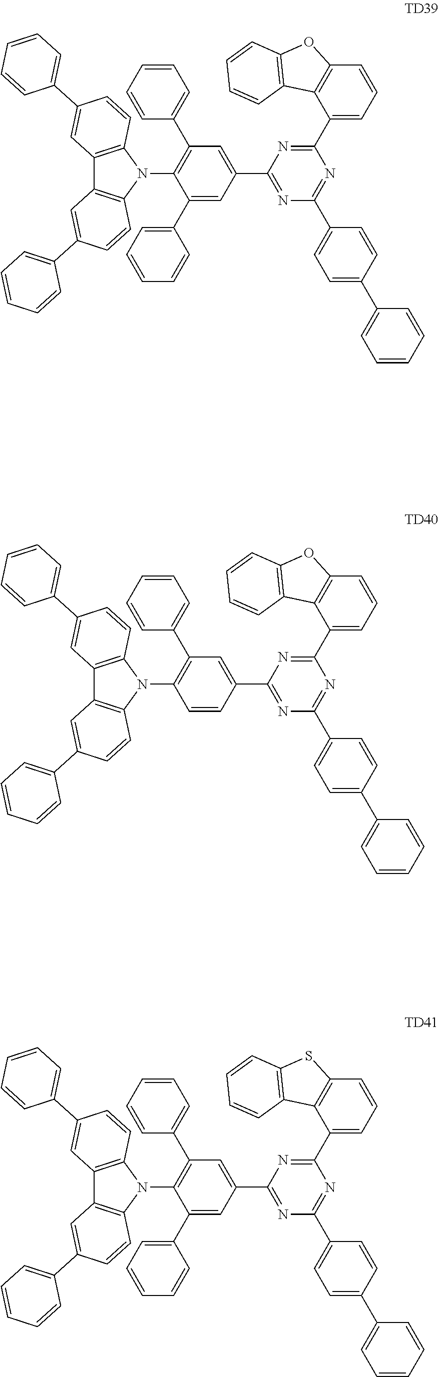 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5oc6ccccc6c45)n3)cc2)cc1 ; c1ccc(-c2ccc(-c3nc(-c4ccc(-n5c6ccc(-c7ccccc7)cc6c6cc(-c7ccccc7)ccc65)c(-c5ccccc5)c4)nc(-c4cccc5oc6ccccc6c45)n3)cc2)cc1 ; c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5sc6ccccc6c45)n3)cc2)cc1]

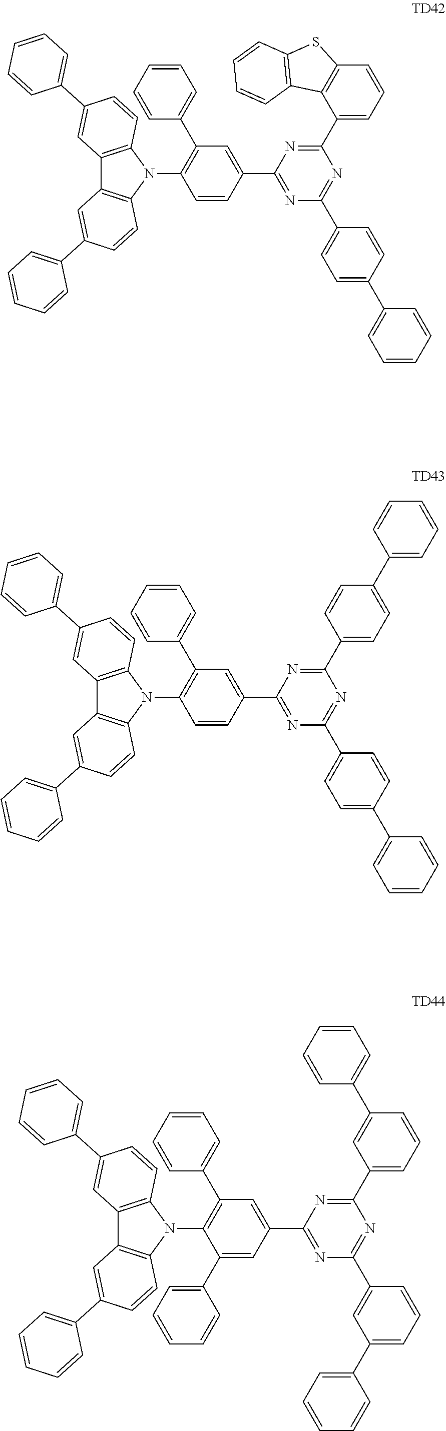 [SMILES: c1ccc(-c2ccc(-c3nc(-c4ccc(-n5c6ccc(-c7ccccc7)cc6c6cc(-c7ccccc7)ccc65)c(-c5ccccc5)c4)nc(-c4cccc5sc6ccccc6c45)n3)cc2)cc1 ; c1ccc(-c2ccc(-c3nc(-c4ccc(-c5ccccc5)cc4)nc(-c4ccc(-n5c6ccc(-c7ccccc7)cc6c6cc(-c7ccccc7)ccc65)c(-c5ccccc5)c4)n3)cc2)cc1 ; c1ccc(-c2cccc(-c3nc(-c4cccc(-c5ccccc5)c4)nc(-c4cc(-c5ccccc5)c(-n5c6ccc(-c7ccccc7)cc6c6cc(-c7ccccc7)ccc65)c(-c5ccccc5)c4)n3)c2)cc1]

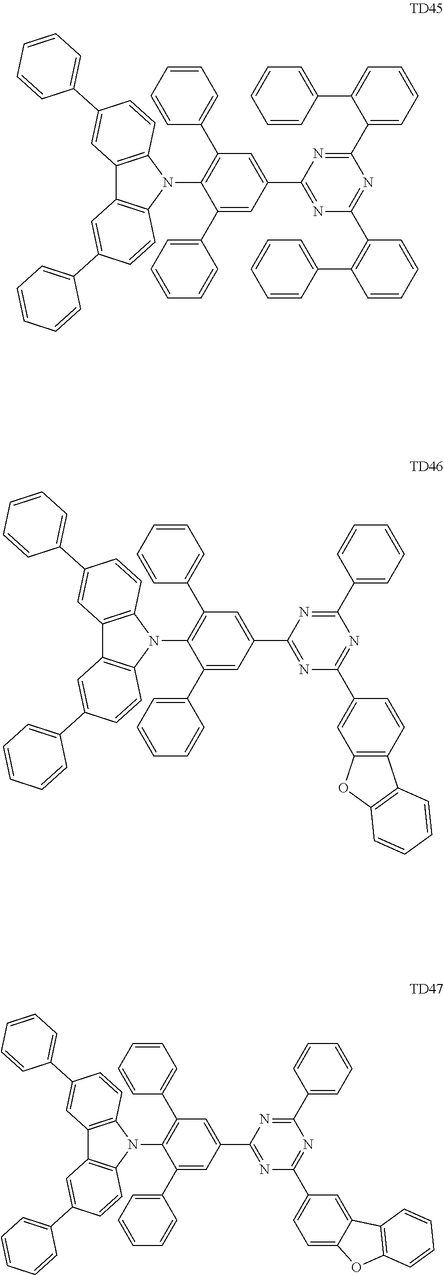 [SMILES: c1ccc(-c2ccc3c(c2)c2cc(-c4ccccc4)ccc2n3-c2c(-c3ccccc3)cc(-c3nc(-c4ccccc4-c4ccccc4)nc(-c4ccccc4-c4ccccc4)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(c4)oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5oc6ccccc6c5c4)n3)cc2-c2ccccc2)cc1]

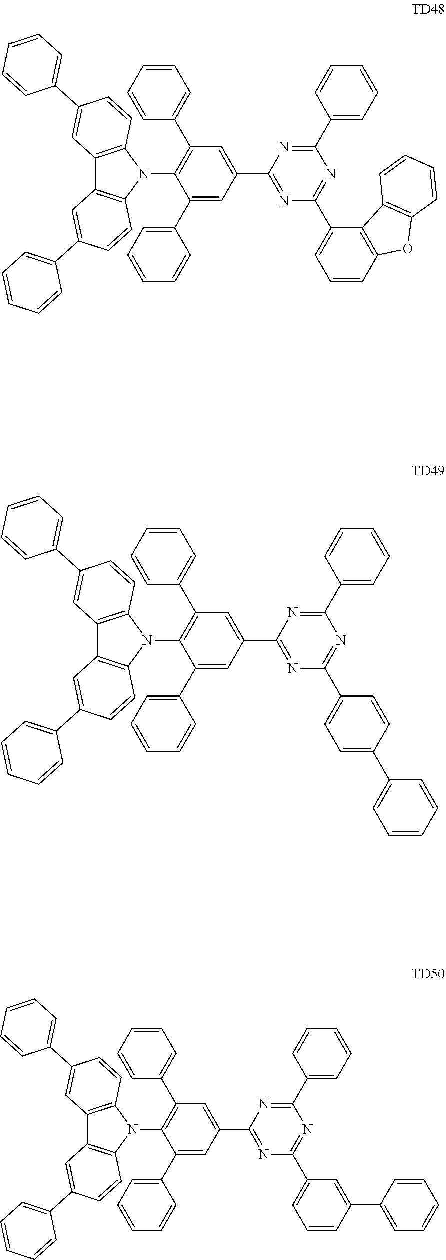 [SMILES: c1ccc(-c2ccc3c(c2)c2cc(-c4ccccc4)ccc2n3-c2c(-c3ccccc3)cc(-c3nc(-c4ccccc4)nc(-c4cccc5oc6ccccc6c45)n3)cc2-c2ccccc2)cc1 ; c1ccc(-c2ccc(-c3nc(-c4ccccc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; c1ccc(-c2cccc(-c3nc(-c4ccccc4)nc(-c4cc(-c5ccccc5)c(-n5c6ccc(-c7ccccc7)cc6c6cc(-c7ccccc7)ccc65)c(-c5ccccc5)c4)n3)c2)cc1]

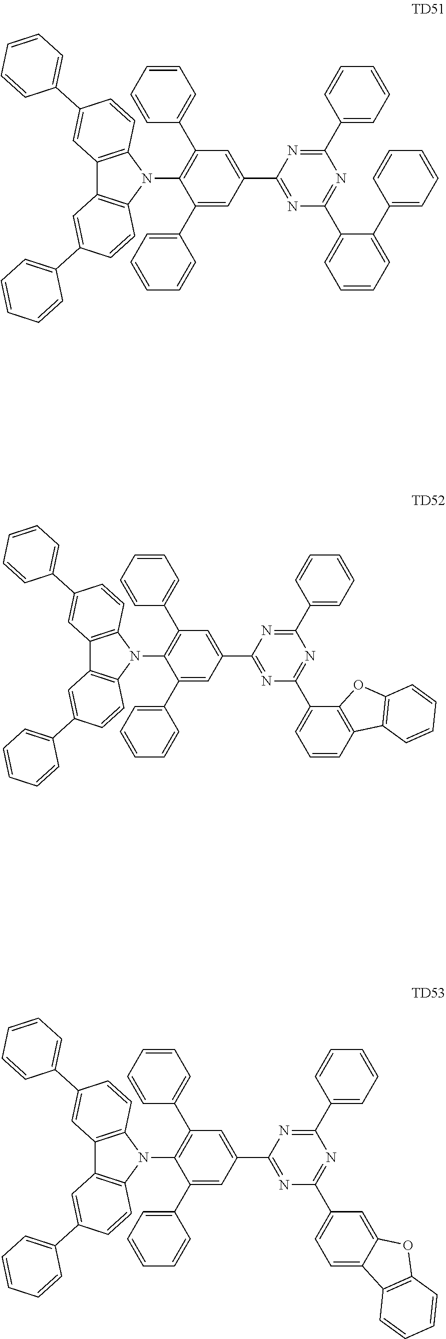 [SMILES: c1ccc(-c2ccc3c(c2)c2cc(-c4ccccc4)ccc2n3-c2c(-c3ccccc3)cc(-c3nc(-c4ccccc4)nc(-c4ccccc4-c4ccccc4)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4cccc5c4oc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(c4)oc4ccccc45)n3)cc2-c2ccccc2)cc1]

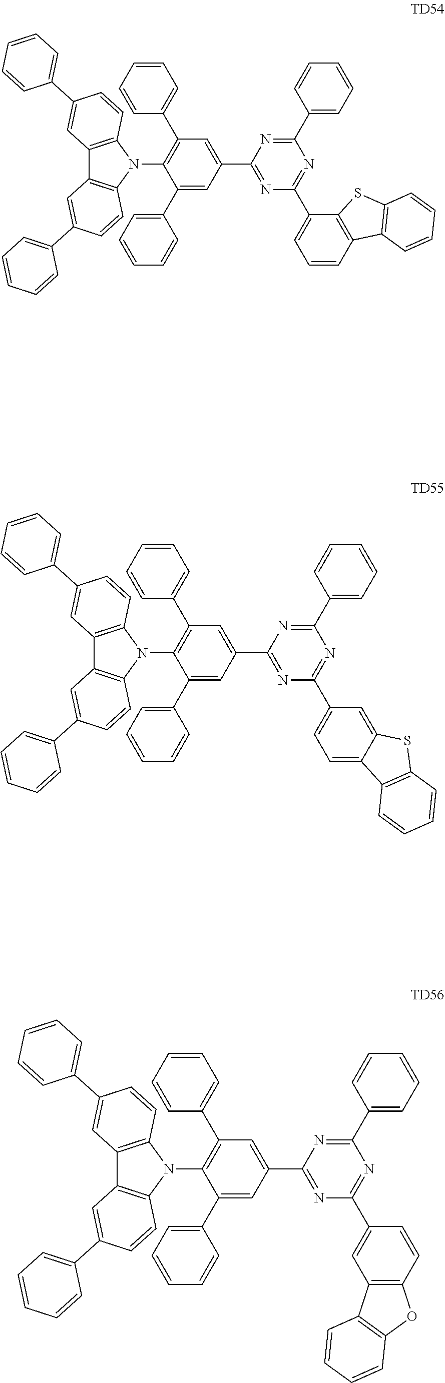 [SMILES: c1ccc(-c2ccc3c(c2)c2cc(-c4ccccc4)ccc2n3-c2c(-c3ccccc3)cc(-c3nc(-c4ccccc4)nc(-c4cccc5c4sc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5c(c4)sc4ccccc45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5oc6ccccc6c5c4)n3)cc2-c2ccccc2)cc1]

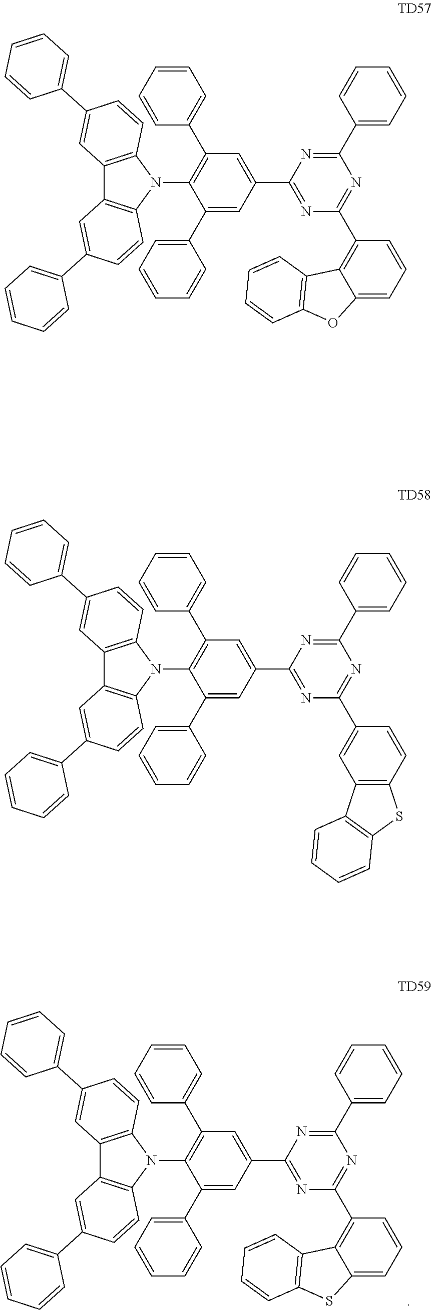 [SMILES: c1ccc(-c2ccc3c(c2)c2cc(-c4ccccc4)ccc2n3-c2c(-c3ccccc3)cc(-c3nc(-c4ccccc4)nc(-c4cccc5oc6ccccc6c45)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4ccc5sc6ccccc6c5c4)n3)cc2-c2ccccc2)cc1 ; c1ccc(-c2ccc3c(c2)c2cc(-c4ccccc4)ccc2n3-c2c(-c3ccccc3)cc(-c3nc(-c4ccccc4)nc(-c4cccc5sc6ccccc6c45)n3)cc2-c2ccccc2)cc1]

The emission layer does not include a phosphorescence emitter and does not substantially emit phosphorescence. Instead, the emission layer is a “delayed fluorescence” emission layer that emits delayed fluorescence by transitioning a triplet exciton of the compound represented by Formula 1 from a triplet state to a singlet state by reverse intersystem crossing (RISC), followed by transiting to a ground state.

As described above, the “delayed fluorescence” emission layer as used herein is distinctly different from the “phosphorescence” emission layer which includes, for example, the compound represented by Formula 1 as a host and the phosphorescence emitter (for example, a transition metal (for example, iridium or platinum etc.) complex) as a dopant, and in which only energy transition from the compound represented by Formula 1 as a host to the phosphorescence emitter occurs, without a process of emitting delayed fluorescence by transitioning a triplet exciton of the compound represented by Formula 1 from a triplet state to a singlet state by reverse intersystem crossing (RISC), followed by transiting to a ground state.

The compound represented by Formula 1 includes ring A₁₁ and at least one D₁ (in Formula 1, c1 is an integer from 1 to 5, and d1 is an integer from 1 to 4). Since ring A₁₁ is a pyridine group, a pyrimidine group, a pyrazine group, a pyridazine group, a triazine group, or a tetrazine group, ring A₁₁ corresponds to an “acceptor group”, and since D₁ is a hole-transporting group (see, for example, Formula 3-1). D₁ corresponds to a “donor group”.

A difference between a triplet energy level (eV) of the thermally activated delayed fluorescence emitter including the compound represented by Formula 1 and a singlet energy level (eV) of the thermally activated delayed fluorescence emitter may be in a range of 0 eV to 0.5 eV (for example, 0 eV to 0.3 eV).

When the difference between the triplet energy level (eV) of the thermally activated delayed fluorescence emitter and the singlet energy level (eV) of the thermally activated delayed fluorescence emitter is within this range, up-conversion from the triplet state to the singlet state is effectively performed such that the fluorescent dopant emits highly efficient delayed fluorescence.

The triplet energy level and the singlet energy level are evaluated by a density functional theory (DFT) method of Gaussian program structurally optimized at a level of B3LYP/6-31G(d,p).

A ratio of a delayed fluorescence component emitted from the thermally activated delayed fluorescence emitter to a total emission component emitted from the emission layer may be 90% or more, 92% or more, 94% or more, 96% or more, or 98% or more, but embodiments of the present disclosure are not limited thereto.

Furthermore, in Formula 1, Ar₂ is a dibenzofuran group, a dibenzothiophene group, or a biphenyl group, each unsubstituted or substituted with at least one R₁₀ , c2 indicating the number of Ar₂ is an integer from 1 to 5, and d2 indicating the number of *-(L₂)ₐ₂-(Ar₂)_{c2} is an integer from 1 to 4. Thus, ring A₁₁ is substituted with at least one *-(L₂)ₐ₂-(Ar₂)_{c2}.

Since ring A₁₁ is substituted with at least one *-(L₂)ₐ₂-(Ar₂)_{c2}, i) ring A₁₁ may be protected from external influences, and ii) electron distribution concentration on a bond between D₁ and L₁ or a bond between D₁ and ring A₁₁ in Formula 1 (particularly, D₁ in Formula 1) is solved, and thus bond-dissociation energy (BDE) for the bond between D₁ and L₁ or the bond between D₁ and ring A₁₁ in Formula 1 may increase. Since the bond between D₁ and L₁ or the bond between D₁ and ring A₁₁ in Formula 1 is a bond in which a twist occurs between a “donor group” and an “acceptor group”, the BDE for the bond increases, thereby improving the entire material stability of the compound represented by Formula 1. Therefore, since the material stability of the compound represented by Formula 1 is improved, an electronic device, for example, an organic light-emitting device, which includes the compound represented by Formula 1, may have improved lifespan characteristics.

The emission layer may variously emit red light, green light, and blue light according to the maximum emission wavelength of the thermally activated delayed fluorescence emitter.

In an exemplary embodiment, light emitted from the thermally activated delayed fluorescence emitter in the emission layer may be blue light, but embodiments of the present disclosure are not limited thereto.

In one embodiment, the host in the emission layer may consist of one compound.

In one or more embodiments, the hosts in the emission layer may be a mixture of at least two different compounds.

The host in the emission layer may include a first material, a second material, or a combination thereof,
the first material and the second material may be different from each other,
the first material may include a π electron-rich cyclic group, and may not include an electron-transporting moiety,
the second material may include a one π electron-rich cyclic group and an electron-transporting moiety, and
the electron-transporting moiety may be a cyano group, a π electron-deficient nitrogen-containing cyclic group, or a group represented by one of the following formulae:

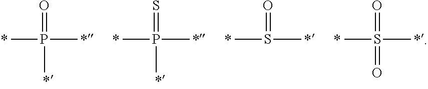

In the formulae, *, *′, and *″ each indicate a binding site to a neighboring atom.

In an exemplary embodiment,
i) the host may consist of one compound in the first material,
ii) the host may be a mixture of at least two different compounds in the first material,
iii) the host may consist of one compound in the second material,
iv) the host may be a mixture of at least two different compounds in the second material, or
v) the host may be a mixture of at least one compound in the first material and at least one compound in the second material, but embodiments of the present disclosure are not limited thereto.

In one embodiment, in Formula 1, L₁ is a group represented by Formula 2-3, and when a1 is 1, the host of the emission layer may be a mixture of at least two different compounds (for example, a) a mixture of at least two compounds in the first material, b) a mixture of at least two different compounds in the second material, or c) a mixture of at least one compound in the first material and at least one compound in the second material).

The term “π electron-deficient nitrogen-containing cyclic group” as used herein refers to a group including a cyclic group having at least one *-N=*′ moiety, and for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, an azadibenzosilole group, or a condensed cyclic group in which a cyclic group is condensed with at least one of the foregoing groups.

The π electron-rich cyclic group may be, for example, a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, or a dihydroacridine group, but embodiments of the present disclosure are not limited thereto. In some embodiments the π electron-rich cyclic group may be nitrogen-free.

The first material may be different from the second material.

In one embodiment, the first material and the second material may each include a carbazole group.

In one or more embodiments, the first material and the second material may each include at least two carbazole groups, but embodiments of the present disclosure are not limited thereto.

In one or more embodiments, the second material may include a cyano group (for example, one, two, three, or four cyano groups).

In one or more embodiments, the first material may include a cyano group-free benzene group and a cyano group-free carbazole group.

In one or more embodiments, the second material may include a cyano group. a carbazole ring, or a combination thereof.

In one or more embodiments, the second material may include a cyano group-containing benzene group, a cyano group-containing carbazole group, or a combination thereof.

In one or more embodiments,
an absolute value of a lowest unoccupied molecular orbital (LUMO) energy level of the first material may be in a range of about 0.90 eV to about 1.20 eV,
an absolute of a highest occupied molecular orbital (HOMO) energy level of the first material may be in a range of about 5.20 eV to about 5.60 eV,
an absolute value of a LUMO energy level of the second material may be in a range of about 1.80 eV to about 2.20 eV, and
an absolute value of a HOMO energy level of the second material may be in a range of about 5.40 eV to about 6.00 eV, but embodiments of the present disclosure are not limited thereto.

When the first material and the second material are within these HOMO and LUMO energy level ranges, charge and/or exciton movement and energy flow in the emission layer are smoothly performed, thereby implementing an organic light-emitting device having high luminescent efficiency and a long lifespan.

In one or more embodiments, the first material may include a compound represented by Formula H-1(1), a compound represented by Formula H-1(2), a compound represented by Formula H-1(3), or a combination thereof:

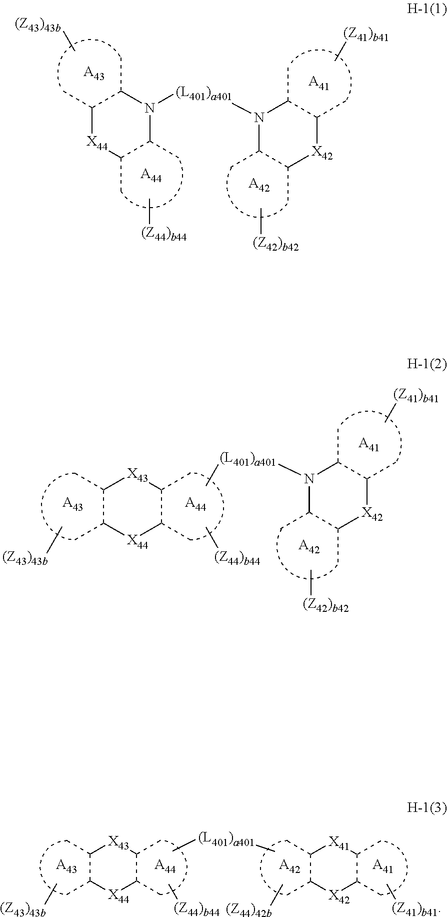

In Formulae H-1(1) to H-1(3), ring A₄₁ to ring A₄₄ may each independently be a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group.

In an exemplary embodiment, ring A₄₁ to ring A₄₄ may each independently be a benzene group, a fluorene group, a carbazole group, a dibenzofuran group, a dibenzothiophene group, or a dibenzosilole group, wherein ring A₄₁, ring A₄₂, or a combination thereof may be a benzene group, or ring A₄₃, ring A₄₄, or a combination thereof may be a benzene group.

In Formulae H-1(1) to H-1(3),
X₄₁ may be N-[(L₄₁₁)_{c411}-Z₄₁₁], C(Z₄₁₅)(Z₄₁₆), O, or S,
X₄₂ may be a single bond, N-[(L₄₁₂)_{c412}-Z₄₁₂], C(Z₄₁₇)(Z₄₁₈), O, or S,
X₄₃ may be N-[(L₄₁₃)_{c413}-Z₄₁₃], C(Z₄₁₉)(Z₄₂₀), O, or S, and
X₄₄ may be a single bond, N-[(L₄₁₄)_{c414}-Z₄₁₄], C(Z₄₂₁)(Z₄₂₂), O, or S.
L₄₀₁ and L₄₁₁ to L₄₁₄ may each independently be:
a single bond; or
a π electron-rich cyclic group, (for example, a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, or a dihydroacridine group) each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, —Si(C)Q₄₀₁)(Q₄₀₂)(Q₄₀₃), or a combination thereof.

a401 and c411 to c414 each indicate the number of L₄₀₁ and the number of L₄₁₁ to L₄₁₄, respectively, and may each independently be an integer from 1 to 10 (for example, an integer from 1 to 5). When a401 is 2 or greater, a plurality of L₄₀₁ may be identical to or different from each other, when c411 is 2 or greater, a plurality of L₄₁₁ may be identical to or different from each other, when c412 is 2 or greater, a plurality of L₄₁₂ may be identical to or different from each other, when c413 is 2 or greater, a plurality of L₄₁₃ may be identical to or different from each other, and when c414 is 2 or greater, a plurality of L₄₁₄ may be identical to or different from each other.

Z₄₁ to Z₄₄ and Z₄₁₁ to Z₄₂₂ may each independently be:
a hydrogen, a deuterium, a C₁-C₂₀ alkyl group, or a C₁-C₂₀ alkoxy group; or
a π electron-rich cyclic group (for example, a phenyl group, a biphenyl group, a terphenyl group, a tetraphenyl group, a naphthyl group, a fluorenyl group, a spiro-bifluorenyl group, a benzofluorenyl group, a dibenzofluorenyl group, a phenanthrenyl group, an anthracenyl group, a triphenylenyl group, a pyrenyl group, a chrysenyl group, a pyrrolyl group, an isoindolyl group, an indolyl group, a furanyl group, a thiophenyl group, a benzofuranyl group, a benzothiophenyl group, a benzosilolyl group, a benzocarbazolyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group) each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, Si(Q₄₀₁)(Q₄₀₂)(Q₄₀₃), or a combination thereof.

b41 to b44 each indicate the number of Z₄₁ to Z₄₄, respectively, and may each independently be 1, 2, 3, or 4.

Q₄₀₁ to Q₄₀₃ may each independently be a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

In one embodiment, in Formulae H-1(1) to H-1(3),
L₄₀₁ and L₄₁₁ to L₄₁₄ may each independently be:
a single bond; or
a benzene group, a fluorene group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, an acridine group, or a dihydroacridine group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, and
Z₄₁ to Z₄₄ and Z₄₁₁ to Z₄₂₂ may each independently be:
a hydrogen, a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, but embodiments of the present disclosure are not limited thereto.

In one embodiment, the first material may include Compounds H1 to H32, but embodiments of the present disclosure are not limited thereto:

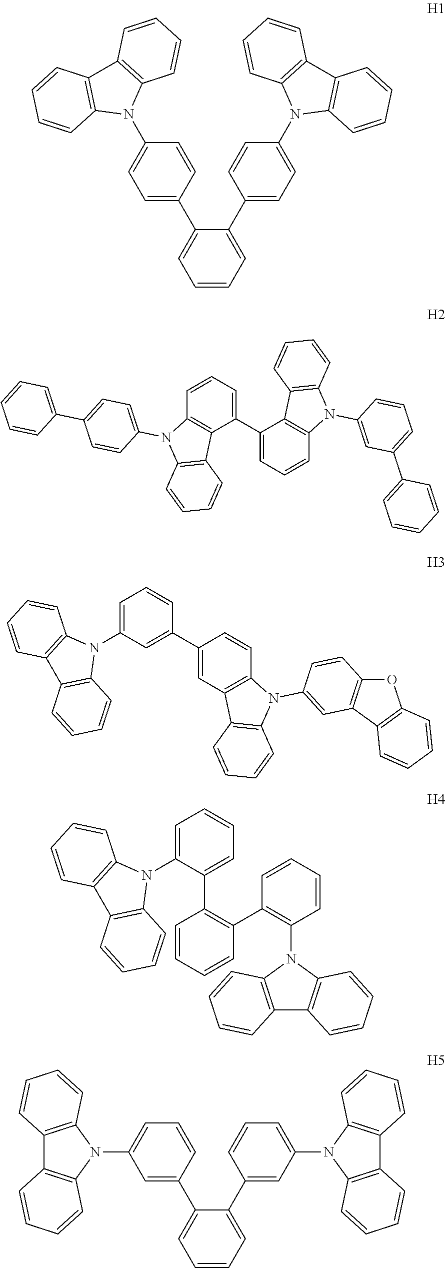

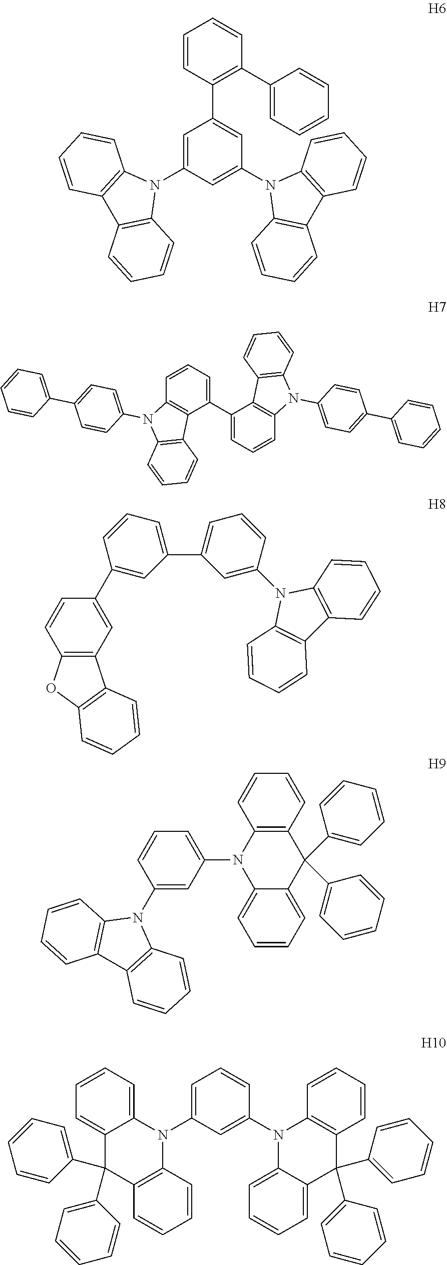

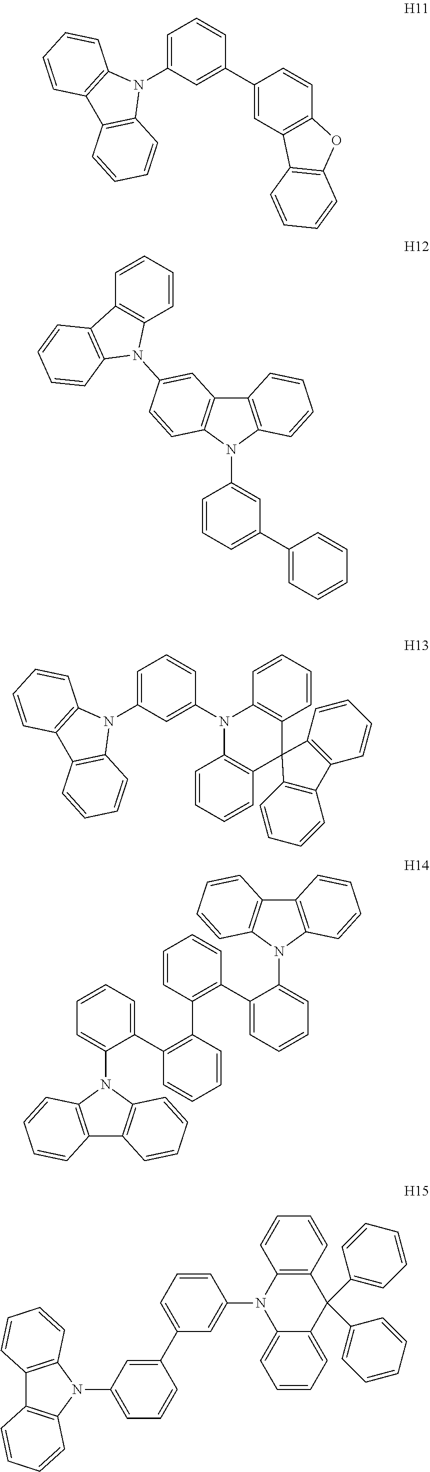

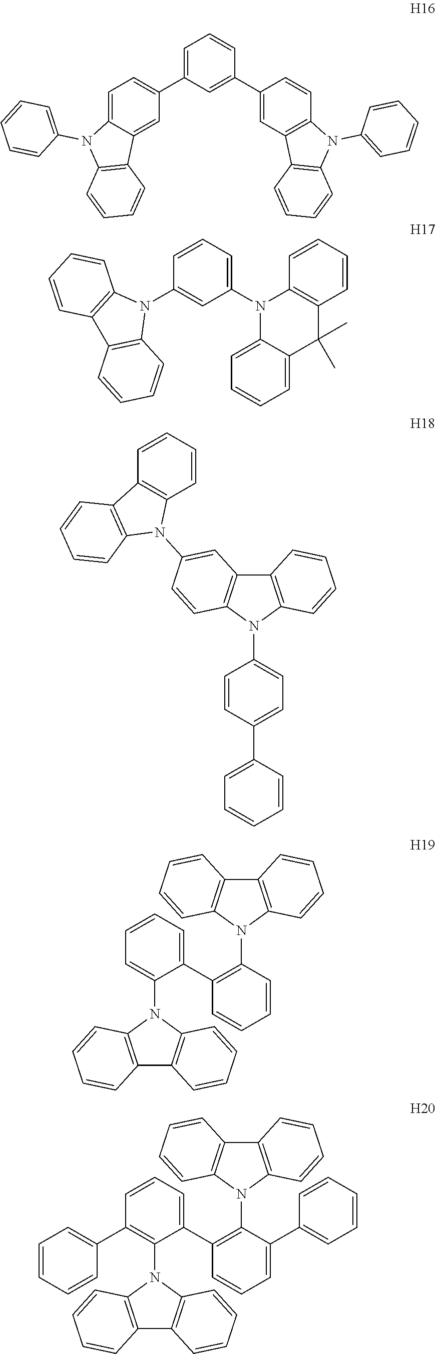

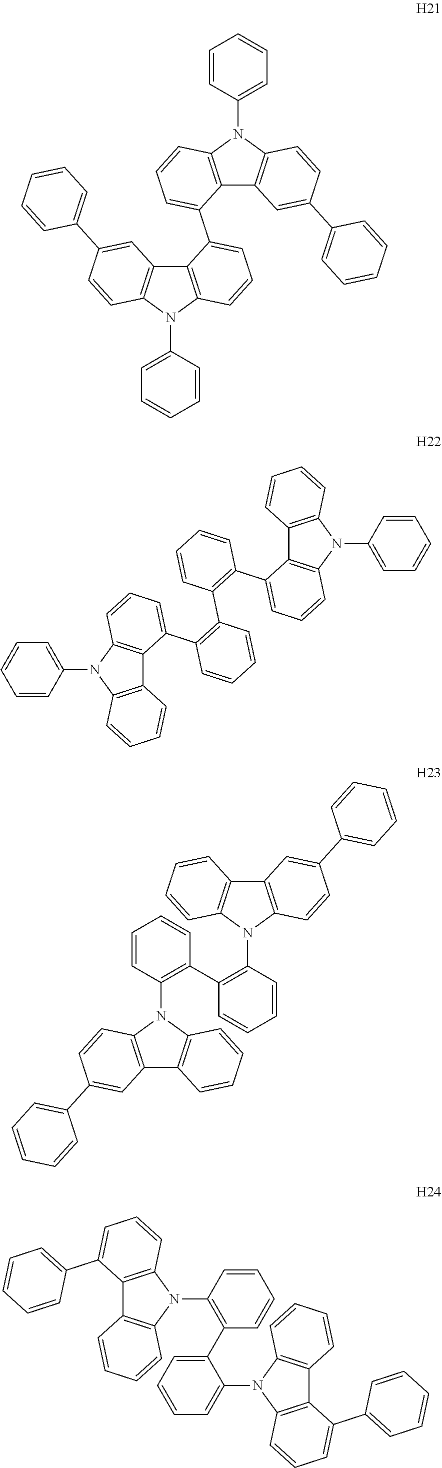 [SMILES: c1ccc(-c2ccc3c(c2)c2c(-c4cccc5c4c4cc(-c6ccccc6)ccc4n5-c4ccccc4)cccc2n3-c2ccccc2)cc1 ; c1ccc(-n2c3ccccc3c3c(-c4ccccc4-c4ccccc4-c4cccc5c4c4ccccc4n5-c4ccccc4)cccc32)cc1 ; c1ccc(-c2ccc3c(c2)c2ccccc2n3-c2ccccc2-c2ccccc2-n2c3ccccc3c3cc(-c4ccccc4)ccc32)cc1 ; c1ccc(-c2cccc3c2c2ccccc2n3-c2ccccc2-c2ccccc2-n2c3ccccc3c3c(-c4ccccc4)cccc32)cc1]

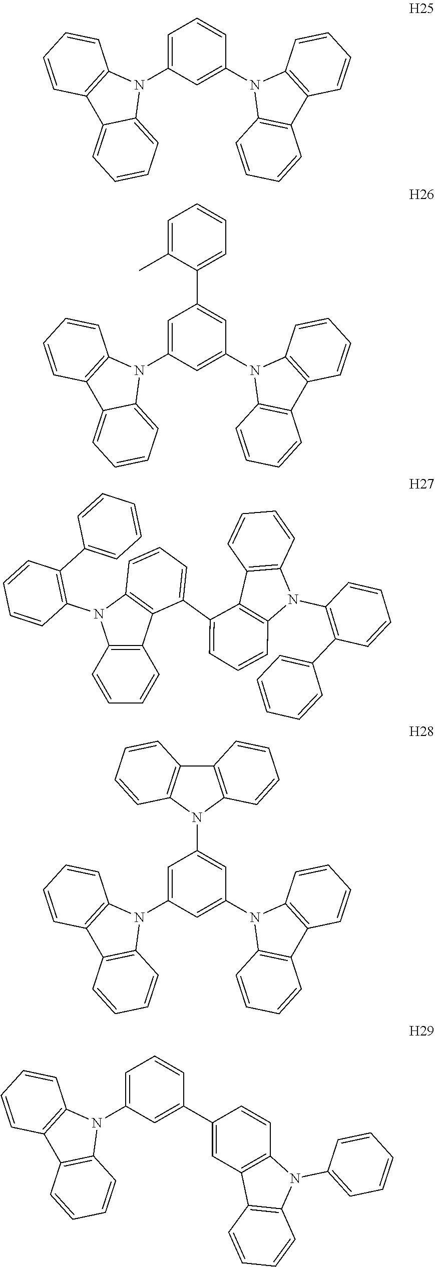

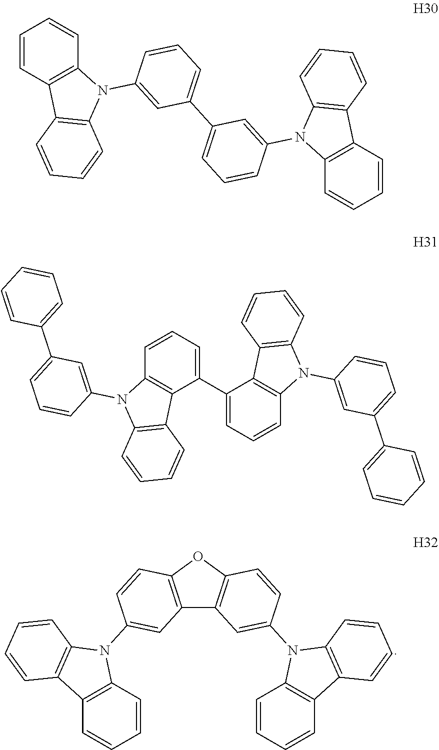 [SMILES: c1cc(-c2cccc(-n3c4ccccc4c4ccccc43)c2)cc(-n2c3ccccc3c3ccccc32)c1 ; c1ccc(-c2cccc(-n3c4ccccc4c4c(-c5cccc6c5c5ccccc5n6-c5cccc(-c6ccccc6)c5)cccc43)c2)cc1 ; c1ccc2c(c1)c1ccccc1n2-c1ccc2oc3ccc(-n4c5ccccc5c5ccccc54)cc3c2c1]

In one embodiment, the first material may not be an amine-based compound.

In one or more embodiments, the first material may not be 1,3-bis(9-carbazolyl/benzene (mCP), tris(4-carbazoyl-9-ylphenyl)amine (TCTA), 4,4′-bis(N-carbazolyl)-1,1′-biphenyl (CBP), 3,3-bis(carbazol-9-yl)biphenyl (mCBP), N,N′-di(1-naphthyl)-N,N′-diphenyl-(1,1′-biphenyl)-4,4′-diamine (NPB), 4,4′,4″-tris[phenyl(m-tolyl)amino]triphenylamine (m-MTDATA), or N,N′-bis(3-methylphenyl)-N,N′-diphenylbenzidine (TPD).

In one or more embodiments, the second material may include a compound represented by Formula E-1:

[Ar₃₀₁]_{xb11}-[(L₃₀₁)_{xb1}-R₃₀₁]_{xb21}. Formula E-1

In Formula E-1,
Ar₃₀₁ may be a substituted or unsubstituted C₅-C₆₀ carbocyclic group or a substituted or unsubstituted C₁-C₆₀ heterocyclic group,
xb11 may be 1, 2, or 3,
L₃₀₁ may be a single bond, a group represented by the following formulae, a substituted or unsubstituted C₅-C₆₀ carbocyclic group, or a substituted or unsubstituted C₁-C₆₀ heterocyclic group, wherein *, *′, and *″ in the following formulae each indicate a binding site to a neighboring atom:

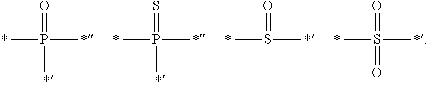

In the formulae above, xb1 may be an integer from 1 to 5, R₃₀₁ may be a hydrogen, a deuterium, —F, —Cl, —Br, —I, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), —S(═O)(Q₃₀₁), —P(═O)(Q₃₀₁)(Q₃₀₂), or —P(═S)(Q₃₀₁)(Q₃₀₂), xb21 may be an integer from 1 to 5,
Q₃₀₁ to Q₃₀₃ may each independently be a C₁-C₁₀ alkyl group, a C₁-C₁₀ alkoxy group, a phenyl group, a biphenyl group, a terphenyl group, or a naphthyl group, and

<Condition 1>, <Condition2>, <Condition 3>, or a combination thereof may be satisfied.

<Condition 1>

In Formula E-1, Ar₃₀₁, L₃₀₁, R₃₀₁, or a combination thereof may each independently include a π electron-deficient nitrogen-containing cyclic group.

<Condition 2>

In Formula E-1, L₃₀₁ may be a group represented by the following formulae:

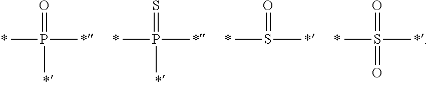

<Condition 3>

In Formula E-1, R₃₀₁ may be a cyano group, —S(═O)₂(Q₃₀₁), —S(═O)(Q₃₀₁), —P(═O)(Q₃₀₁)(Q₃₀₂), —P(═S)(Q₃₀₁)(Q₃₀₂), or a combination thereof.

In one or more embodiments, the second material may include a compound represented by Formula E-1(1), a compound represented by Formula E-1(2), a compound represented by Formula E-1(3), or a combination thereof:

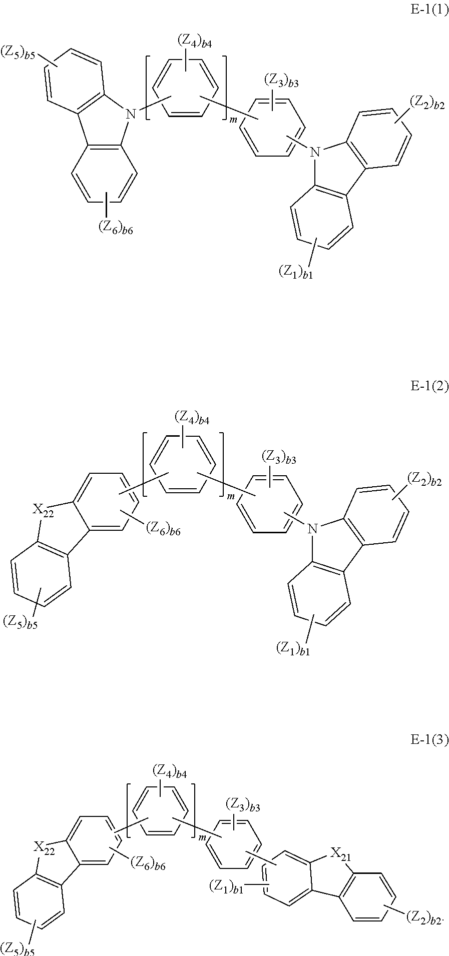

In Formulae E-1(1) to E-1(3),
ring A₁, ring A₂, ring A₅, and ring A₆ may each independently be a benzene group, a naphthalene group, an anthracene group, a phenanthrene group, a triphenylene group, a pyrene group, a chrysene group, a cyclopentadiene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, or a phenanthroline group.

In an exemplary embodiment, ring A₁, ring A₂, ring A₅, and ring A₆ may each independently be a benzene group, a carbazole group, a fluorene group, a dibenzothiophene group, or a dibenzofuran group.

In Formulae E-1(1) to E-1(3), Z₁ to Z₆ may each independently be: a hydrogen, a deuterium, or a cyano group; or
a C₁-C₂₀ alkyl group, a phenyl group, a biphenyl group, a terphenyl group, a dibenzofuranyl group, or a dibenzothiophenyl group, each unsubstituted or substituted with a deuterium, a cyano group, a C₁-C₂₀ alkyl group, a phenyl group, a biphenyl group, or a combination thereof.

In an exemplary embodiment, in Formulae E-1(1) to E-1(3), Z₁ to Z₆ may each independently be:
a hydrogen, a deuterium or a cyano group; or
a C₃-C₁₀ alkyl group, a phenyl group, a biphenyl group, a terphenyl group, a dibenzofuranyl group, or a dibenzothiophenyl group, each unsubstituted or substituted with a deuterium, a cyano group, a C₃-C₁₀ alkyl group, a phenyl group, a biphenyl group, or a combination thereof.

In one embodiment, in Formulae E-1(1) to E-1(3), Z₁ to Z₆ may each independently be:
a hydrogen, a deuterium or a cyano group; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a biphenyl group, or a terphenyl group, each unsubstituted or substituted with a deuterium, a cyano group, an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a biphenyl group, or a combination thereof.

In Formulae E-1(1) to E-1(3), b1 to b6 indicate the number of Z₁ to Z₆, respectively, and may each independently be 1, 2, or 3. When b1 to b6 are each two or more, two or more Z₁ to Z₆ may be identical to or different from each other.

In one embodiment, in Formulae E-1(1) to E-1(3), Z₁, Z₂, Z₃, Z₄, Z₅, R₆, or a combination thereof, may be a cyano group.

In an exemplary embodiment, the number of cyano groups included in the compound represented by Formula E-1(1), the number of cyano groups included in the compound represented by Formula E-1(2), and the number of cyano groups included in the compound represented by Formula E-1(3) may each independently be 1, 2, or 3, but embodiments of the present disclosure are not limited thereto.

In one embodiment, in Formulae E-1(1) to E-1(3),
Z₁, Z₂, or a combination thereof may be a cyano group,
Z₃, Z₄, or a combination thereof may be a cyano group,
Z₅, Z₆, or a combination thereof may be a cyano group,
Z₁, Z₂, or a combination thereof may be a cyano group, and Z₃, Z₄, or a combination thereof may be a cyano group,
Z₁, Z₂, or a combination thereof may be a cyano group, and Z₅, Z₆, or a combination thereof may be a cyano group,
Z₃, Z₄, or a combination thereof may be a cyano group, and Z₅, Z₆, or a combination thereof may be a cyano group, or
Z₁, Z₂, or a combination thereof may be a cyano group, Z₃, Z₄, or a combination thereof may be a cyano group, and Z₅, Z₆, or a combination thereof may be a cyano group.

In Formulae E-1(1) to E-1(3), X₂₁ and X₂₂ may each independently be O or S, and m may be 0 or 1.

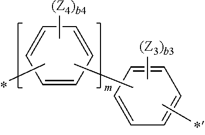

In one embodiment, a group represented by in Formulae E-1(1) to E-1(3) may be a group represented by Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, or P1 to P9:

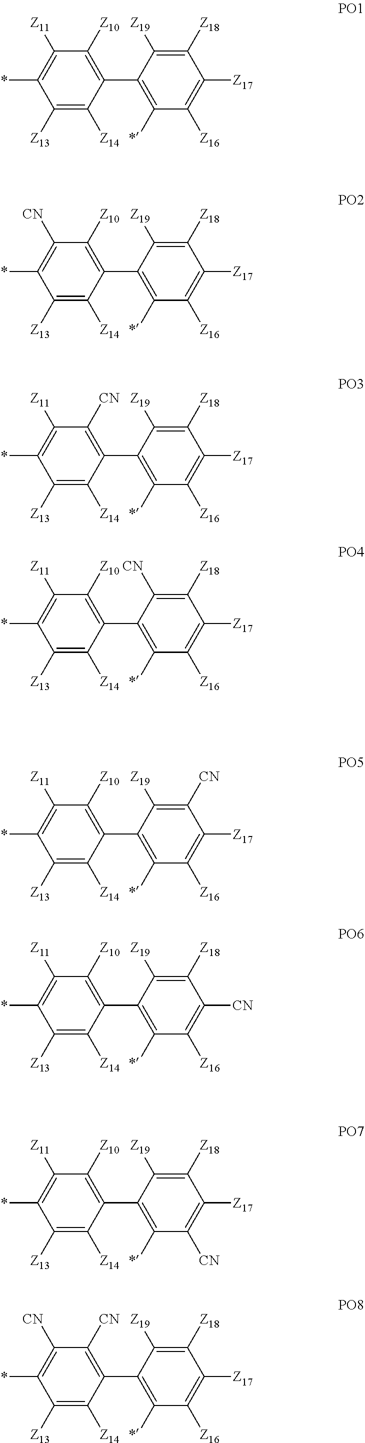

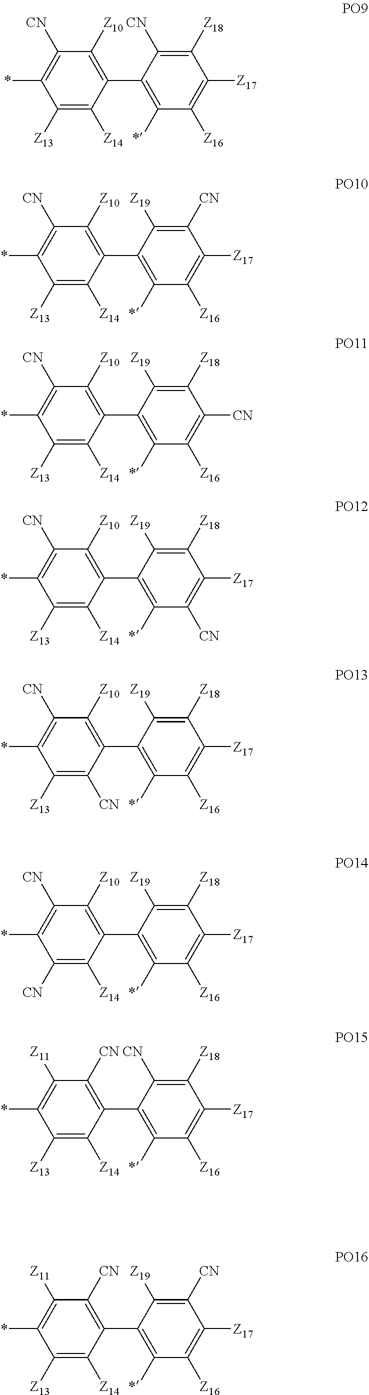

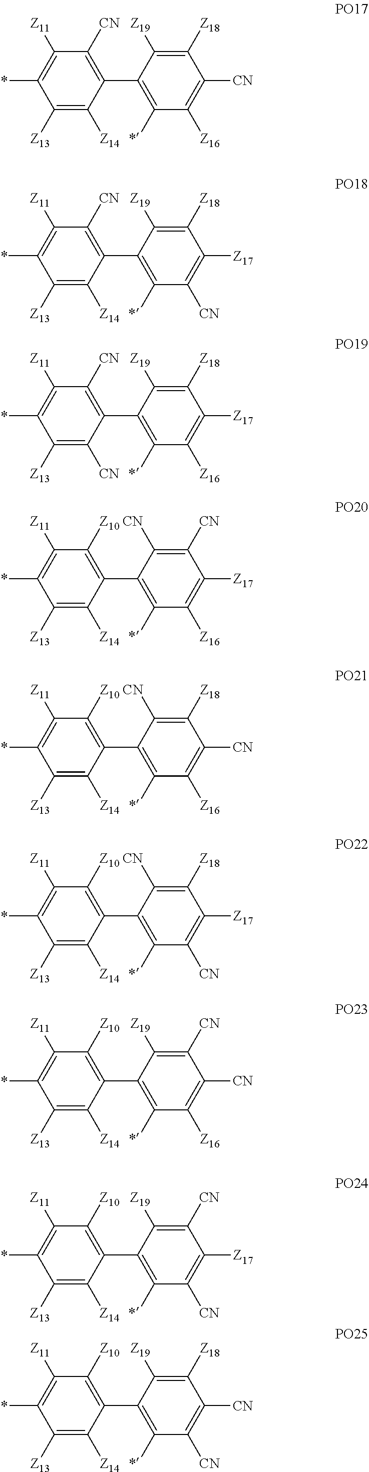

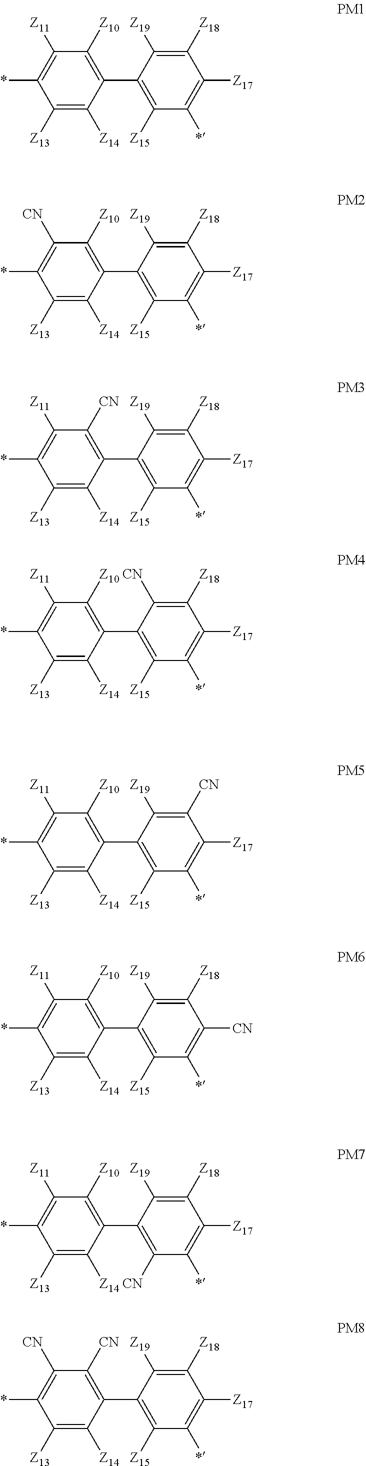

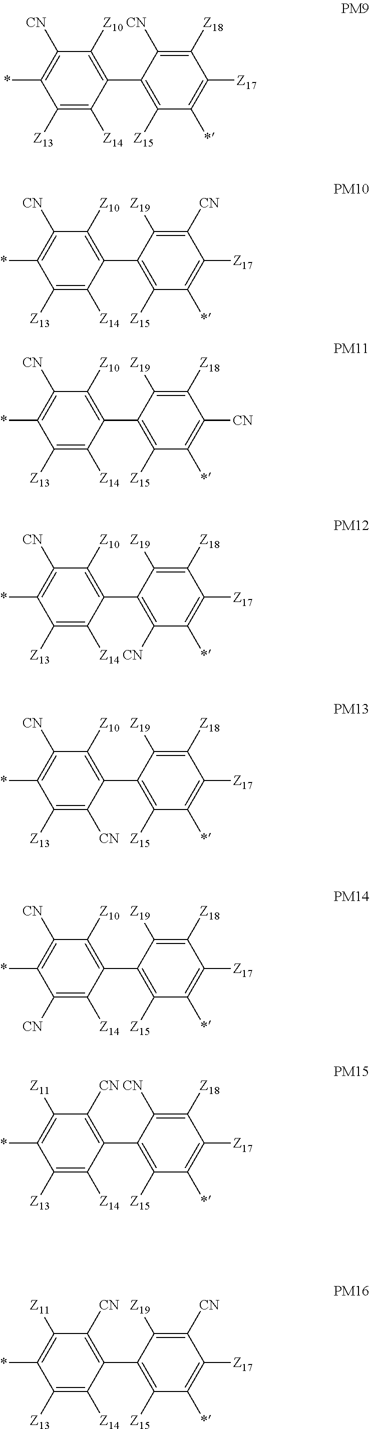

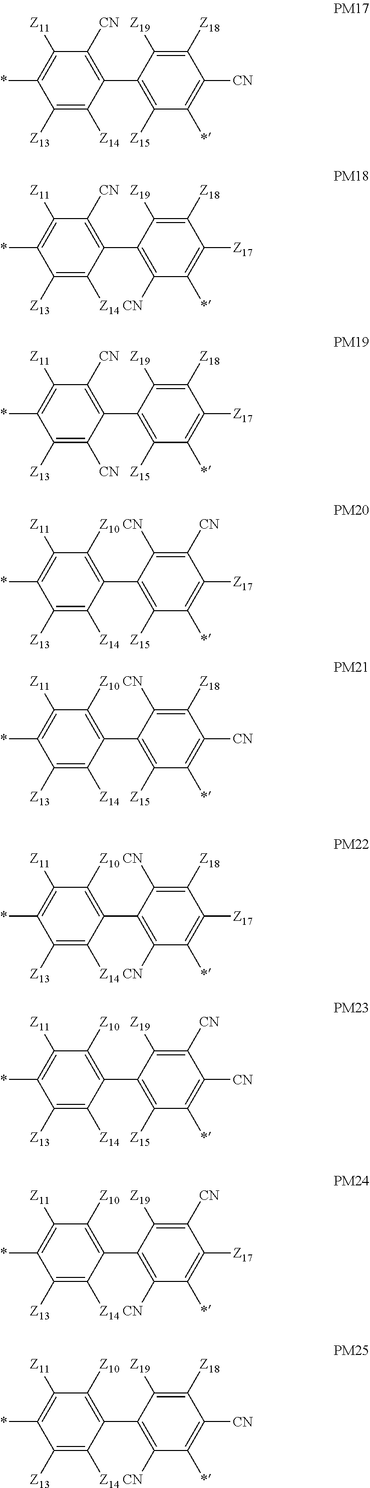

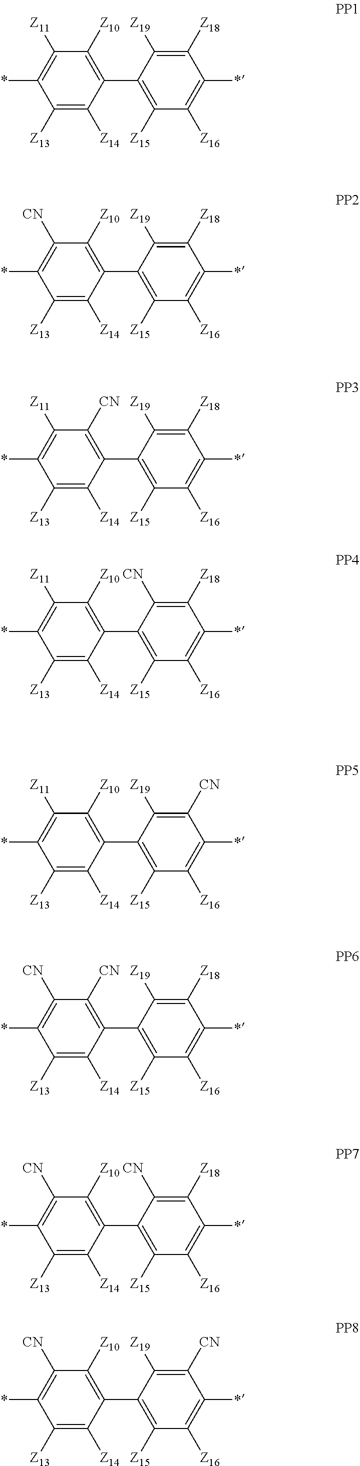

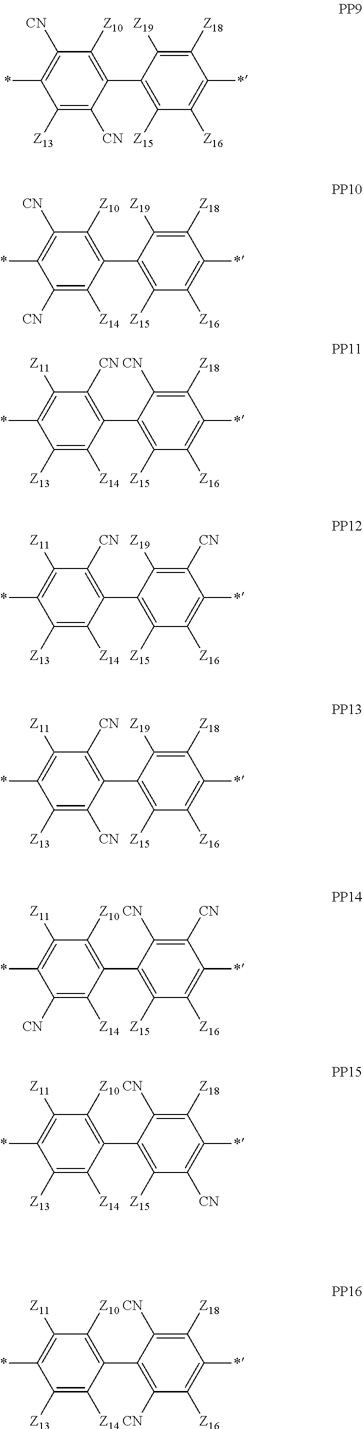

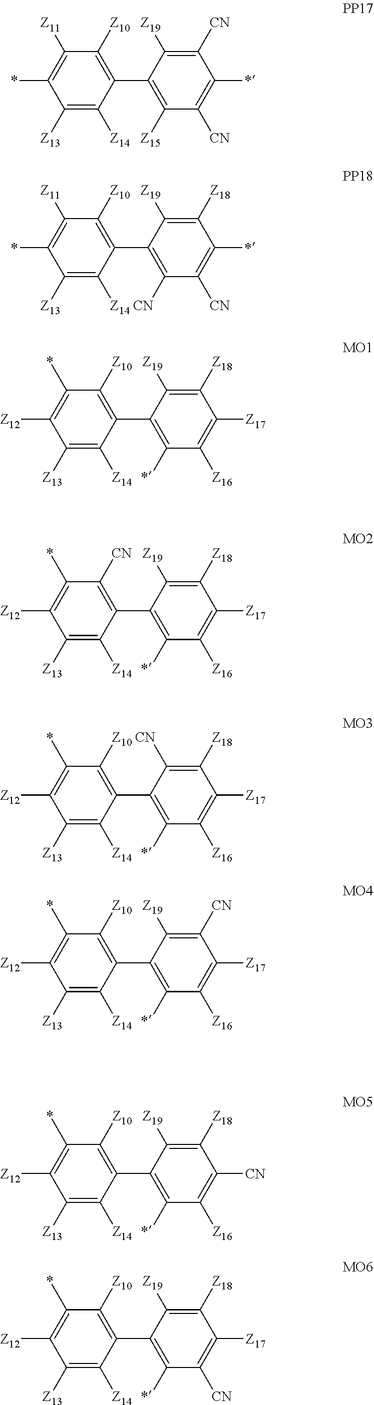

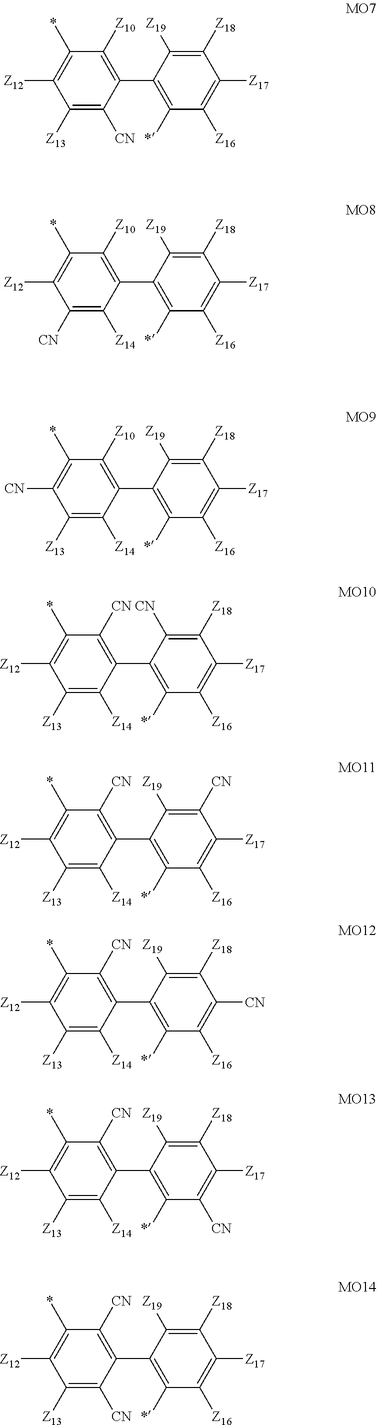

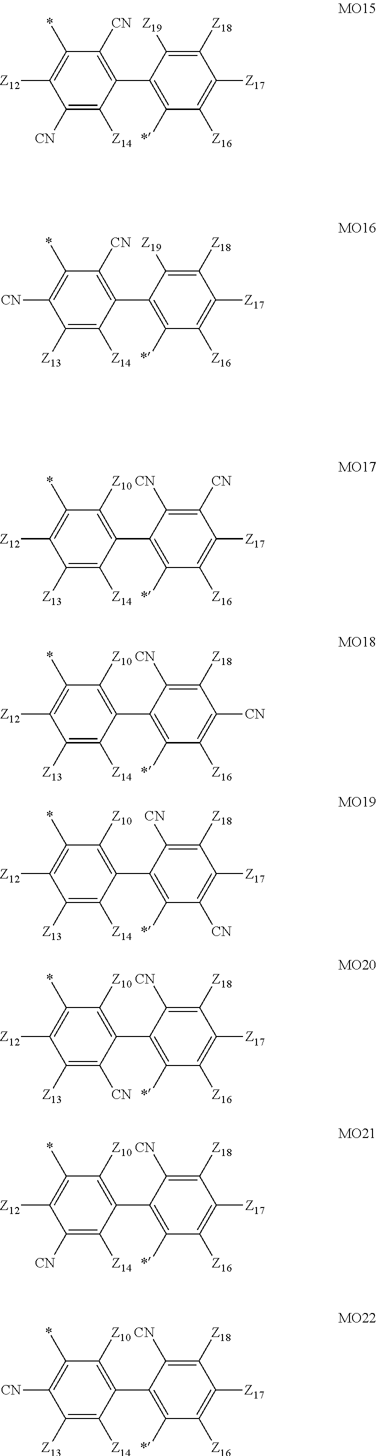

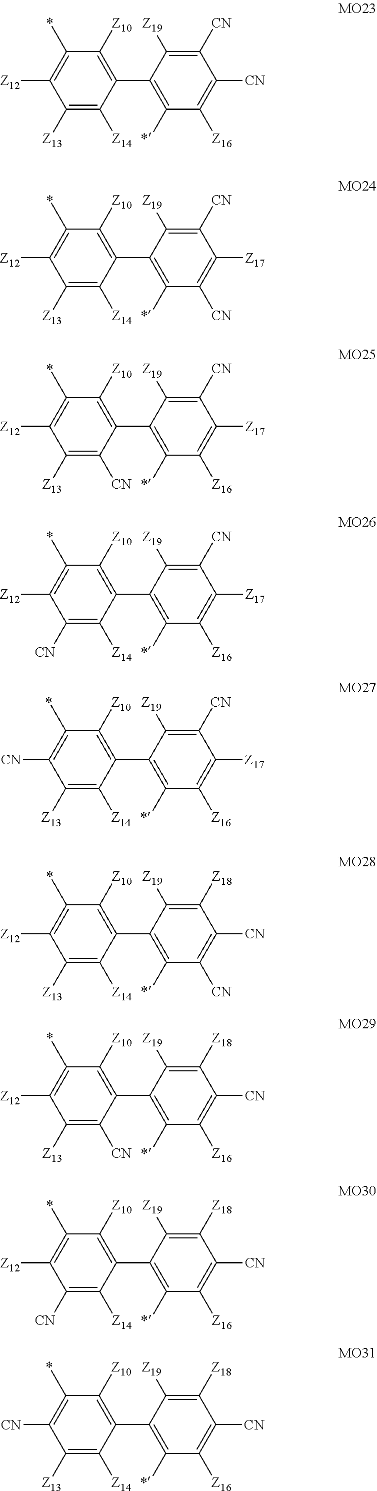

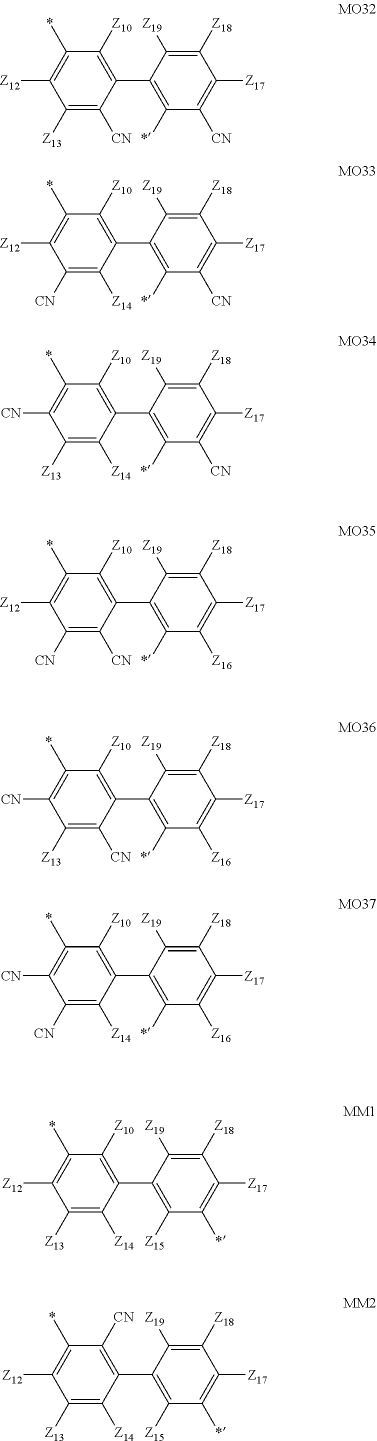

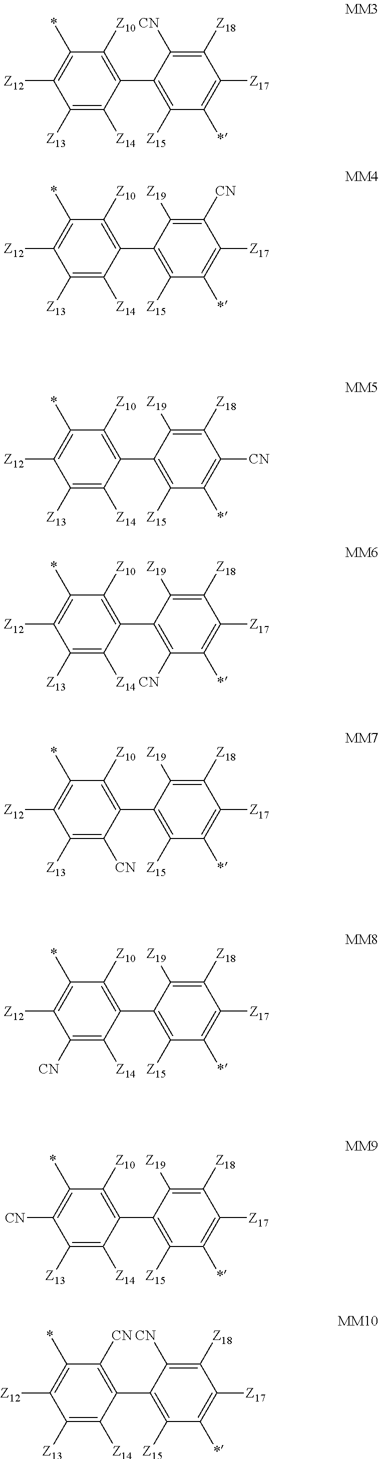

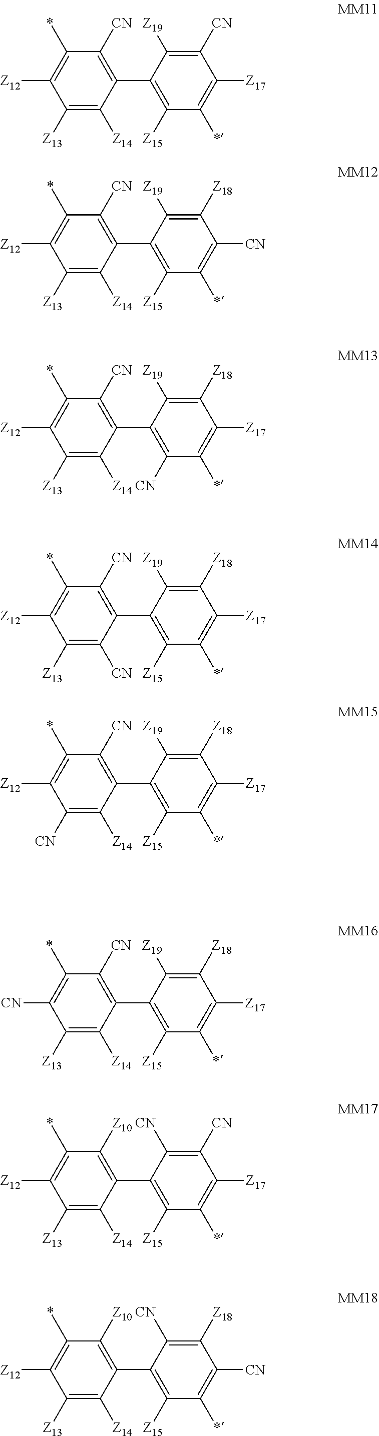

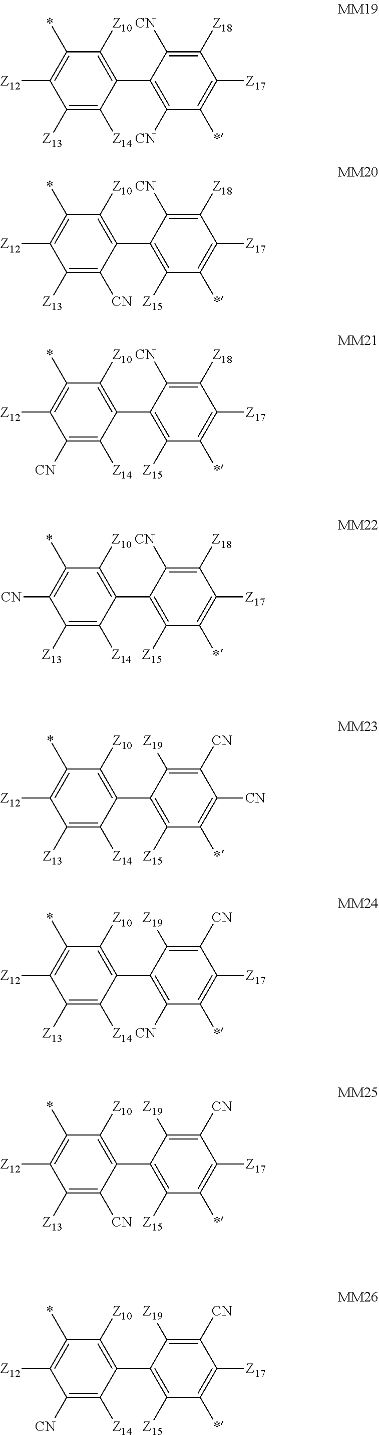

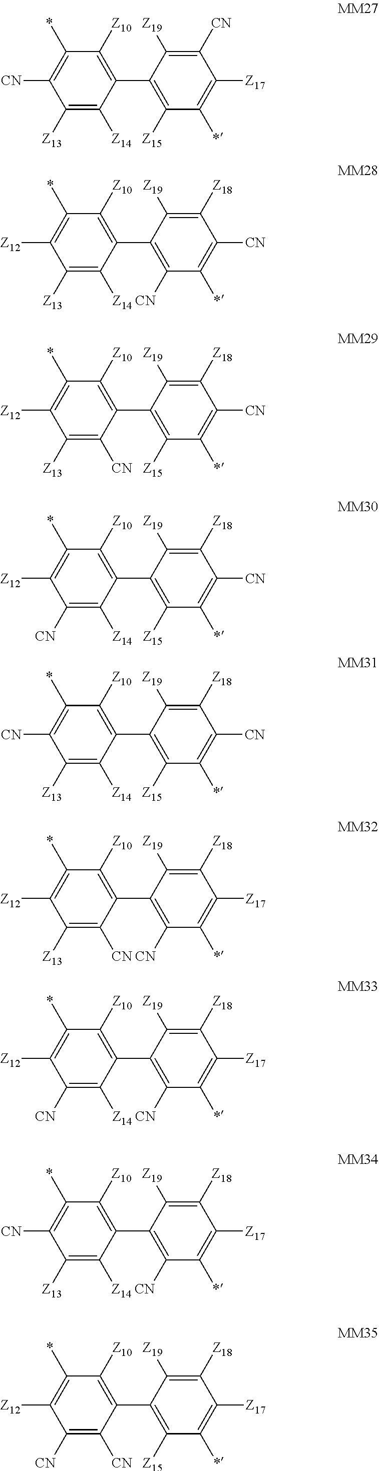

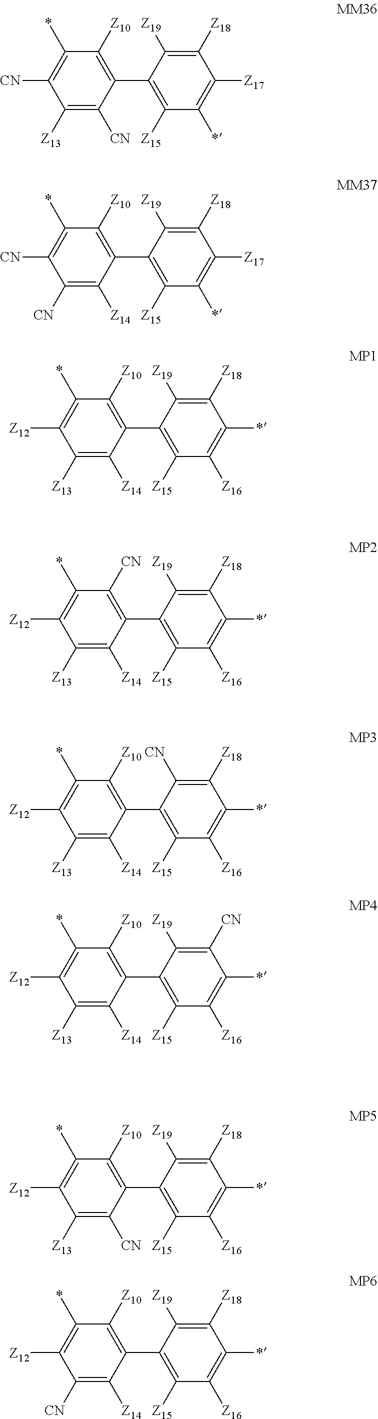

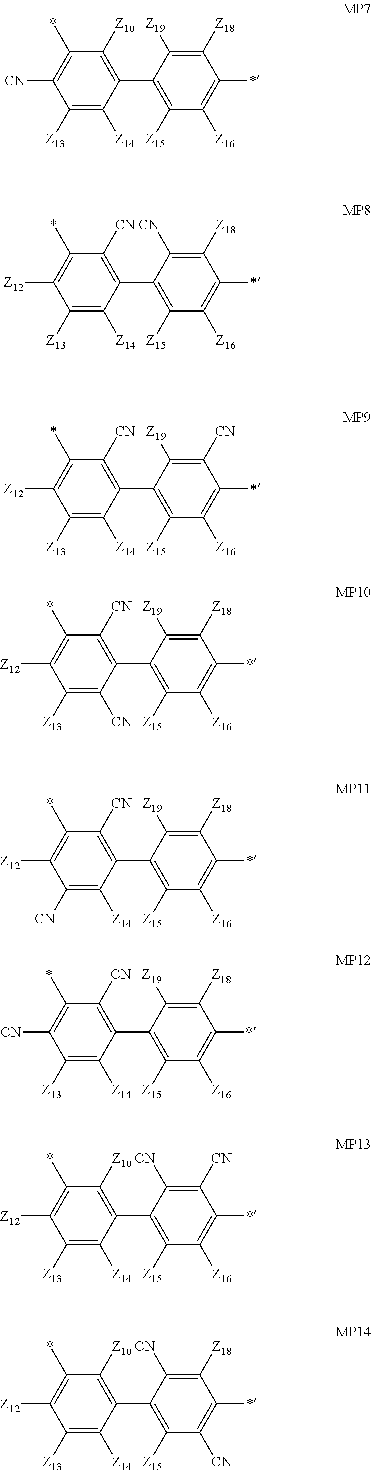

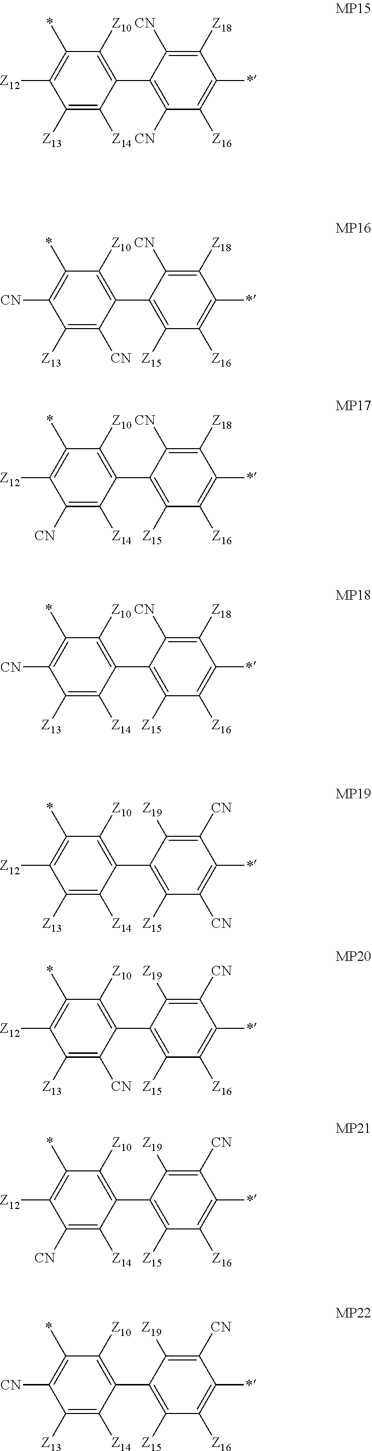

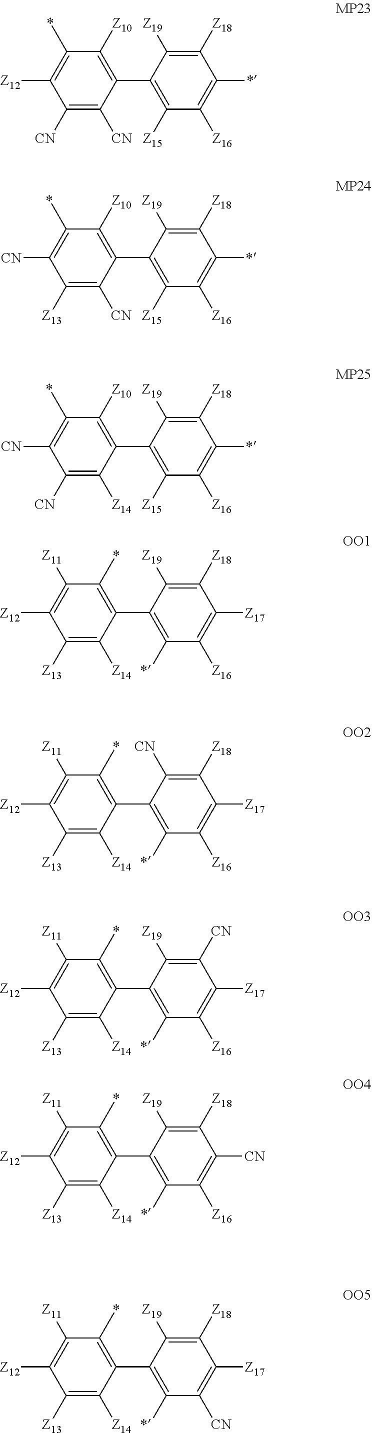

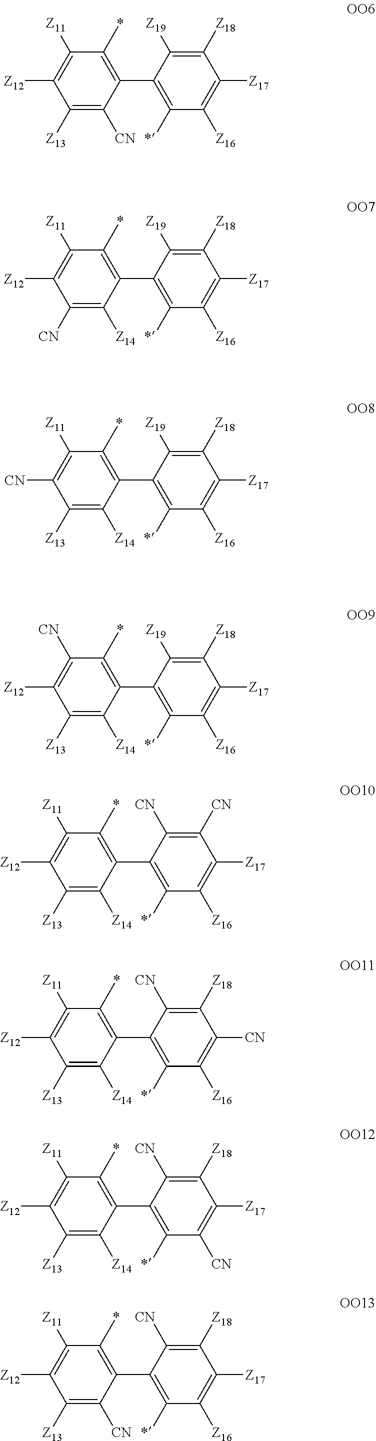

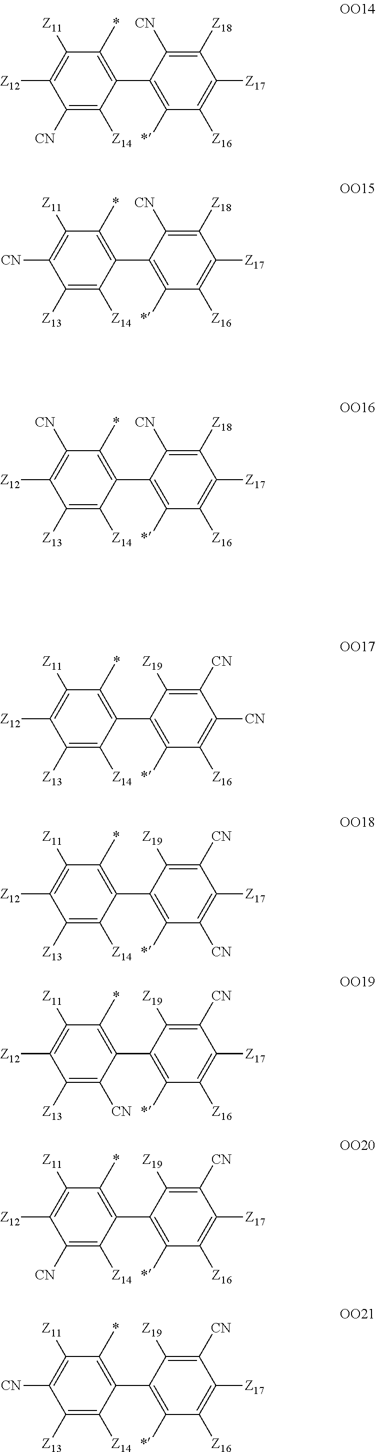

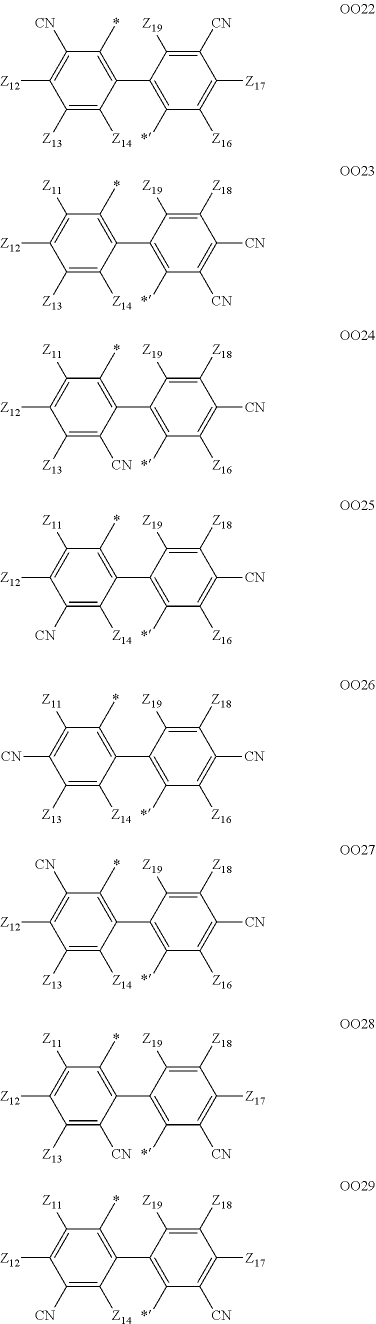

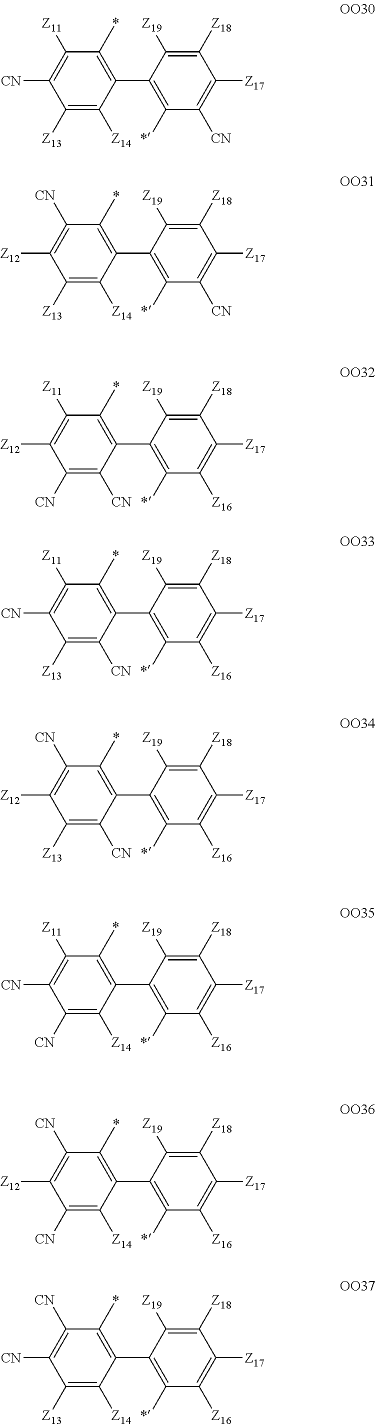

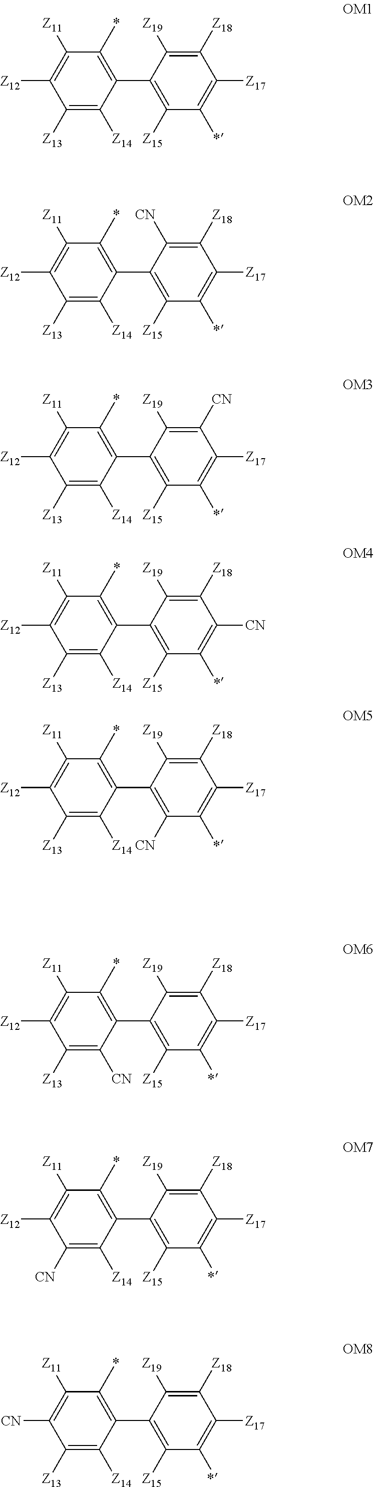

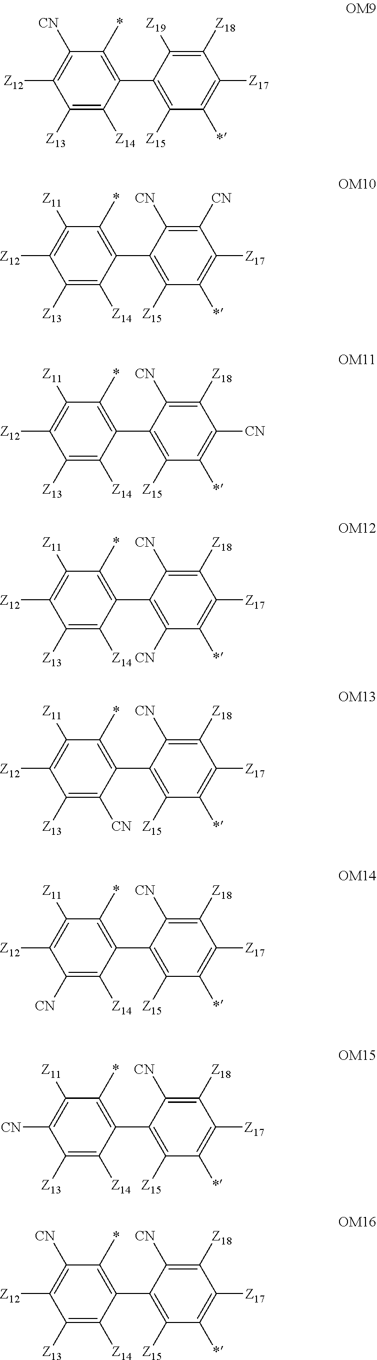

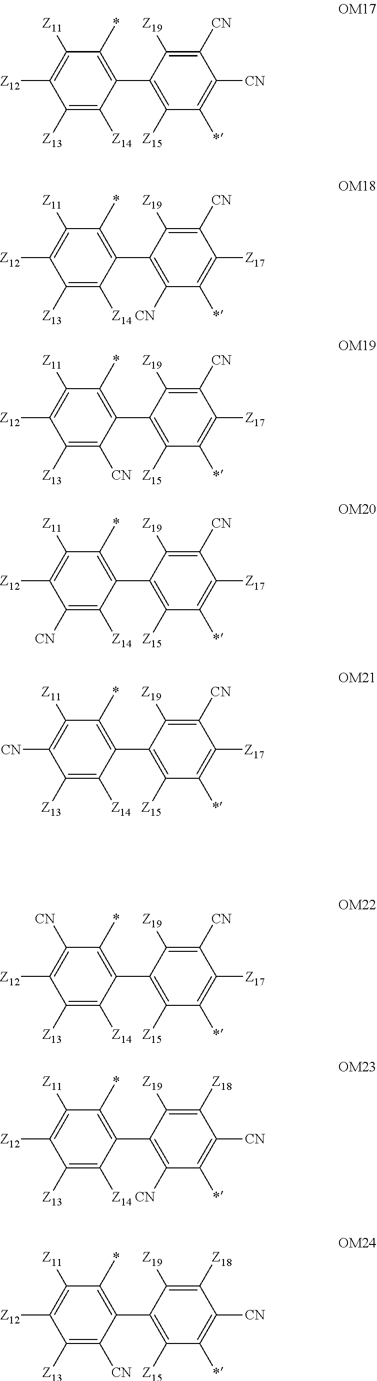

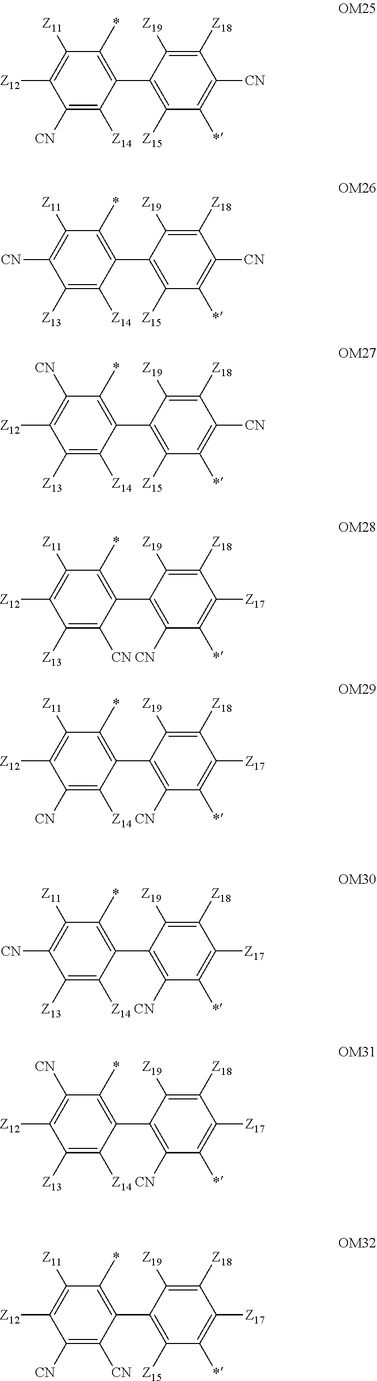

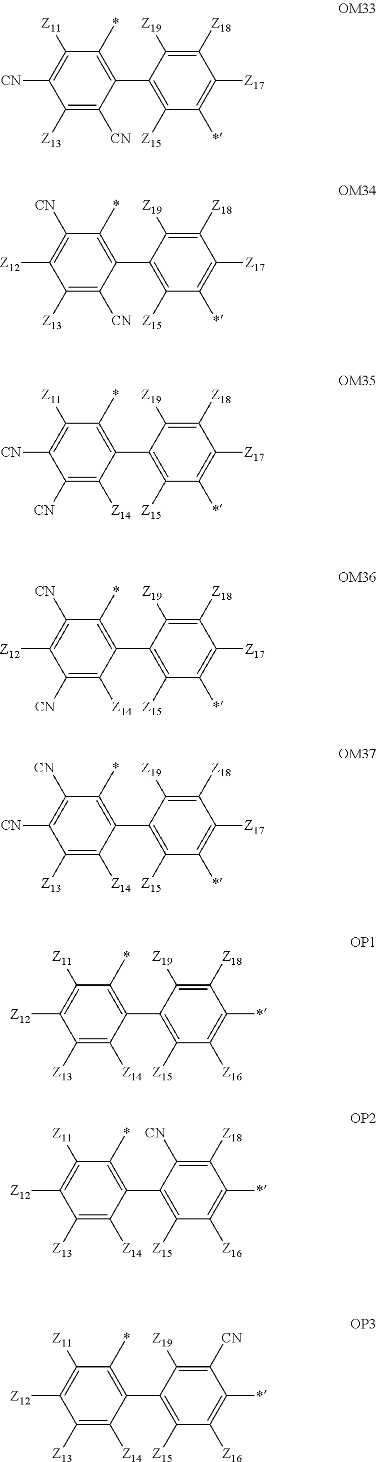

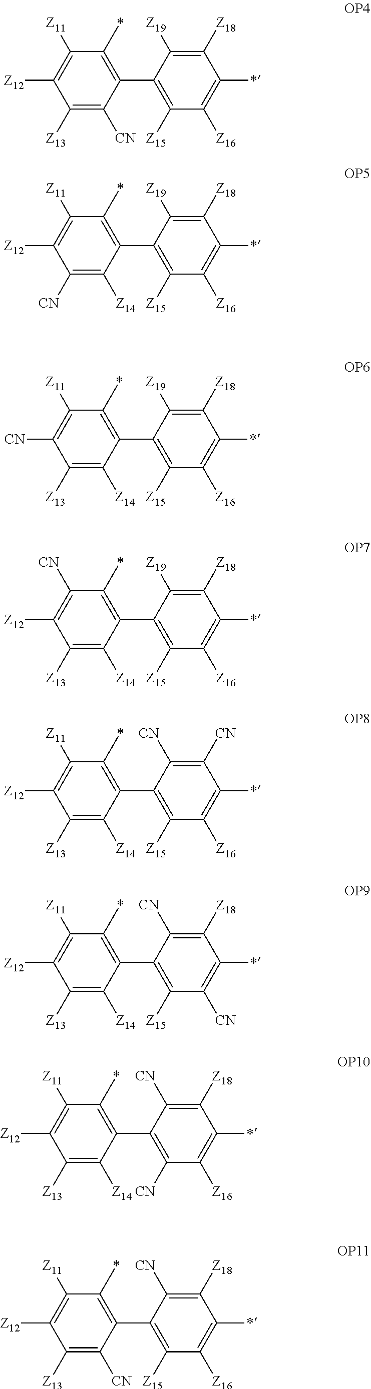

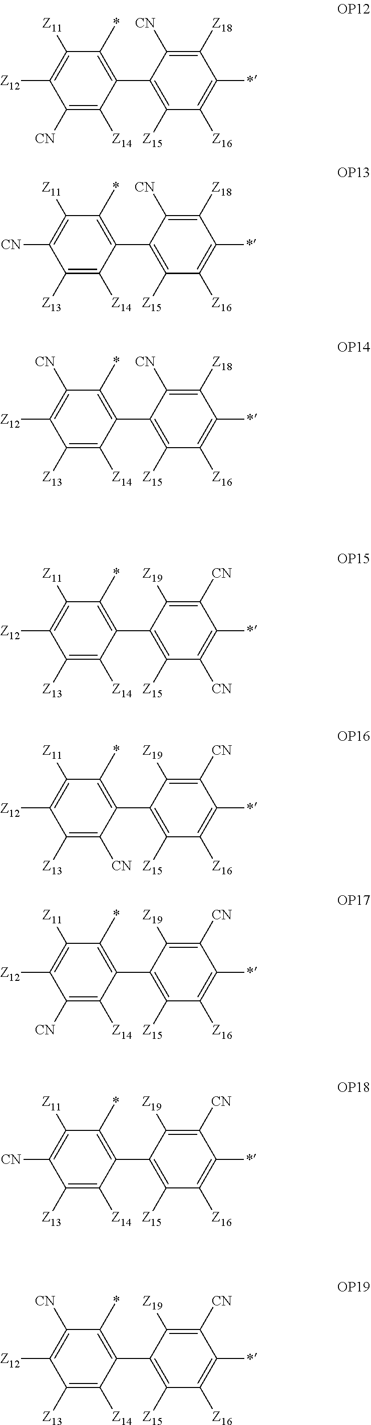

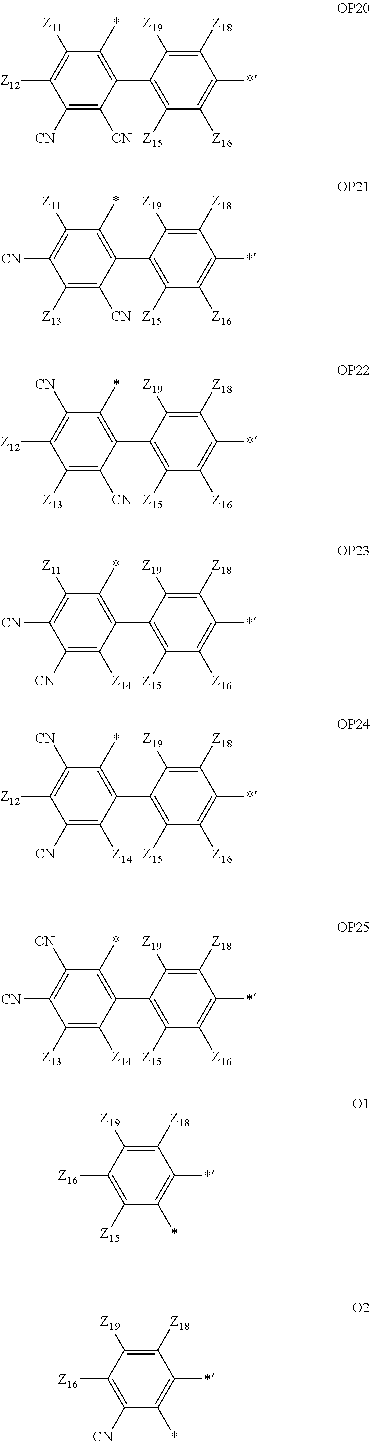

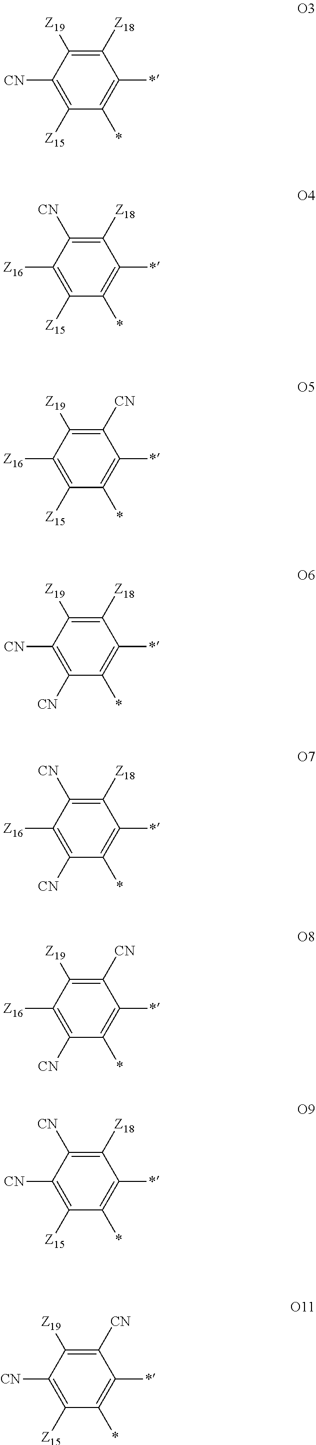

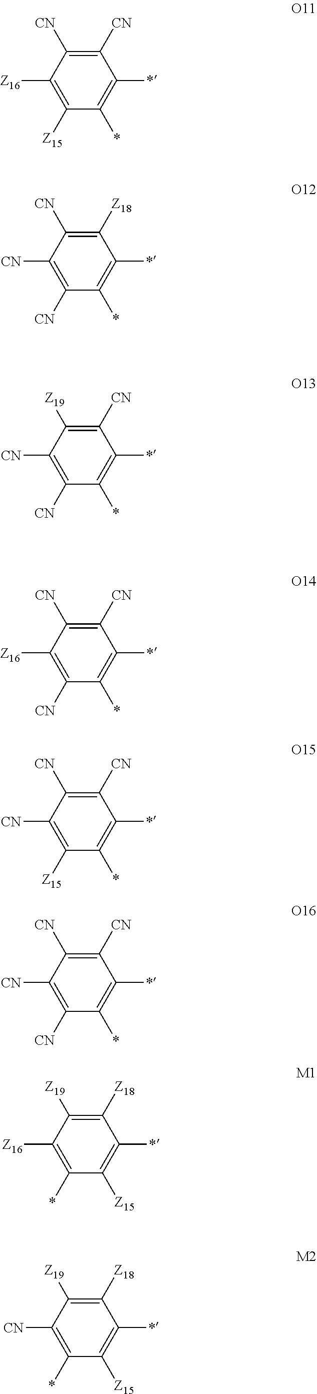

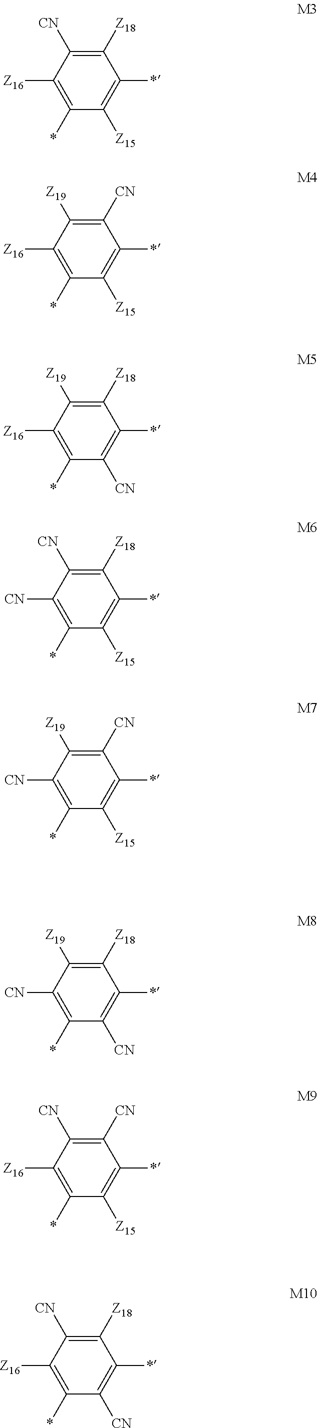

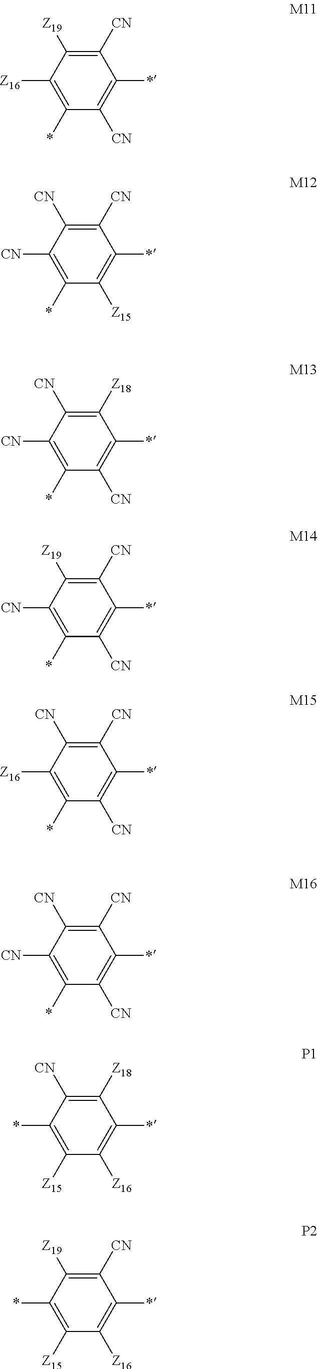

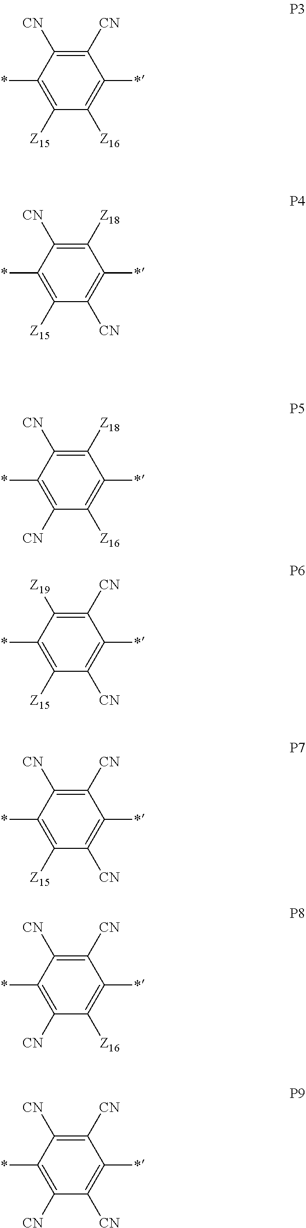

In Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ may each independently be the same as described in connection with Z₃ and Z_{4,} and * and *′ each indicate a binding site to a neighboring atom.

In one embodiment, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ may not be a cyano group.

In one or more embodiments, in Formulae PO1 to PO25, PM1 to PM25, PP1 to PP18, MO1 to MO37, MM1 to MM37, MP1 to MP25, OO1 to OO37, OM1 to OM37, OP1 to OP25, O1 to O16, M1 to M16, and P1 to P9, Z₁₀ to Z₁₉ may each independently be:
a hydrogen, a deuterium, or a cyano group; or
a C₁-C₂₀ alkyl group, a phenyl group, a biphenyl group, a terphenyl group, a dibenzofuranyl group, or a dibenzothiophenyl group, each unsubstituted or substituted with a deuterium, a cyano group, a C₁-C₂₀ alkyl group, a phenyl group, a biphenyl group, or a combination thereof.

In one embodiment, the second material may include Compounds E1 to E8, but embodiments of the present disclosure are not limited thereto:

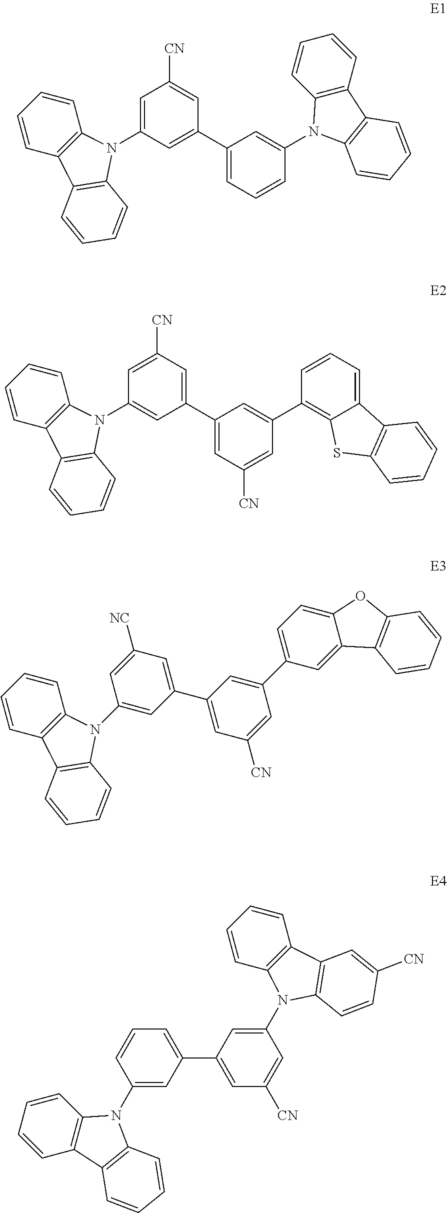 [SMILES: N#Cc1cc(-c2cccc(-n3c4ccccc4c4ccccc43)c2)cc(-n2c3ccccc3c3ccccc32)c1 ; N#Cc1cc(-c2cc(C#N)cc(-n3c4ccccc4c4ccccc43)c2)cc(-c2cccc3c2sc2ccccc23)c1 ; N#Cc1cc(-c2cc(C#N)cc(-n3c4ccccc4c4ccccc43)c2)cc(-c2ccc3oc4ccccc4c3c2)c1 ; N#Cc1cc(-c2cccc(-n3c4ccccc4c4ccccc43)c2)cc(-n2c3ccccc3c3cc(C#N)ccc32)c1]

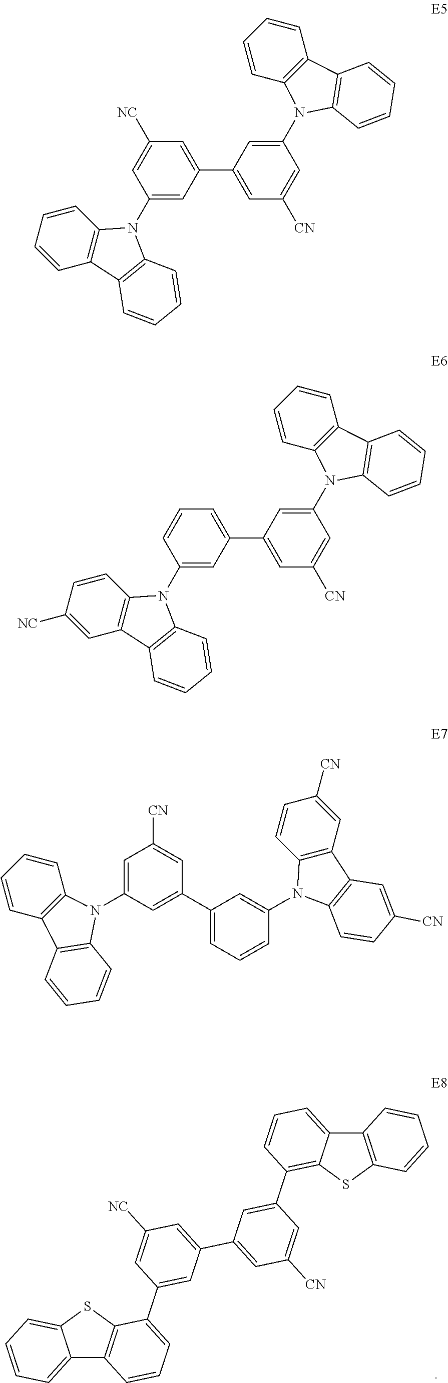 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccc(C#N)cc4c4cc(C#N)ccc43)c2)cc(-n2c3ccccc3c3ccccc32)c1 ; N#Cc1cc(-c2cc(C#N)cc(-c3cccc4c3sc3ccccc34)c2)cc(-c2cccc3c2sc2ccccc23)c1]

A difference between a triplet energy level (eV) of the host and a triplet energy level (eV) of the thermally activated delayed fluorescence emitter may be in a range of about 0.2 eV to about 0.5 eV. When the difference between the triplet energy level (eV) of the host and the triplet energy level (eV) of the thermally activated delayed fluorescence emitter is within this range, energy of the triplet exciton generated in the thermally activated delayed fluorescence emitter may be prevented from leaking toward the host in the emission layer, thereby achieving efficient light emission. The activated excitation energy level of the host may be suppressed, thereby implementing long lifespan driving of an organic light-emitting device.

The triplet energy level may be evaluated by using a DFT method of Gaussian program structurally optimized at a level of B3LYP/6-31G(d,p).

An amount of the thermally activated delayed fluorescence emitter in the emission layer may be in a range of about 0.01 parts by weight to about 30 parts by weight based on 100 parts by weight of the host, but embodiments of the present disclosure are not limited thereto. When the amount of the thermally activated delayed fluorescence emitter is within this range, high-quality organic light-emitting devices may be implemented without concentration quenching.

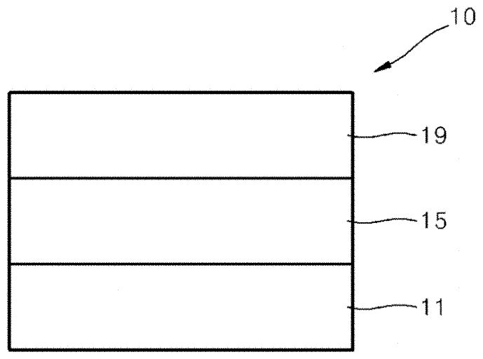

FIG. 1 is a schematic view of an exemplary embodiment of an organic light-emitting device 10. Hereinafter, the structure of an exemplary embodiment of an organic light-emitting device and an exemplary embodiment of a method of manufacturing an organic light-emitting device will be described in connection with FIG. 1. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent polymeric substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), or zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. In an exemplary embodiment, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include a hole injection layer, a hole transport layer, an electron blocking layer, a buffer layer, or a combination thereof.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

A hole injection layer may be formed on the first electrode 11 by using one or more suitable methods selected from vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. In an exemplary embodiment, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec. However, the deposition conditions are not limited thereto.

When the hole injection layer is formed using spin coating, coating conditions may vary according to the material used to form the hole injection layer, and the structure and thermal properties of the hole injection layer. In an exemplary embodiment, a coating speed may be from about 2,000 rpm to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202, or a combination thereof:

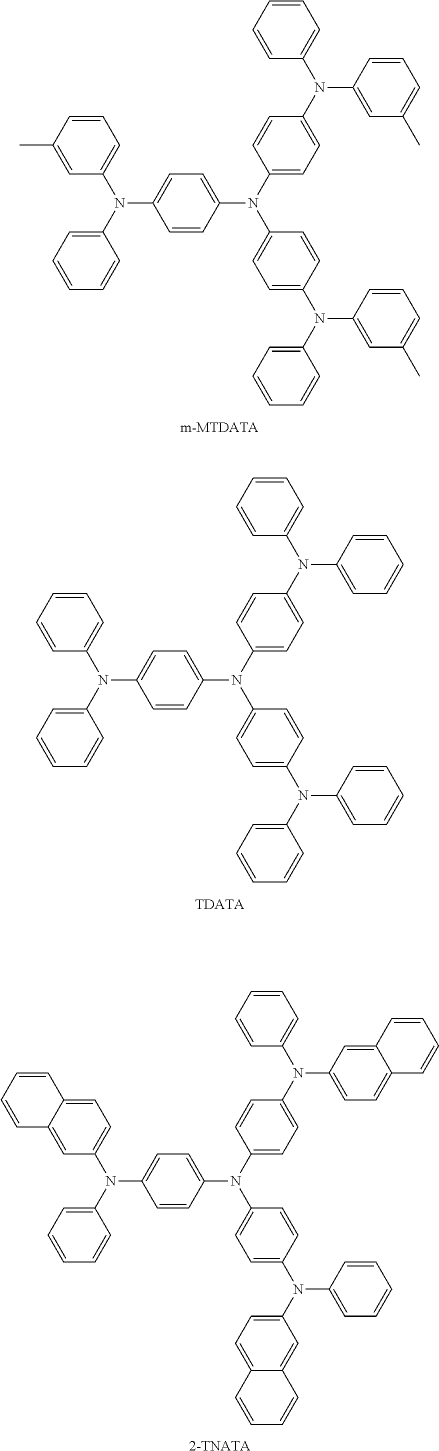

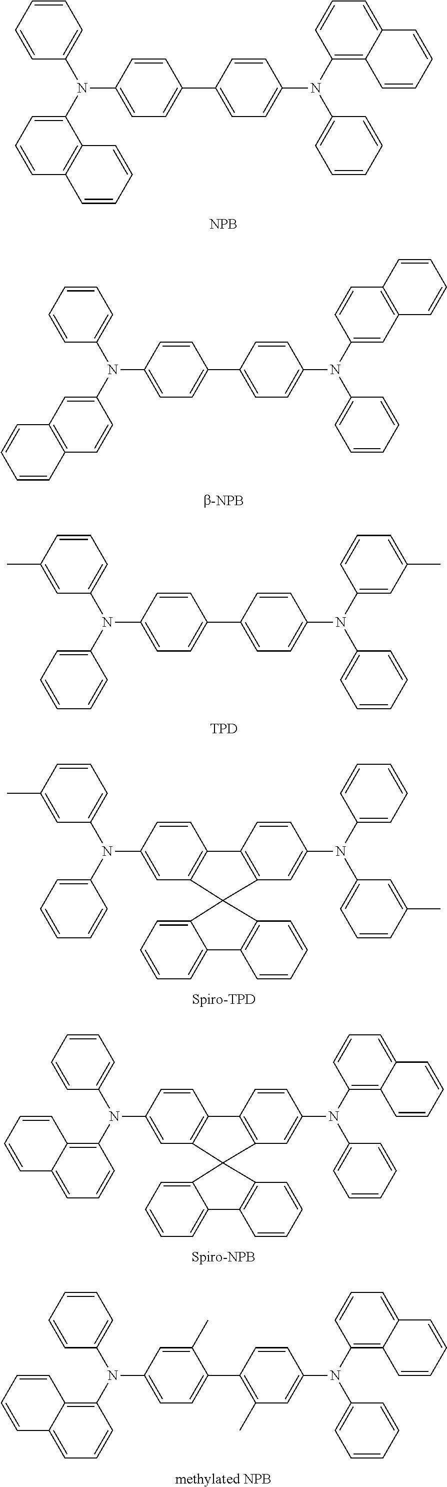

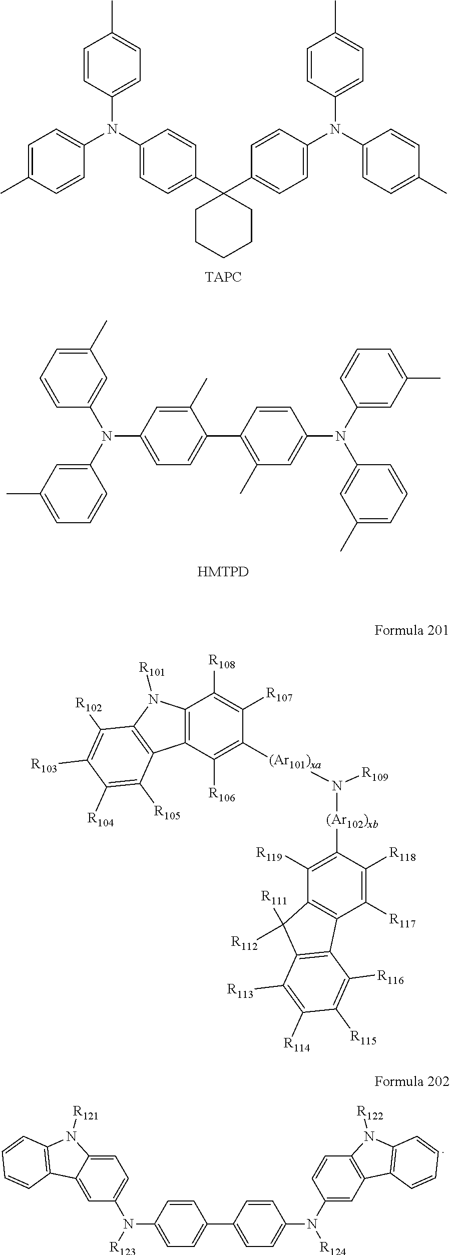

Ar₁₀₁ and Ar₁₀₂ in Formula 201 may each independently be:
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group; or
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each substituted with a deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₂-C₁₀ heterocycloalkyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group.

In Formula 201, xa and xb may each independently be an integer from 0 to 5, or may be 0, 1, or 2. In an exemplary embodiment, xa may be 1 and xb may be 0, but embodiments of the present disclosure are not limited thereto.

R₁₀₁ to R₁₀₈, R₁₁₁ to R₁₁₉, and R₁₂₁ to R₁₂₄ in Formulae 201 and 202 may each independently be:
a hydrogen, a deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a C₁-C₁₀ alkyl group (for example, a methyl group, an ethyl group, a propyl group, a butyl group, a pentyl group, a hexyl group, and the like), or a C₁-C₁₀ alkoxy group (for example, a methoxy group, an ethoxy group, a propoxy group, a butoxy group, a pentoxy group, and the like);
a C₁-C₁₀ alkyl group or a C₁-C₁₀ alkoxy group, each substituted with a deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof;
a phenyl group, a naphthyl group, an anthracenyl group, a fluorenyl group, and a pyrenyl group; or
a phenyl group, a naphthyl group, an anthracenyl group, a fluorenyl group, and a pyrenyl group, each substituted with a deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or a combination thereof, but embodiments of the present disclosure are not limited thereto.

R₁₀₉ in Formula 201 may be: a phenyl group, a naphthyl group, an anthracenyl group, and a pyridinyl group; or
a phenyl group, a naphthyl group, an anthracenyl group, and a pyridinyl group, each substituted with deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or a combination thereof.

In one embodiment, the compound represented by Formula 201 may be represented by Formula 201A, but embodiments of the present disclosure are not limited thereto:

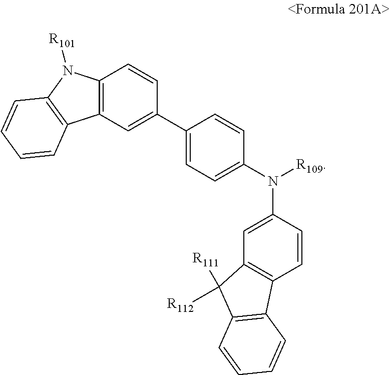

R₁₀₁, R₁₁₁, R₁₁₂, and R₁₀₉ in Formula 201A are the same as described above.

In an exemplary embodiment, the compound represented by Formula 201, and the compound represented by Formula 202 may include Compounds HT1 to HT20, but embodiments of the present disclosure are not limited thereto:

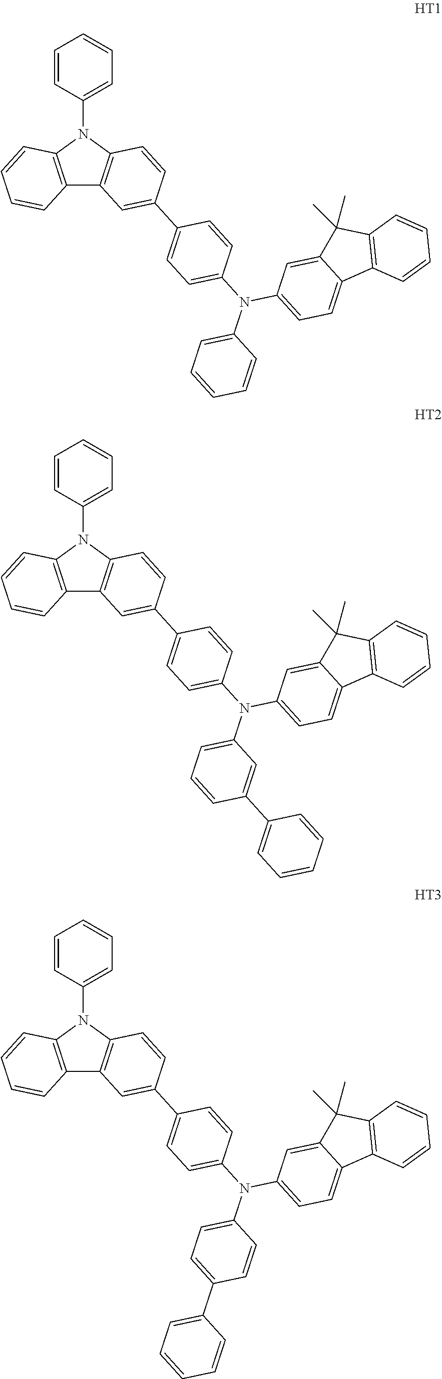 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

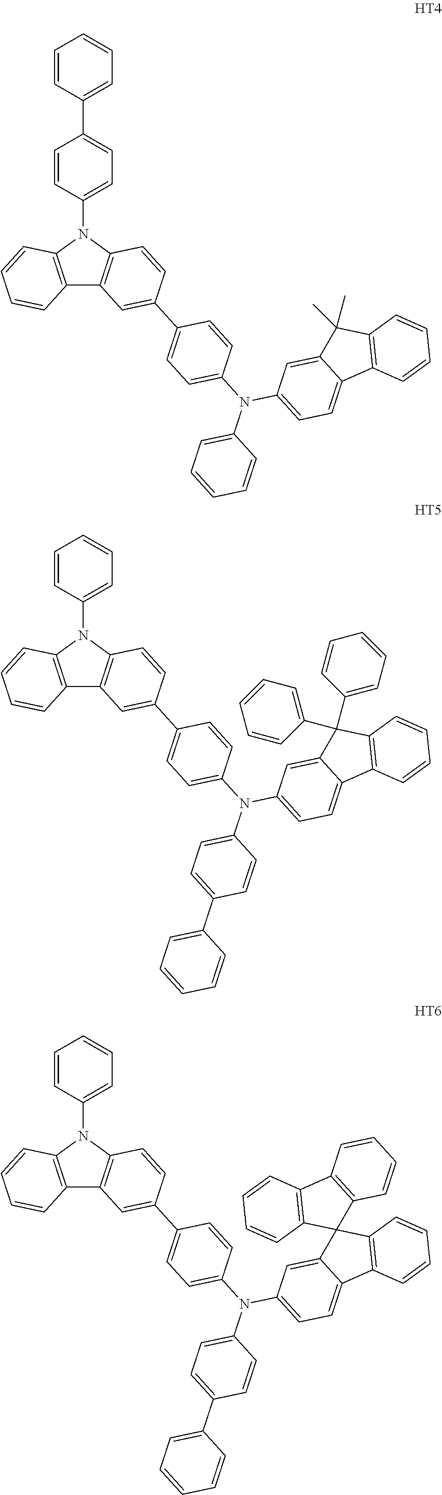 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

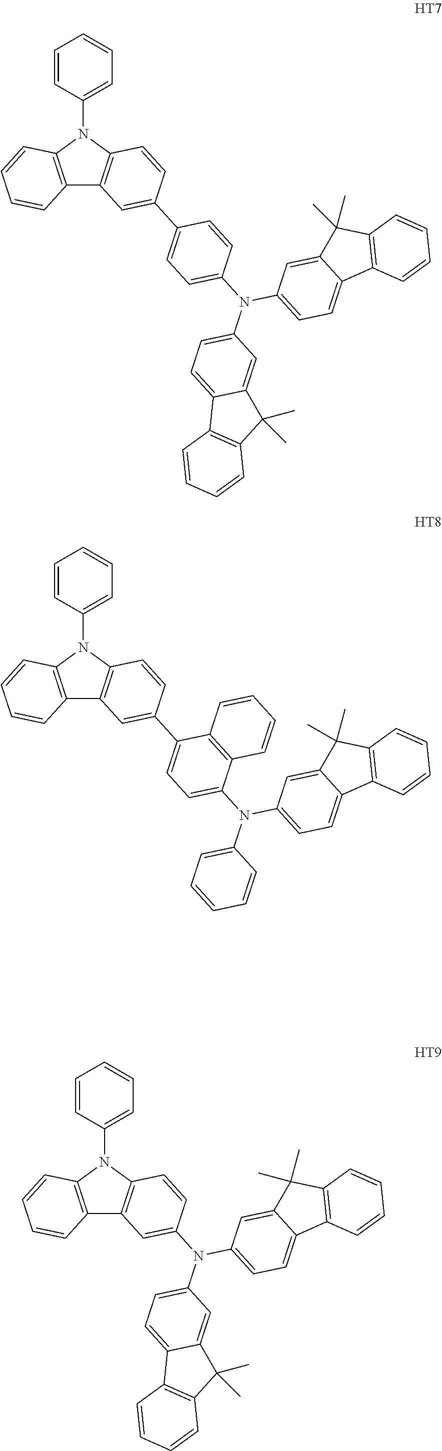 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

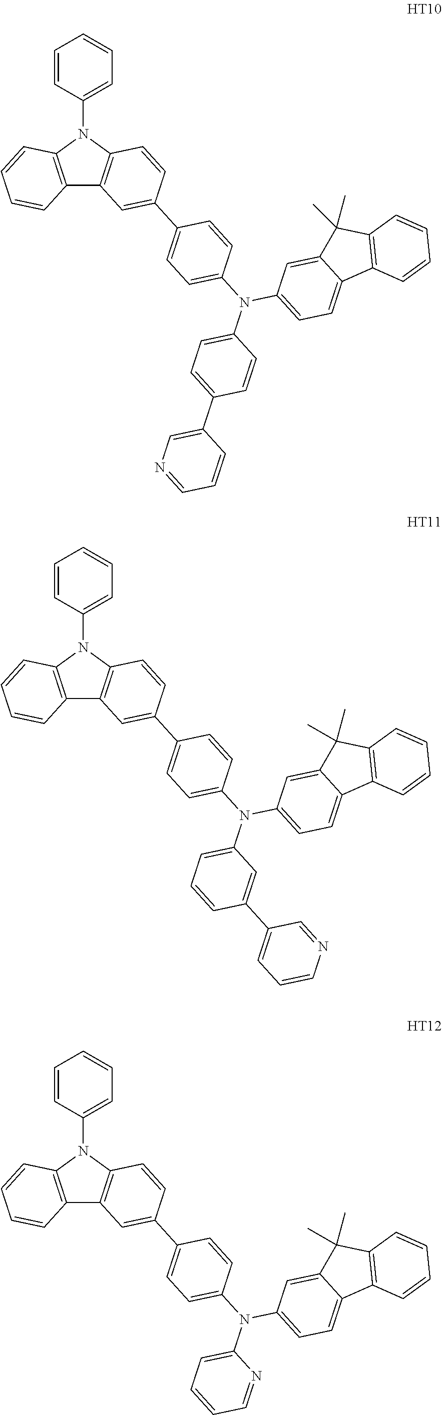 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

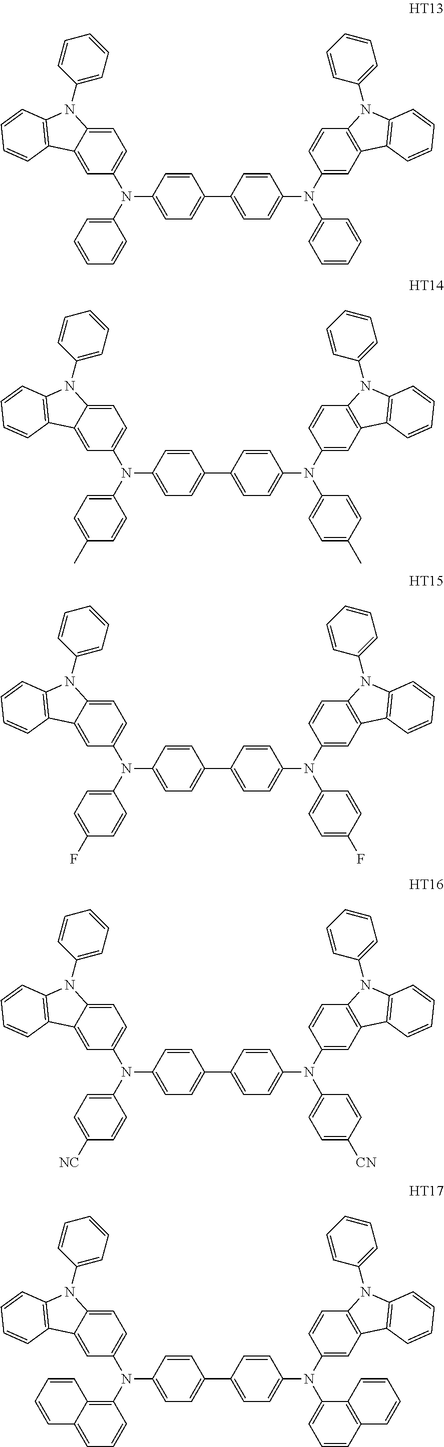

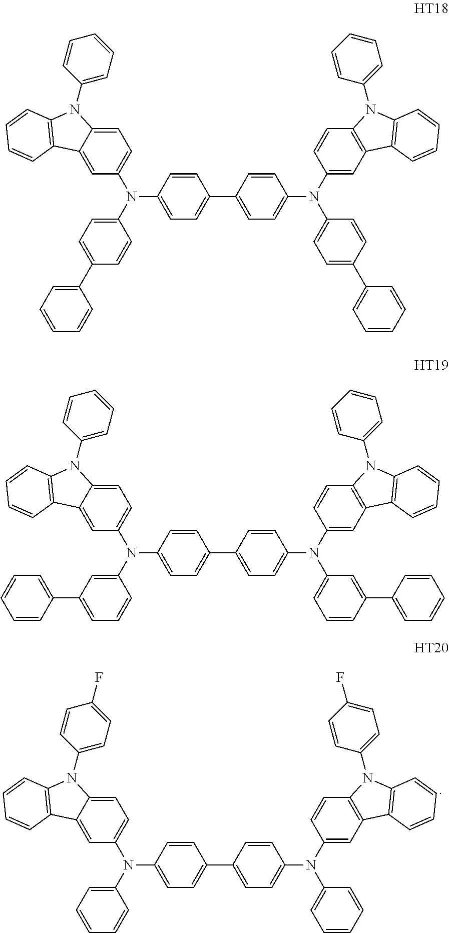 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes a hole injection layer and a hole transport layer, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be a quinone derivative, a metal oxide, or a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 or Compound HT-D2 below, but are not limited thereto.

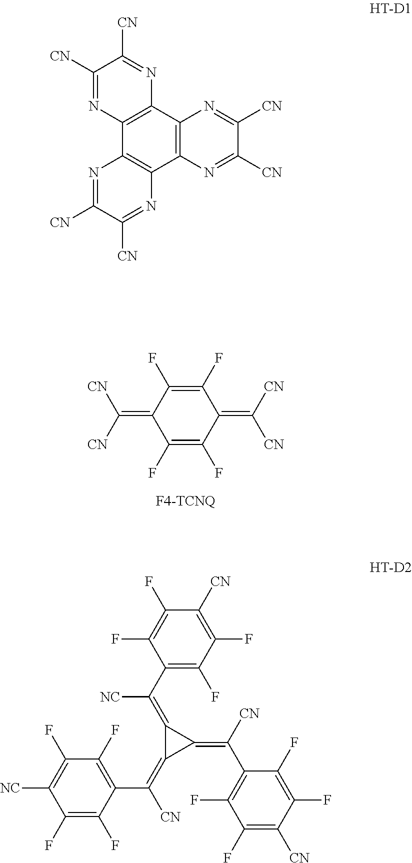

The hole transport region may include a buffer layer.

Also, the buffer layer may compensate for an optical resonance distance according to a wavelength of light emitted from the emission layer, and thus, efficiency of a formed organic light-emitting device may be improved.

The electron transport region may further include an electron blocking layer. The electron blocking layer may include, for example, mCP, but a material therefor is not limited thereto:

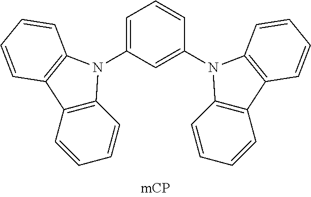 [SMILES: c1cc(-n2c3ccccc3c3ccccc32)cc(-n2c3ccccc3c3ccccc32)c1]

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

The emission layer may include a host and a thermally activated delayed fluorescent dopant, and the host and the fluorescent dopant may be the same as described above.

A thickness of the emission layer may be in a range of about 100 Å to about 1,000 Å, for example, about 200 Å to about 600 Å. When the thickness of the emission layer is within any of these ranges, excellent light-emission characteristics may be obtained without a substantial increase in driving voltage.

Then, an electron transport region may be disposed on the emission layer.

The electron transport region may include a hole blocking layer, an electron transport layer, an electron injection layer, or a combination thereof.

In an exemplary embodiment, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP and Bphen, but may also include other materials:

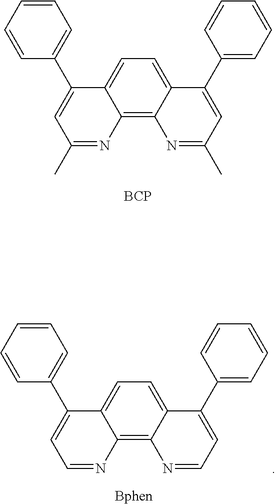

A thickness of the hole blocking layer may be in a range of about 20 Å to about 1,000 Å, for example, about 30 Å to about 300 Å. When the thickness of the hole blocking layer is within these ranges, the hole blocking layer may have improved hole blocking ability without a substantial increase in driving voltage.

The electron transport layer may further include BCP, Bphen, Alq₃, BAlq, TAZ, NTAZ, or a combination thereof.

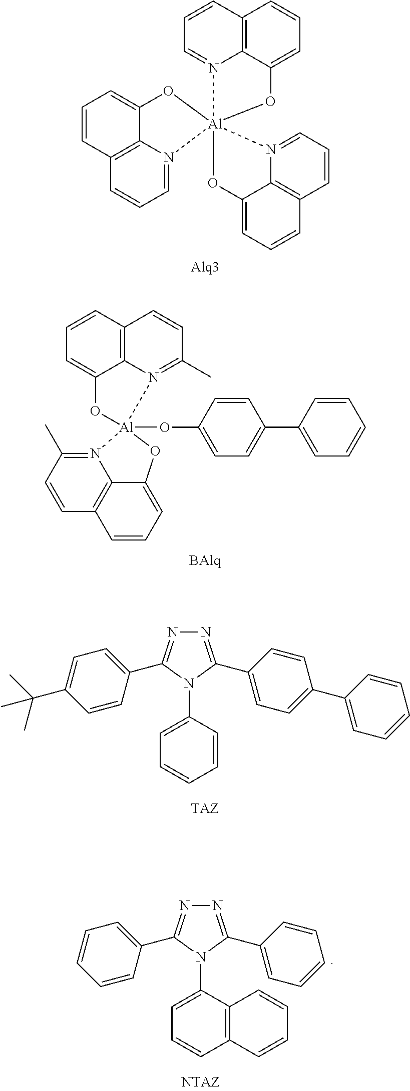

In one or more embodiments, the electron transport layer may include ET1 to ET25, but are not limited thereto:

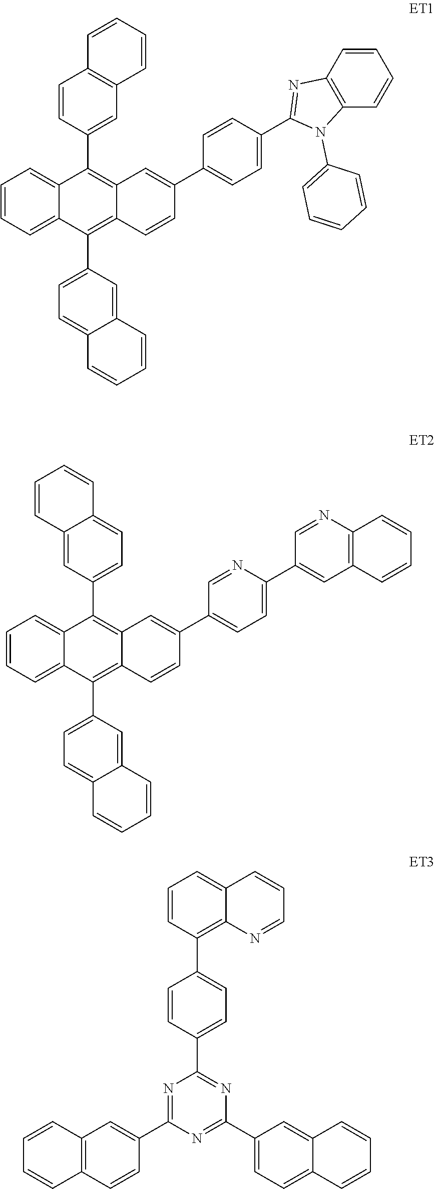 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

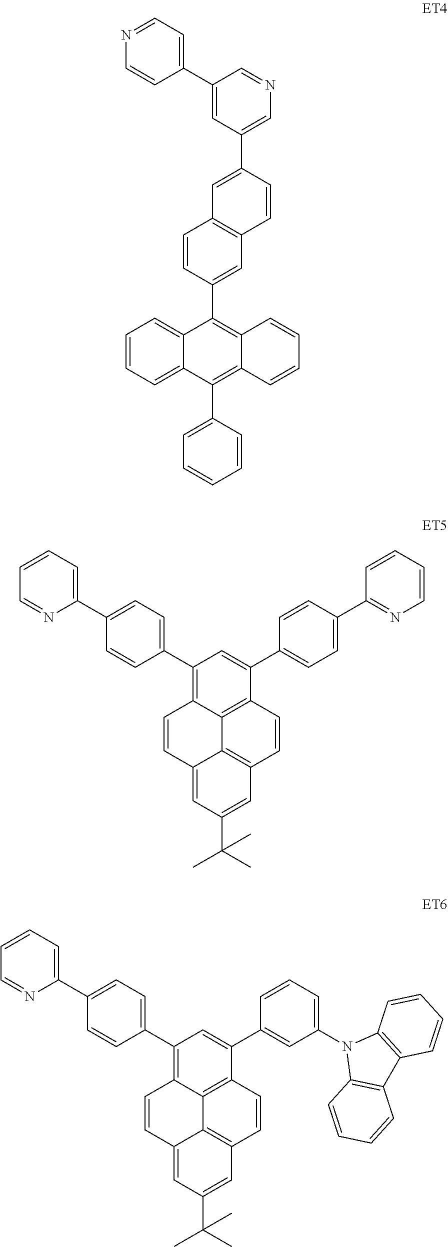 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

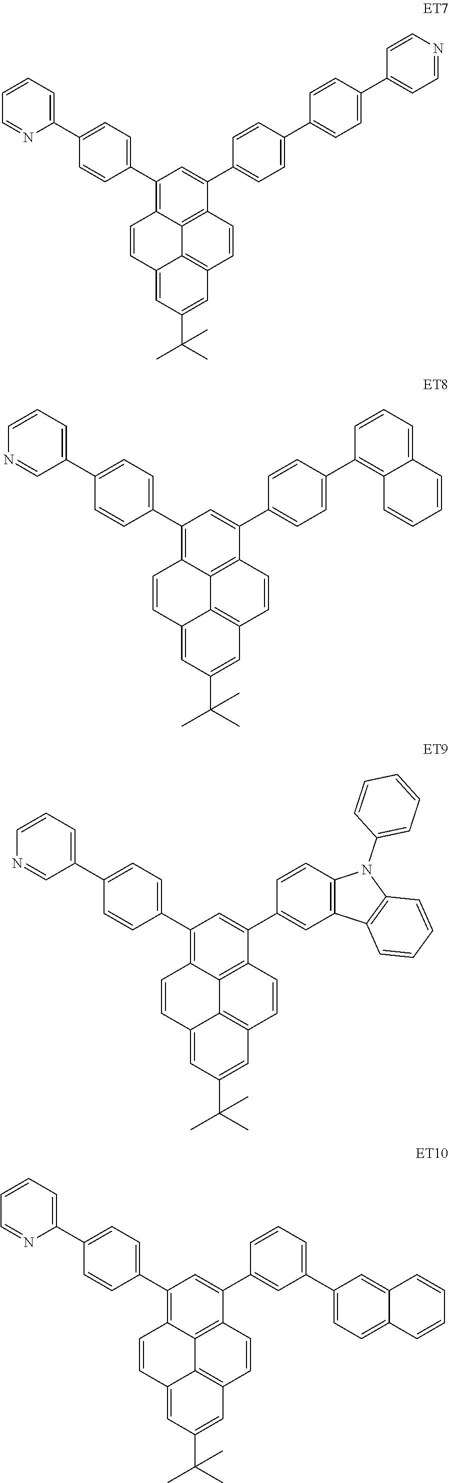 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34 ; CC(C)(C)c1cc2ccc3c(-c4ccc(-c5ccccn5)cc4)cc(-c4cccc(-c5ccc6ccccc6c5)c4)c4ccc(c1)c2c34]

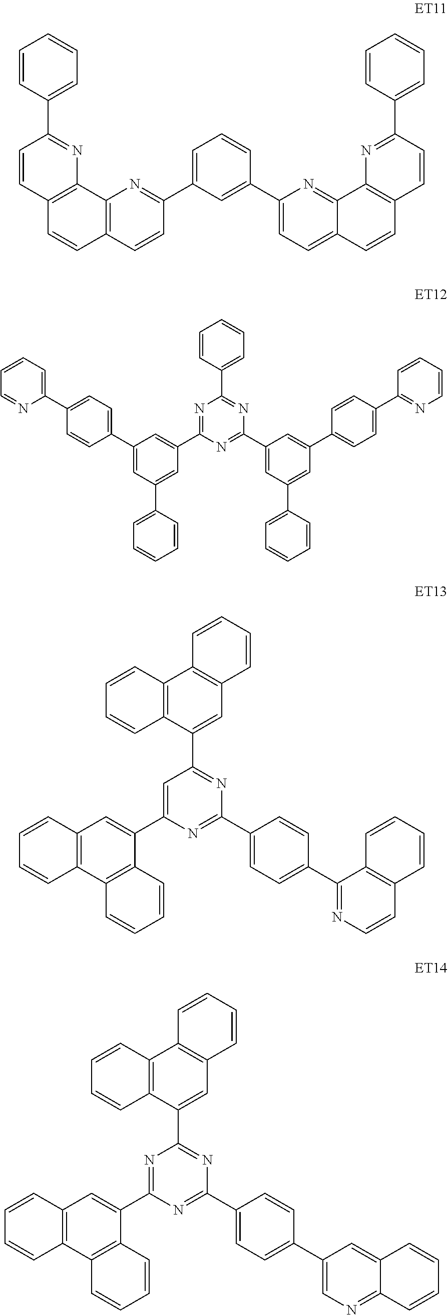 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

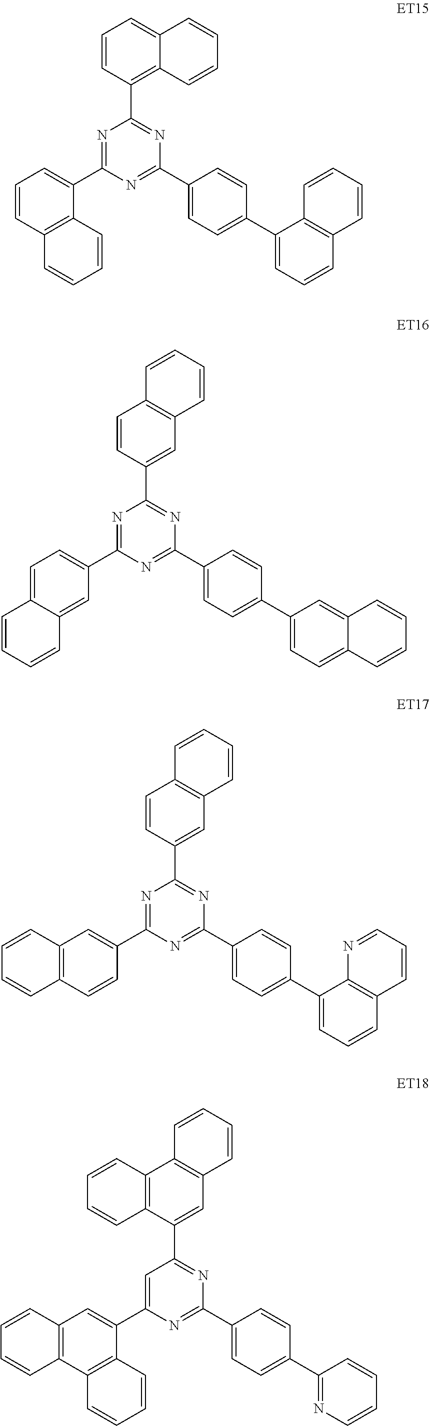 [SMILES: c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

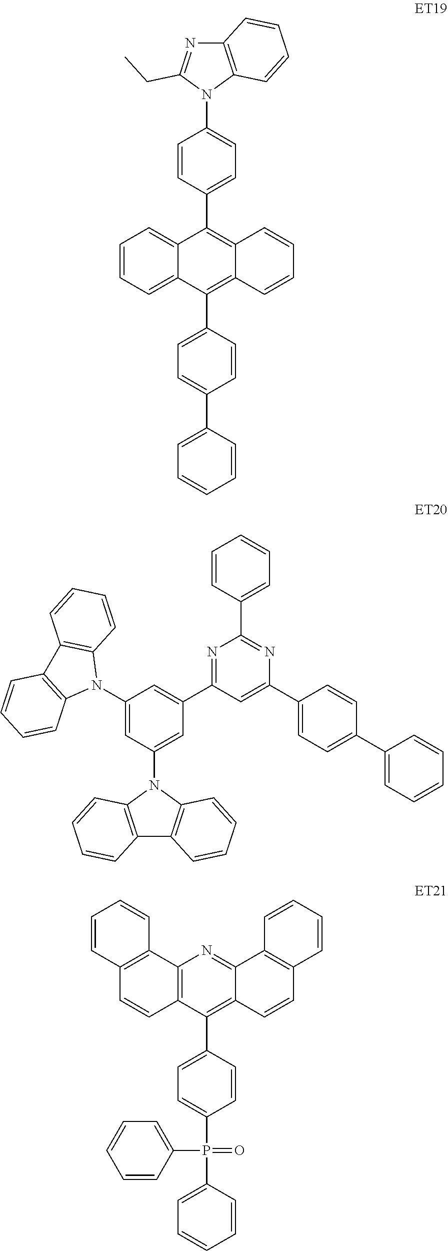

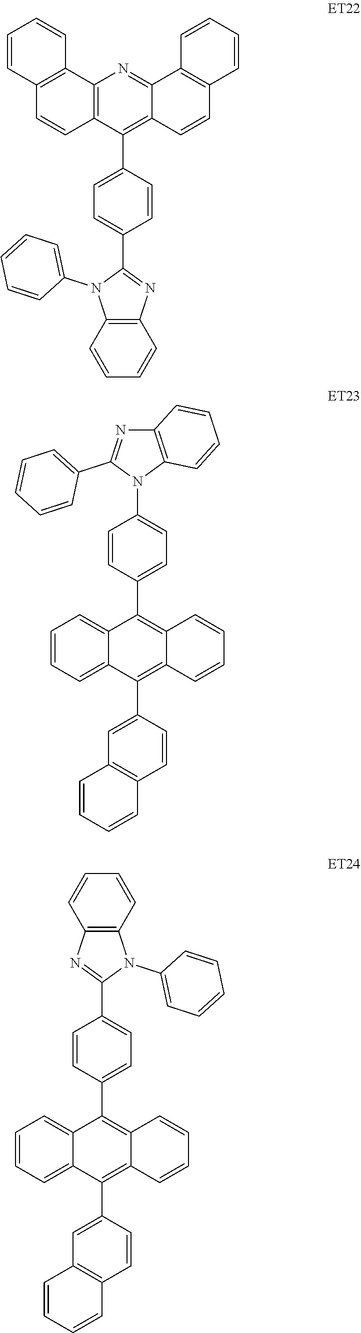

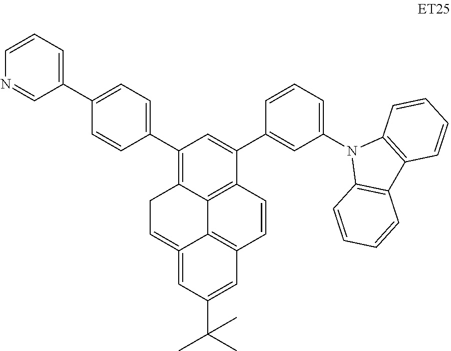

A thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Lithium (Li) complex. The Li complex may include, for example, Compound ET-D1 (lithium 8-hydroxyquinolate, LiQ) or ET-D2.

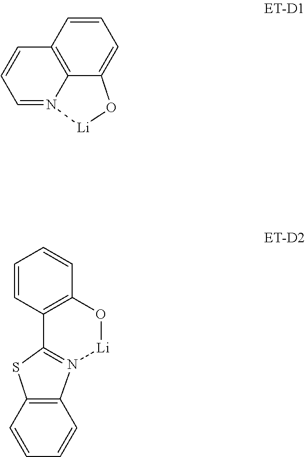

The electron transport region may include an electron injection layer (EIL) that promotes flow of electrons from the second electrode 19 thereinto.

The electron injection layer may include LiF, NaCl, CsF, Li₂O, BaO, or a combination thereof.

A thickness of the electron injection layer may be in a range of about 1 | to about 100 Å, for example, about 3 Å to about 90 Å. When the thickness of the electron injection layer is within the range described above, the electron injection layer may have satisfactory electron injection characteristics without a substantial increase in driving voltage.

The second electrode 19 may be formed on the organic layer 15. The second electrode 19 may be a cathode. A material for forming the second electrode 19 may be selected from metal, an alloy, an electrically conductive compound, and a combination thereof, which have a relatively low work function. In an exemplary embodiment, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIG. 1, but embodiments of the present disclosure are not limited thereto.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, and an isopropyloxy group.

The term “C₂-C₆₀ alkenyl group” as used herein refers to a hydrocarbon group formed by substituting at least one double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₂-C₁₀ heterocycloalkyl group” as used herein refers to a monovalent saturated monocyclic group having at least one heteroatom selected from N, O, P, Si and S as a ring-forming atom and 2 to 10 carbon atoms, and non-limiting examples thereof include a tetrahydrofuranyl group, and a tetrahydrothiophenyl group. The term “C₂-C₁₀ heterocycloalkylene group” as used herein refers to a divalent group having the same structure as the C₂-C₁₀ heterocycloalkyl group.

The term “C₃-C₁₀ cycloalkenyl group” as used herein refers to a monovalent monocyclic group that has 3 to 10 carbon atoms and at least one double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₂-C₁₀ heterocycloalkenyl group” as used herein refers to a monovalent monocyclic group that has at least one heteroatom selected from N, O, P, Si, and S as a ring-forming atom, 2 to 10 carbon atoms, and at least one double bond in its ring. Non-limiting examples of the C₂-C₁₀ heterocycloalkenyl group include a 2,3-dihydrofuranyl group, and a 2,3-dihydrothiophenyl group. The term “C₂-C₁₀ heterocycloalkenylene group” as used herein refers to a divalent group having the same structure as the C₂-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₂-C₆₀ heteroaryl group” as used herein refers to a monovalent group having a heterocyclic aromatic system that has at least one heteroatom selected from N, O, P, Si, and S as a ring-forming atom, and 2 to 60 carbon atoms. The term “C₂-C₆₀ heteroarylene group,” as used herein refers to a divalent group having a heterocyclic aromatic system that has at least one heteroatom selected from N, O, P, Si, and S as a ring-forming atom, and 2 to 60 carbon atoms. Non-limiting examples of the C₂-C₆₀ heteroaryl group include a pyridinyl group, a pyrimidinyl group, a pyrazinyl group, a pyridazinyl group, a triazinyl group, a quinolinyl group, and an isoquinolinyl group. When the C₂-C₆₀ heteroaryl group and the C₂-C₆₀ heteroarylene group each include two or more rings, the rings may be fused to each other.

The term “C₆-C₆₀ aryloxy group” as used herein refers to —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

The term “monovalent non-aromatic condensed polycyclic group” as used herein refers to a monovalent group having two or more rings condensed to each other, only carbon atoms (for example, the number of carbon atoms may be in a range of 8 to 60) as a ring-forming atom, and no aromaticity in its entire molecular structure. Non-limiting examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed to each other, a heteroatom selected from N, O, P, Si, and S, other than carbon atoms (for example, the number of carbon atoms may be in a range of 2 to 60), as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

At least one substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be:
a deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with deuterium, —F, —CI, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₄)(Q₁₅), —B(Q₁₆)(Q₁₇), or a combination thereof; a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group;
a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₄)(Q₂₅), —B(Q₂₆)(Q₂₇); or a combination thereof, —Si(Q₃₁)(Q₃₂)(Q₃₃), —N(Q₃₄)(Q₃₅), and —B(Q₃₆)(Q₃₇), and
Q₁ to Q₇, Q₁₁ to Q₁₇, Q₂₁ to Q₂₇, and Q₃₁ to Q₃₇ may each independently be a hydrogen, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

The term “room temperature” as used herein refers to about 25° C.

The terms “biphenyl group” and “terphenyl group” as used herein each refer to a monovalent group in which two or three benzene groups are linked to each other via a single bond, respectively.

Hereinafter, a compound and an organic light-emitting device according to embodiments are described in detail with reference to Synthesis Example and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1

### Synthesis of Compound TD1

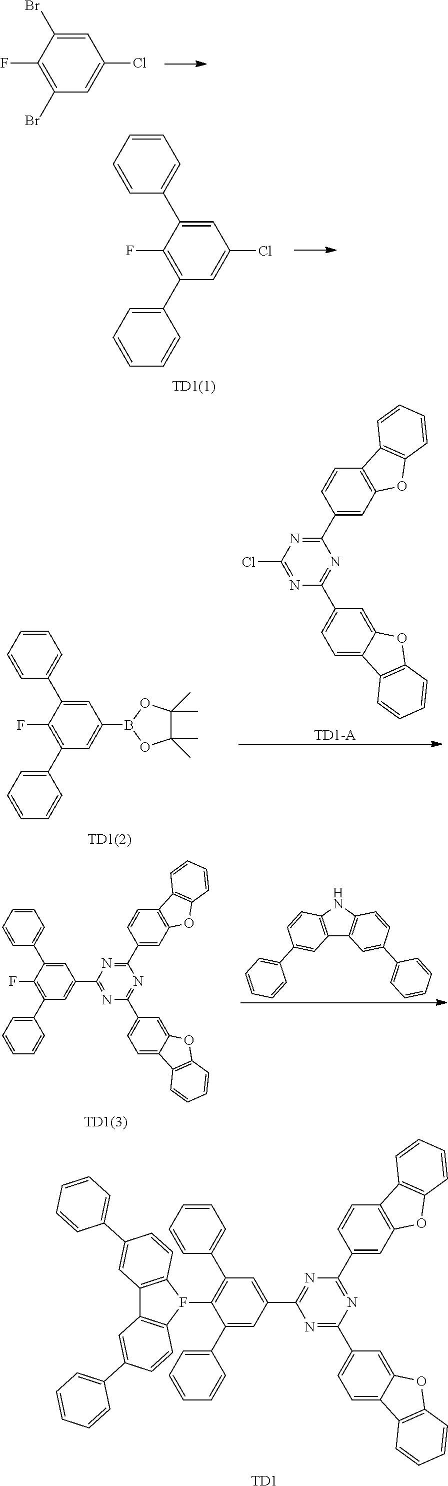

### Synthesis of Intermediate TD1(1)

Phenylboronic acid (63.43 g, 520.22 mmol), 1,3-dibromo-5-chloro-2-fluorobenzene (50 g, 173.41 mmol), palladium tetrakis(triphenylphosphine) (Pd(PPh₃)₄) (20.04 g, 17.34 mmol), potassium carbonate (K2CO₃) (95.87 g, 693.63 mmol), and S-phos (14.24 g, 34.68 mmol) were added to 300 ml of tetrahydrofuran and 300 ml of distilled water and heated under reflux. After the reaction was completed, the reaction product was cooled to room temperature, and an organic layer was extracted therefrom by using ethyl acetate. The extracted organic layer was dried by using anhydrous sodium sulfate (Na₂SO₄), concentrated, and then separated by silica gel column chromatography (dichloromethane/hexane). A solid obtained therefrom was recrystallized by using hexane to obtain Intermediate TD1(1) (40.7 g, 143.81 mmol, yield of 83%) as a white solid.

### Synthesis of Intermediate TD2(2)

Intermediate TD1(1) (40.7 g, 143.81 mmol), bis(pinacolato)diboron (54.78 g, 215.71 mmol), potassium acetate (35.29 g, 359.52 mmol), tris(dibenzylideneacetone)dipalladium(0) (Pd₂(dba)₃) (13.17 g, 14.38 mmol), and tricyclohexylphosphine (4.03 g, 14.38 mmol) were added to 290 ml of dioxane and heated under reflux. After the reaction was completed, the reaction product was cooled to room temperature, and excess toluene was added thereto and dissolved therein. The mixed solution passed through silica gel and was filtered to obtain an organic layer. The obtained organic layer was concentrated, and hexane was added thereto to obtain a precipitate. The precipitate was filtered to obtain Intermediate TD1(2) (47.0 g, 125.58 mmol, yield of 87%) as a white solid.

### Synthesis of Intermediate TD1(3)

Compound TD1-A (18 g, 67.23 mmol), Intermediate TD1(2) (30.2 g, 80.68 mmol), palladium tetrakis(triphenylphosphine) (Pd(PPh₃)₄) (3.89 g, 3.36 mmol), potassium carbonate (K₂CO₃) (18.59 g, 134.47 mmol), and S-phos (5.52 g, 13.45 mmol) were added to 120 ml of tetrahydrofuran and 120 ml of distilled water and heated under reflux. After the reaction was completed, the reaction product was cooled to room temperature, and methanol was added thereto. The mixed solution passed through silica gel and was filtered to obtain an organic layer. The obtained organic layer was concentrated and precipitated by adding methanol to obtain Intermediate TD1(3) (yield of 79%).

### Synthesis of Compound TD1

Intermediate TD1(3) (10 mmol), 3,6-diphenyl-9H-carbazole (4.19 g, 15 mmol), and cesium carbonate (Cs₂CO₃) (6.52 g, 20 mmol) were added to 20 ml of N,N-dimethylformamide and stirred at a temperature of 165° C. for 20 hours. After the reaction was completed, the reaction product was cooled to room temperature, methanol was added thereto. The mixed solution passed through silica gel and was filtered to obtain an organic layer. The obtained organic layer was concentrated and dissolved again in toluene. The result passed through silica gel and was filtered, concentrated, and recrystallized (ethyl acetate/ethanol) to synthesize Compound TD1 (yield of 69%).

LC-Mass (Calcd.: 958.33 g/mol, Found: 959.31 g/mol (M+1)).

### Synthesis Example 2

### Synthesis of Compound TD2

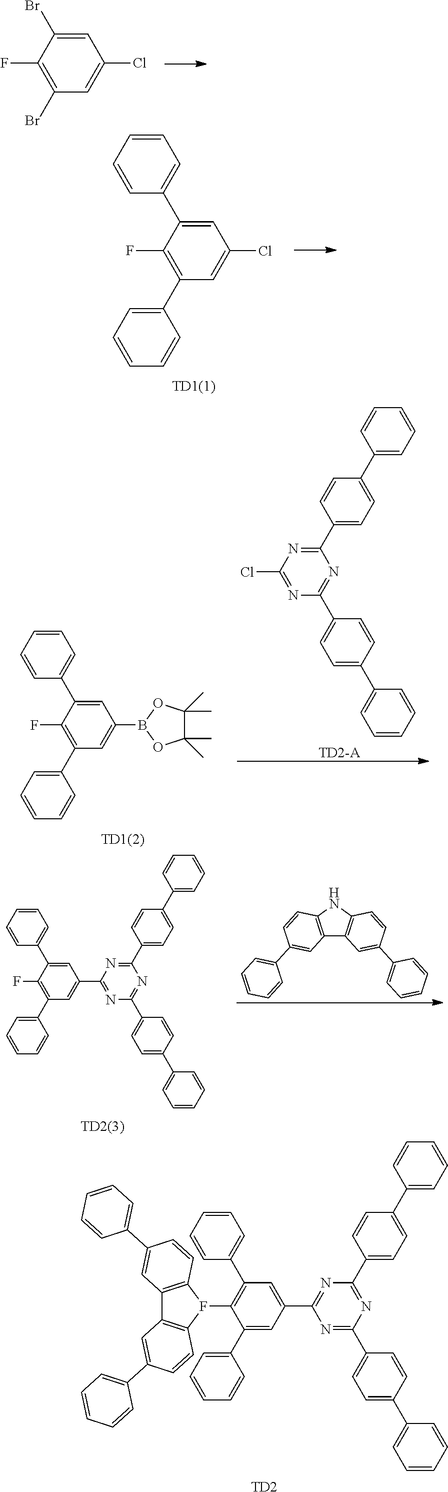

### Synthesis of Intermediate TD2(3)

Intermediate TD2(3) (yield of 79%) was synthesized in the same manner as used to synthesize Intermediate TD1(3) of Synthesis Example 1, except that Compound TD2-A was used instead of Compound TD1-A.

### Synthesis of Compound TD2

Compound TD2 (yield of 65%) was synthesized in the same manner as used to synthesize Compound TD1 of Synthesis Example 1, except that Intermediate TD2 (3) was used instead of Intermediate TD1 (3).

LC-Mass (Calcd.: 930.37 g/mol, Found: 931.37 g/mol (M+1)).

### Synthesis Example 3

### Synthesis of Compound TD43

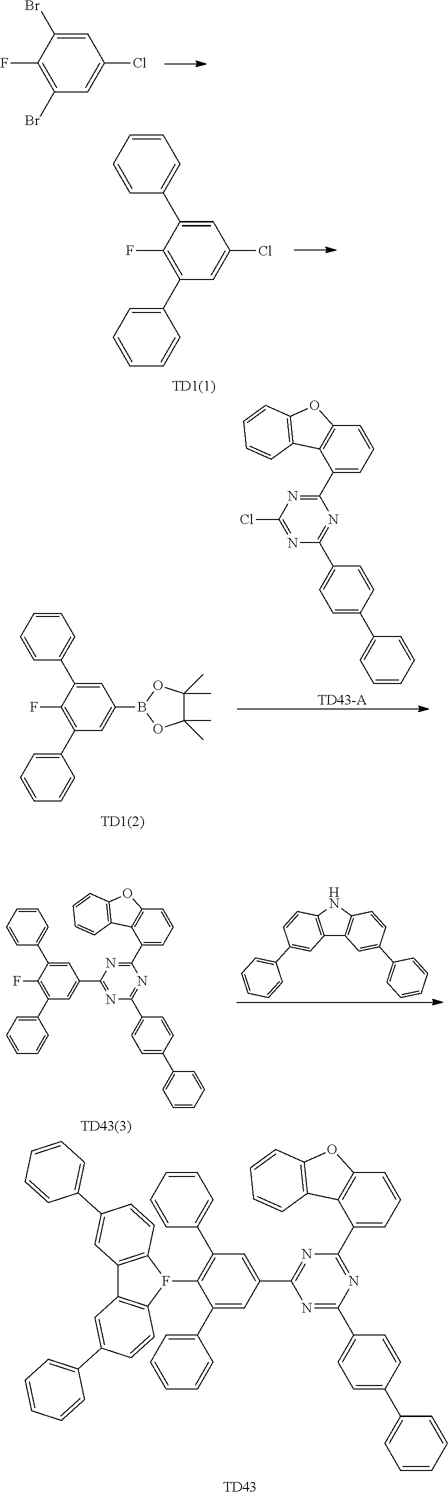

### Synthesis of Intermediate TD43(3)

Intermediate TD43(3) was synthesized in the same manner as used to synthesize Intermediate TD1(3) of Synthesis Example 1, except that Compound TD43-A was used instead of Compound TD1-A.

### Synthesis of Compound TD43

Compound TD43 (3.6 g, yield of 68.3%) was synthesized in the same manner as used to synthesize Compound TD1 of Synthesis Example 1, except that Intermediate TD43(3) was used instead of Intermediate TD1(3).

LC-Mass (Calcd.: 944.35 g/mol, Found: 945.37 g/mol (M+1)).

### Synthesis Example 4

### Synthesis of Compound TD23

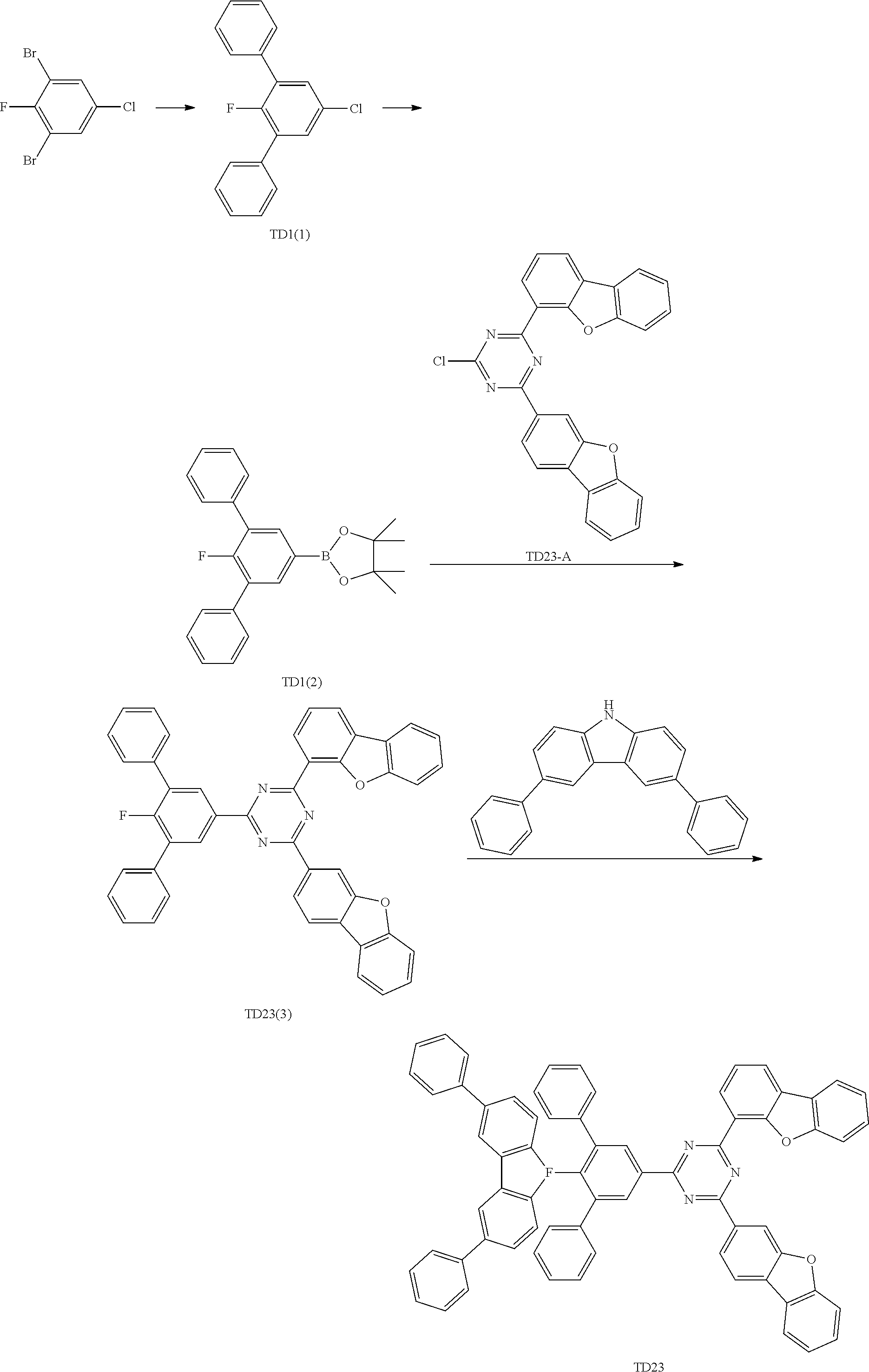

### Synthesis of Intermediate TD23(3)

Intermediate TD23(3) was synthesized in the same manner as used to synthesize Intermediate TD1(3) of Synthesis Example 1, except that Compound TD23-A was used instead of Compound TD1-A.

### Synthesis of Compound TD23

Compound TD23 (4.7 g, yield of 78.7%) was synthesized in the same manner as used to synthesize Compound TD1 of Synthesis Example 1, except that Intermediate TD23(3) was used instead of Intermediate TD1(3).

LC-Mass (Calcd.: 958.33 g/mol, Found: 959.31 g/mol (M+1)).

### Evaluation Example 1

### BDE Evaluation of N—C Bond

Bond dissociation energy (BDE) of N—C bond (see N—C bond indicated by an ellipse) of Compounds TD1, TD2, A, and B was evaluated by using a density functional theory (DFT) of TURBOMOLE program (structurally optimized at a level of PBE0/def2-SVP/COSMO), and results thereof are shown in Table 1.

TABLE 1

| Compound No. | BDE of N—C bond (kcal/mol) |
|---|---|
| Compound TD1 | 13.145 |
| Compound TD2 | 14.326 |
| Compound A | 10.626 |
| Compound B | 10.023 |

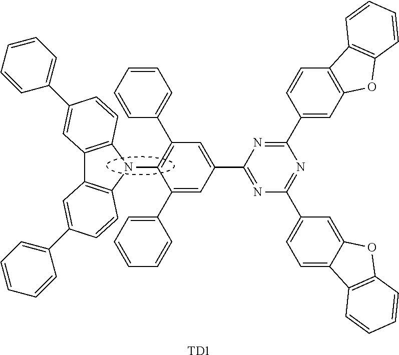 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; "TD1"]

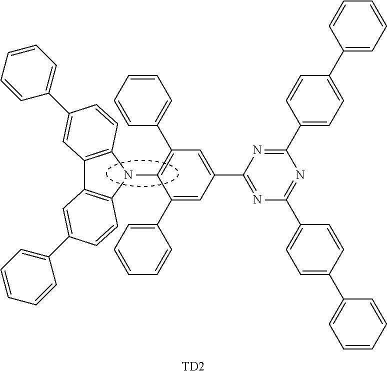 [SMILES: c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; "TD2"]

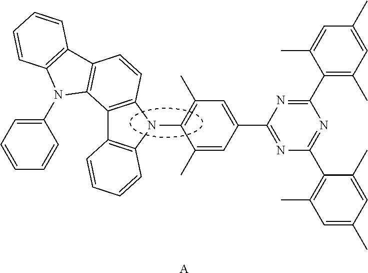

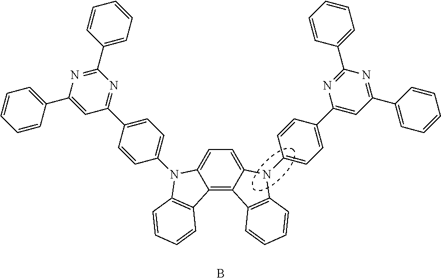

Referring to Table 1, it is confirmed that BDE of N—C bond of Compounds TD1 and TD2 is higher than BDE of N—C bond of Compounds A and B.

### Evaluation Example 2

### Evaluation of PL Stability

A quartz substrate washed with chloroform and pure water was prepared, and predetermined materials shown in Table 2 were vacuum-deposited (co-deposited) at a vacuum degree of 10⁻⁷ torr to form films 1 to 4, A, and B having a thickness of 50 nm.

Immediately after films 1 to 4, A, and B were formed, a PL spectrum for each film was evaluated at room temperature by using a He—Cd laser (available from KIMMON-KOHA) (excitation wavelength=325 nm) in an Ar atmosphere in which outside air was blocked, and intensity I₁(a.u.) of light having a maximum emission wavelength in the PL spectrum was measured.

Then, in an Ar atmosphere in which outside air was blocked, films 1 to 4, A, and B were exposed to light of He—Cd laser (available from KIMMON-KOHA) (excitation wavelength=325 nm), which was a pumping laser used to evaluate I₁, for 3 hours, the PL spectrum of each film was evaluated at room temperature by using He—Cd laser (available from KIMMON-KOHA) (excitation wavelength=325 nm), and intensity I₂(a.u.) of light having a maximum emission wavelength in the PL spectrum was measured.

The PL stability for each film, which was obtained by calculating (I₂/I₁)×100(%) from 1, and 12 measured as described above, are shown in Table 2.

TABLE 2

| | Compound used to | (I₂/I₁) × 100 (%) |
|---|---|---|
| Film name | produce film | (PL stability) |
| Film 1 | E4:Compound TD1 | 82 |
| | (volume ratio of 85:15) | |
| Film 2 | E4:Compound TD2 | 83 |
| | (volume ratio of 85:15) | |
| Film 3 | E4:Compound TD43 | 85 |
| | (volume ratio of 85:15) | |
| Film 4 | E4:Compound TD23 | 82 |
| | (volume ratio of 85:15) | |
| Film A | E4:Compound A | 64 |
| | (volume ratio of 85:15) | |
| Film B | E4:Compound B | 78 |
| | (volume ratio of 85:15) | |

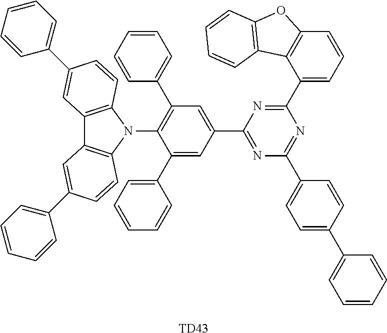 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5oc6ccccc6c45)n3)cc2)cc1 ; "TD43"]

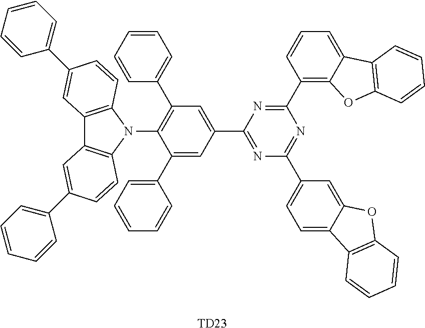 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4cccc5c4oc4ccccc45)n3)cc2-c2ccccc2)cc1 ; "TD23"]

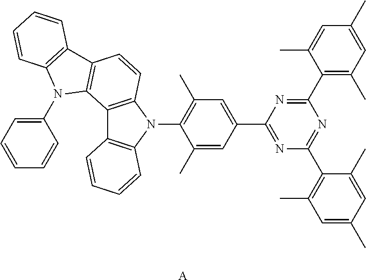

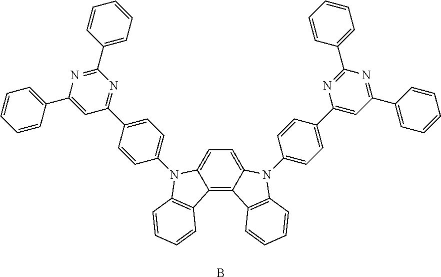

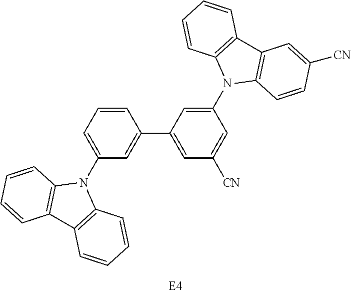 [SMILES: N#Cc1cc(-c2cccc(-n3c4ccccc4c4ccccc43)c2)cc(-n2c3ccccc3c3cc(C#N)ccc32)c1]

Referring to Table 2, it is confirmed that films 1 to 4 have high PL stabilities, as compared with those of films A and B.

### Example 1

A glass substrate, on which an ITO electrode (first electrode, anode) having a thickness of 1,500 Å was formed and was sonicated with distilled water. After washing with distilled water, the glass substrate was sonicated with a solvent such as isopropyl alcohol, acetone, or methanol, dried, and then transferred to a plasma cleaner. The glass substrate was washed for 5 minutes by using oxygen plasma. Then, the glass substrate was provided to a vacuum deposition apparatus.

Compound HT3 and Compound HT-D2 were co-deposited on the ITO electrode of the glass substrate to form a hole injection layer having a thickness of 100 Å, Compound HT3 was deposited on the hole injection layer to form a hole transport layer having a thickness of 1,350 Å, mCP was deposited on the hole transport layer to form an electron blocking layer having a thickness of 100 Å, thereby forming a hole transport region.

A host and a delayed fluorescence emitter were co-deposited on the hole transport region at a weight ratio of 85:15 to form an emission layer having a thickness of 300 Å. Compound H19 and Compound E4 (volume ratio of 1:9) were used as the host, and Compound TD1 was used as the delayed fluorescence emitter.

Compound BCP was vacuum-deposited on the emission layer to form a hole blocking layer having a thickness of 100 Å, Compound ET3 and LiQ were vacuum-deposited on the hole blocking layer to form an electron transport layer having a thickness of 300 Å, LiQ was deposited on the electron transport layer to form an electron injection layer having a thickness of 10 Å, and Al was deposited on the electron injection layer to form an Al electrode (second electrode, cathode) having a thickness of 1,000 Å, thereby completing the manufacture of an organic light-emitting device.

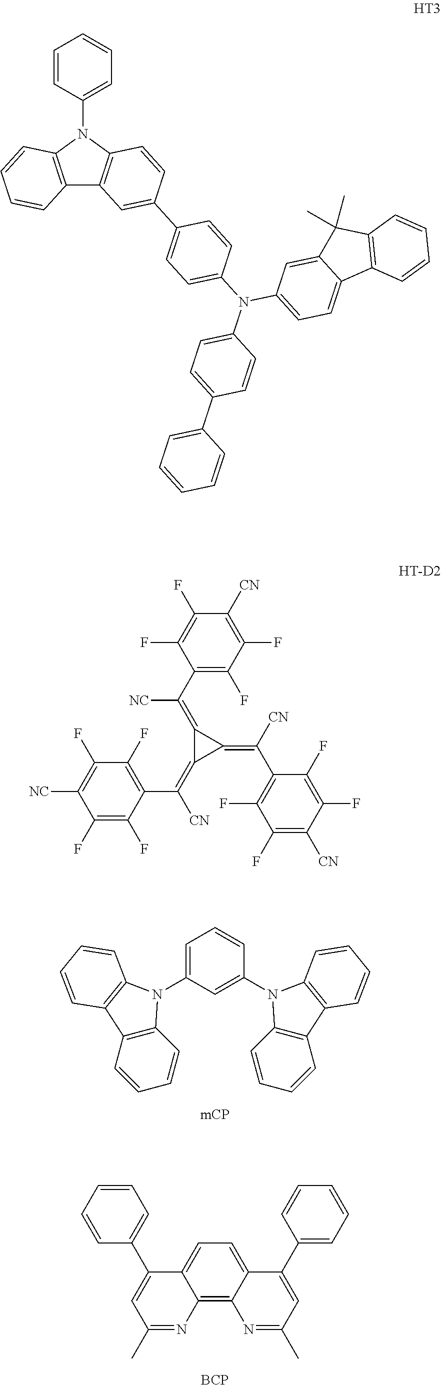

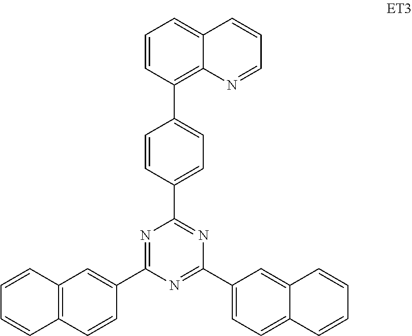 [SMILES: c1ccc2cc(-c3nc(-c4ccc(-c5cccc6cccnc56)cc4)nc(-c4ccc5ccccc5c4)n3)ccc2c1]

### Examples 2 to 4 and Comparative Examples A and B

Organic light-emitting devices were manufactured in the same manner as in Example 1, except that the configuration of the emission layer was changed as shown in Table 3.

### Evaluation Example 2

### Evaluation of Data about Organic Light-Emitting Devices

The maximum emission wavelength (λₘₐₓ), maximum external quantum efficiency (EQEₘₐₓ), and lifespan (T₉₅) of each of Examples 1 to 4 and Comparative Examples A and B were measured by using a current-voltage meter (Keithley 2400) and a luminance meter (Minolta Cs-1000A), and results thereof are shown in Table 3. The lifespan (T₉₅) data (at 500 cd/m²) in Table 3 indicates an amount of time (hr) that lapsed when luminance was 95% of initial luminance (100%).

TABLE 3

| | Host | | | | | | |
|---|---|---|---|---|---|---|---|
| | First | Second | | | Maximum | | Lifespan |
| | material | material | | | emission | | (T₉₅) |
| | (hole- | electron- | | Delayed | wavelength | | at |
| | transporting | transporting | HT:ET | fluorescence | (λₘₐₓ) | EQEₘₐₓ | 500 cd/m² |
| No. | host, HT) | host, ET | (volume ratio) | emitter | (nm) | (%) | (hr) |
| Example 1 | H19 | E4 | 1:9 | TD1 | 457 | 12.1 | 10.5 |
| Example 2 | H19 | E4 | 1:9 | TD2 | 449 | 8.9 | 10.3 |
| Example 3 | H19 | E4 | 1:9 | TD43 | 458 | 12.7 | 11.3 |
| Example 4 | H19 | E4 | 1:9 | TD23 | 457 | 8.0 | 6.2 |
| Comparative | H19 | E4 | 1:9 | A | 460 | 6.4 | 0.1 |
| Example A | | | | | | | |
| Comparative | H19 | E4 | 1:9 | B | 476 | 11.1 | 4.0 |
| Example B | | | | | | | |

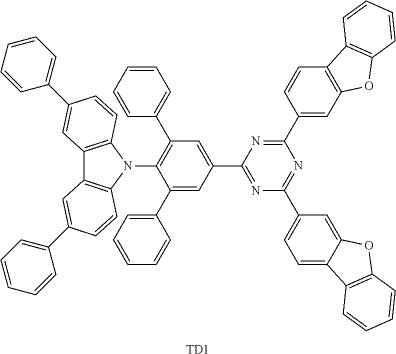 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4ccc5c(c4)oc4ccccc45)n3)cc2-c2ccccc2)cc1 ; "TD1"]

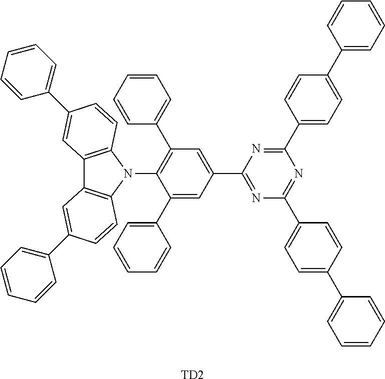 [SMILES: c1ccc(-c2ccc(-c3nc(-c4ccc(-c5ccccc5)cc4)nc(-c4cc(-c5ccccc5)c(-n5c6ccc(-c7ccccc7)cc6c6cc(-c7ccccc7)ccc65)c(-c5ccccc5)c4)n3)cc2)cc1 ; "TD2"]

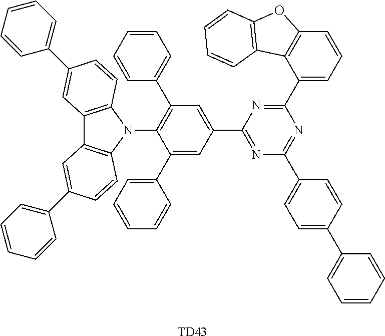 [SMILES: c1ccc(-c2ccc(-c3nc(-c4cc(-c5ccccc5)c(-n5c6ccc(-c7ccccc7)cc6c6cc(-c7ccccc7)ccc65)c(-c5ccccc5)c4)nc(-c4cccc5oc6ccccc6c45)n3)cc2)cc1 ; "TD43"]

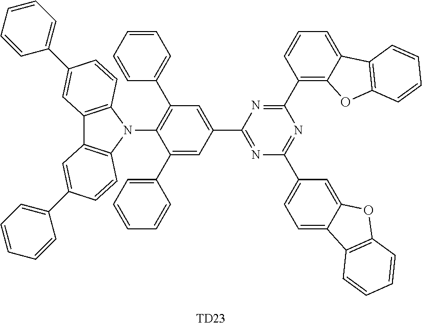 [SMILES: c1ccc(-c2ccc3c(c2)c2cc(-c4ccccc4)ccc2n3-c2c(-c3ccccc3)cc(-c3nc(-c4ccc5c(c4)oc4ccccc45)nc(-c4cccc5c4oc4ccccc45)n3)cc2-c2ccccc2)cc1 ; "TD23"]

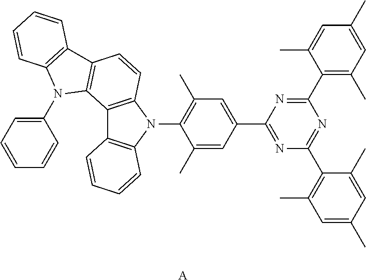

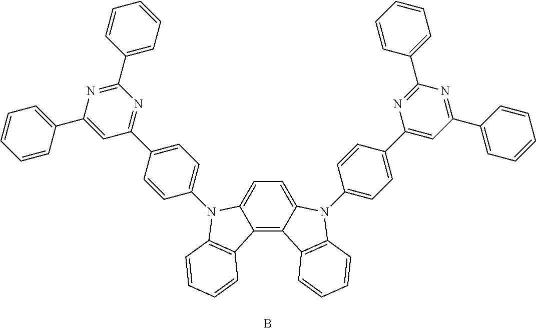

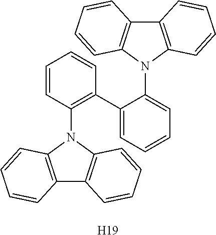

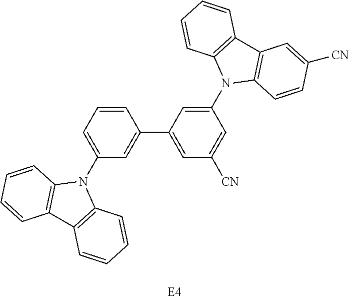 [SMILES: N#Cc1cc(-c2cccc(-n3c4ccccc4c4ccccc43)c2)cc(-n2c3ccccc3c3cc(C#N)ccc32)c1]

Referring to Table 3, it is confirmed that the organic light-emitting devices of Examples 1 to 4 have improved external quantum efficiency and lifespan, as compared with those of the organic light-emitting devices of Comparative Examples A and B.

An organic light-emitting device according to an embodiment may have high efficiency and a long lifespan.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. An organic light-emitting device comprising:
a first electrode;
a second electrode facing the first electrode; and
an organic layer disposed between the first electrode and the second electrode,
wherein the organic layer comprises an emission layer,
the emission layer comprises a thermally activated delayed fluorescence emitter and a host,
the emission layer does not comprise a phosphorescence emitter, and
the thermally activated delayed fluorescence emitter comprises a compound represented by Formula 1: 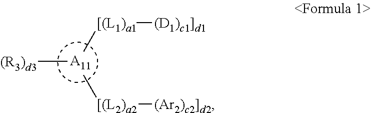
wherein, in Formula 1,
ring A₁₁ is a pyridine group, a pyrimidine group, a pyrazine group, a pyridazine group, a triazine group, or a tetrazine group,
L₁ and L₂ are each independently:
a single bond; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₀₁)(Q₁₀₂)(Q₁₀₃), or a combination thereof,
a1 and a2 are each independently an integer from 1 to 5,
D₁ is a hole-transporting group,
Ar₂ is a dibenzofuran group, a dibenzothiophene group, or a biphenyl group, each unsubstituted or substituted with at least one R₁₀,
c1 and c2 are each independently an integer from 1 to 5,
R₃ and R₁₀ are each independently:
a hydrogen, a deuterium, a C₁-C₂₀ alkyl group, or a C₁-C₂₀ alkoxy group; or
a π electron-rich cyclic group unsubstituted or substituted with of deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₁₁)(Q₁₁₂)(Q₁₁₃), or a combination thereof,
d1 to d3 are each independently an integer from 1 to 4, and
Q₁₀₁ to Q₁₀₃ and Q₁₁₁ to Q₁₁₃ are each independently a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

2. The organic light-emitting device of claim 1, wherein ring A₁₁ is a triazine group.

3. The organic light-emitting device of claim 1, wherein
L₁ and L₂ are each independently:
a single bond; or
a benzene group, a fluorene group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, an acridine group, or a dihydroacridine group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof.

4. The organic light-emitting device of claim 1, wherein
D₁ in Formula 1 is a nitrogen-containing hole-transporting group, and
N in D₁ and C in ring A₁₁ are linked to each other via a single bond, or N in D₁ and C in L₁ are linked to each other via a single bond.

5. The organic light-emitting device of claim 1, wherein D₁ is a group represented by Formula 3-1: 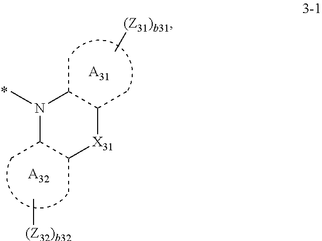
wherein, in Formula 3-1,
ring A₃₁ and ring A₃₂ are each independently a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group,
X₃₁ is a single bond, N(Z₃₃), C(Z₃₄)(Z₃₅), O, or S,
Z₃₁ to Z₃₅ are each independently:
a hydrogen, a deuterium, a C₁-C₂₀ alkyl group, or a C₁-C₂₀ alkoxy group; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₁₂₁)(Q₁₂₂)(Q₁₂₃), or a combination thereof,
b31 and b32 are each independently 1, 2, 3, or 4,
Q₁₂₁ to Q₁₂₃ are each independently a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group, and
*indicates a binding site to L₁ or ring A₁₁ in Formula 1.

6. The organic light-emitting device of claim 1, wherein
D₁ is a group represented by Formulae 3-1(1) to 3-1(3): 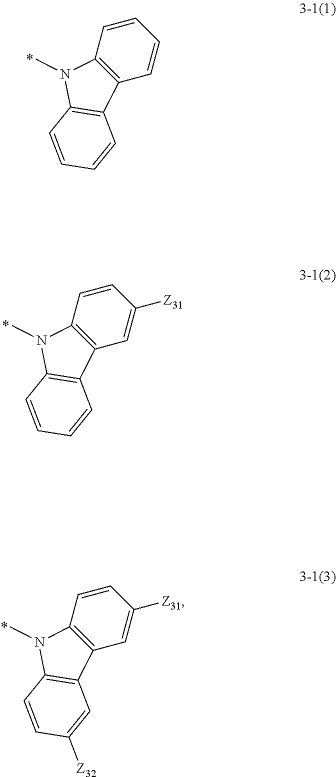
wherein, in Formulae 3-1(1) to 3-1(3),
Z₃₁ and Z₃₂ are each independently:
a deuterium, a C₁-C₁₀ alkyl group, or a C₁-C₁₀ alkoxy group; or a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof, and
*indicates a binding site to L₁ or ring A₁₁ in Formula 1.

7. The organic light-emitting device of claim 1, wherein
Ar₂ is a group represented by Formulae 4-1 to 4-31: 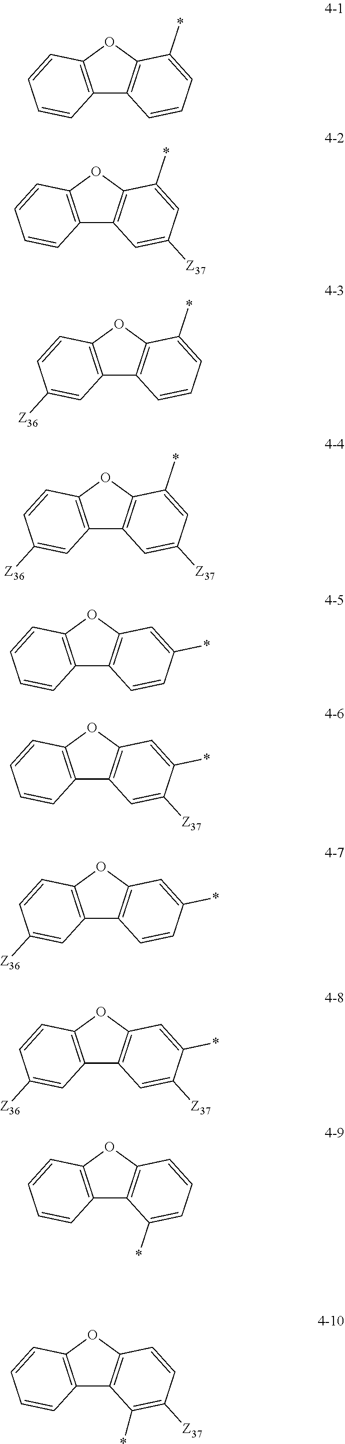 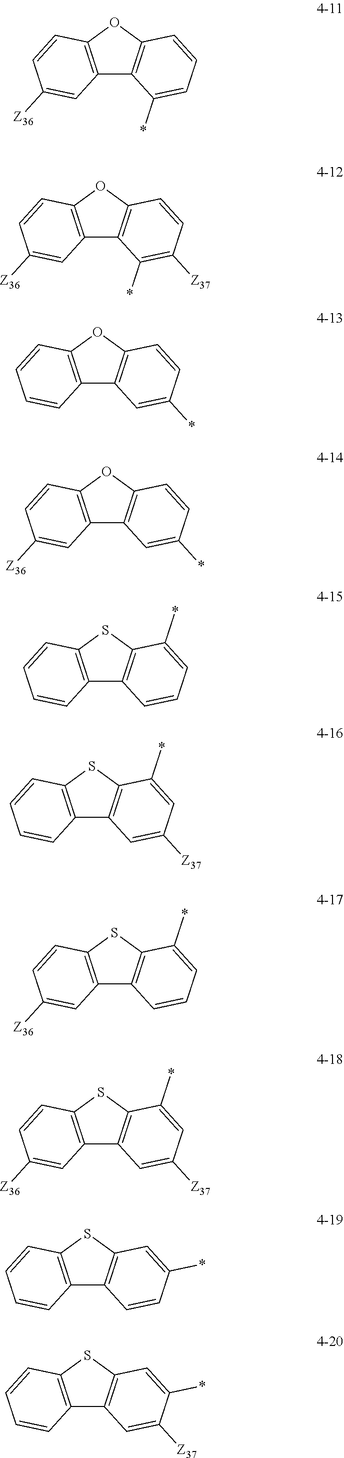 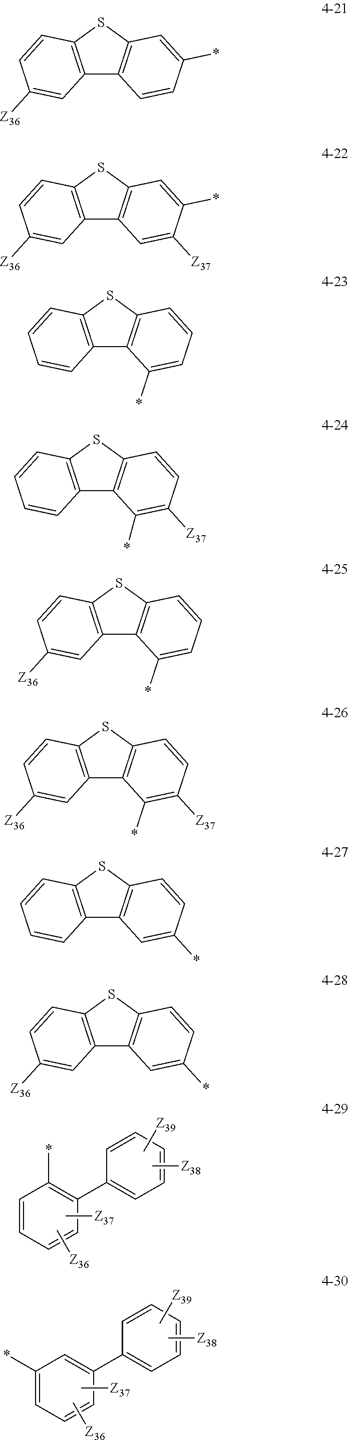 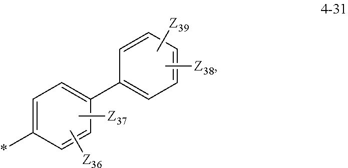
wherein, in Formulae 4-1 to 4-31,
Z₃₆ to Z₃₉ are each independently:
a hydrogen, a deuterium, a C₁-C₁₀ alkyl group, or a C₁-C₁₀ alkoxy group; or
a phenyl group, a biphenyl group, a terphenyl group, a tetraphenyl group, a fluorenyl group, a dibenzocarbazolyl group, a dibenzofuranyl group, a dibenzothiophenyl group, a carbazolyl group, a dibenzosilolyl group, an indenocarbazolyl group, an indolocarbazolyl group, a benzofurocarbazolyl group, a benzothienocarbazolyl group, a benzosilolocarbazolyl group, an acridinyl group, or a dihydroacridinyl group, each unsubstituted or substituted with a deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₁₀ alkyl)phenyl group, or a combination thereof wherein Z₃₆ and Z₃₇ in Formulae 4-1 to 4-28 are not hydrogen, and
*indicates a binding site to L₂ or ring A₁₁ in Formula 1.

8. The organic light-emitting device of claim 1, wherein
the thermally activated delayed fluorescence emitter comprises a compound represented by Formulae 1-1 to 1-5: 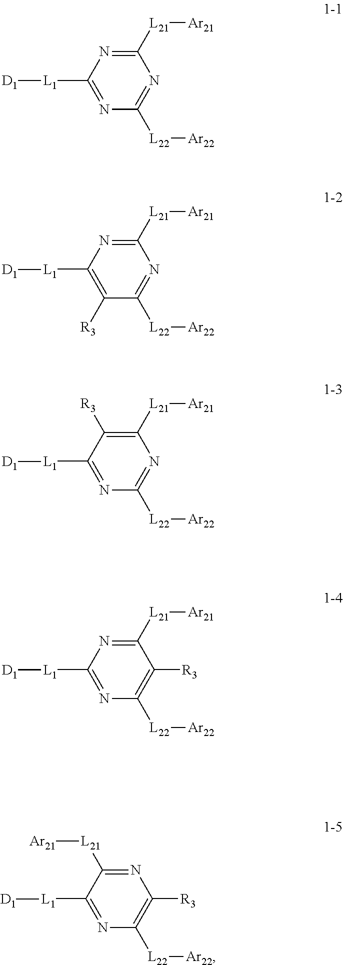
wherein, in Formulae 1-1 to 1-5,
L₁, D₁, and R₃ are each independently the same as described in claim 1,
L₁₁ and L₁₂ are each independently the same as described in connection with L₁ in claim 1,
D₁₁ and D₁₂ are each independently the same as described in connection with D₁ in claim 1,
L₂₁ and L₂₂ are each independently the same as described in connection with L₂ in claim 1, and
Ar₂₁ and Ar₂₂ are each independently the same as described in connection with Are in claim 1.

9. The organic light-emitting device of claim 1, wherein
a difference between a triplet energy level of the thermally activated delayed fluorescence emitter and a singlet energy level of the thermally activated delayed fluorescence emitter is in a range of about 0 eV to about 0.5 eV, and
the triplet energy level and the singlet energy level are evaluated by using a density functional theory method of a Gaussian program structurally optimized at a level of B3LYP/6-31G(d,p).

10. The organic light-emitting device of claim 1, wherein
the host consists of one compound.

11. The organic light-emitting device of claim 1, wherein
the host is a mixture of different two or more compounds.

12. The organic light-emitting device of claim 1, wherein
the host comprises a first material, a second material, or a combination thereof,
the first material is different from the second material,
the first material comprises a π electron-rich cyclic group, and does not comprise an electron-transporting moiety,
the second material comprises a π electron-rich cyclic group or an electron-transporting moiety, and
the electron-transporting moiety is a cyano group, a π electron-deficient nitrogen-containing cyclic group, or a group represented by one of the following formulae: 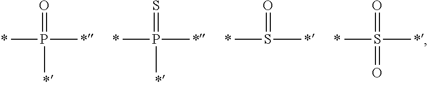
wherein *, *′, and *″ in the formulae each indicate a binding site to a neighboring atom.

13. The organic light-emitting device of claim 12, wherein
i) the host consists of one compound in the first material,
ii) the host is a mixture of at least two different compounds in the first material,
iii) the host consists of one compound in the second material,
iv) the host is a mixture of at least two different compounds in the second material, or
v) the host is a mixture of at least one compound in the first material and at least one compound in the second material.

14. The organic light-emitting device of claim 12, wherein
the first material comprises a cyano group-free phenyl group and a cyano group-free carbazole group, and
the second material comprises a cyano group-containing benzene group, a cyano group-containing carbazole group, or a combination thereof.

15. The organic light-emitting device of claim 12, wherein
the first material comprises a compound represented by Formula H-1(1), a compound represented by Formula H-1(2), a compound represented by Formula H-1(3), or a combination thereof: 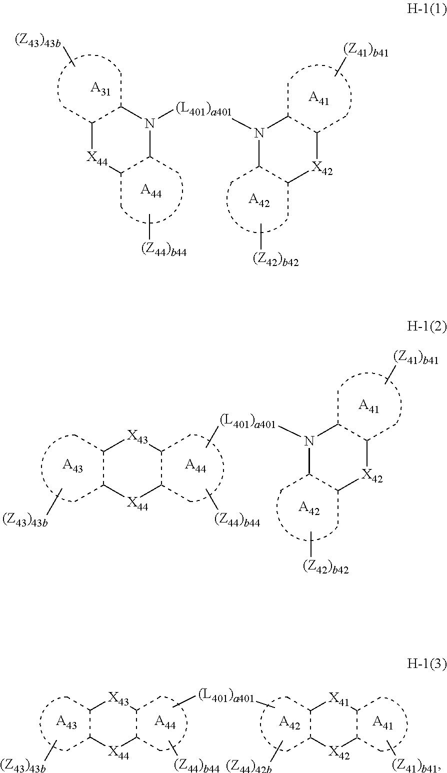
wherein, in Formulae H-1(1) to H-1(3),
rings A₄₁ to A₄₄ are each independently a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group,
X₄₁ is N-[(L₄₁₁)_{c411}-Z₄₁₁], C(Z₄₁₅)(Z₄₁₆), O, or S,
X₄₂ is a single bond, N-[(L₄₁₂)_{c412}-Z₄₁₂], C(Z₄₁₇)(Z₄₁₈), O, or S,
X₄₃ is N-[(L₄₁₃)_{c413}-Z₄₁₃], C(Z₄₁₉)(Z₄₂₀), O, or S,
X₄₄ is a single bond, N-[(L₄₁₄)_{c414}-Z₄₁₄], C(Z₄₂₁)(Z₄₂₂), O, or S,
L₄₀₁ and L₄₁₁ to L₄₁₄ are each independently:
a single bond; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₄₀₁)(Q₄₀₂)(Q₄₀₃), or a combination thereof,
a401 and c411 to c414 are each independently an integer from 1 to 10, wherein, when a401 is two or more, two or more L₄₀₁ are identical to or different from each other, when c411 is two or more, two or more L₄₁₁ are identical to or different from each other, when c412 is two or more, two or more L₄₁₂ are identical to or different from each other, when c413 is two or more, two or more L₄₁₃ are identical to or different from each other, and when c414 is two or more, two or more L₄₁₄ are identical to or different from each other,
Z₄₁ to Z₄₄ and Z₄₁₁ to Z₄₂₂ are each independently:
a hydrogen, a deuterium, a C₁-C₂₀ alkyl group, or a C₁-C₂₀ alkoxy group; or
a π electron-rich cyclic group unsubstituted or substituted with a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a tetraphenyl group, a (C₁-C₂₀ alkyl)phenyl group, —Si(Q₄₀₁)(Q₄₀₂)(Q₄₀₃) or a combination thereof,
b41 to b44 are each independently 1, 2, 3, or 4, and
Q₄₀₁ to Q₄₀₃ are each independently a hydrogen, a deuterium, a C₁-C₂₀ alkyl group, a C₁-C₂₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, or a tetraphenyl group.

16. The organic light-emitting device of claim 12, wherein
the second material comprises at least one cyano group.

17. The organic light-emitting device of claim 12, wherein
the second material comprises a benzene moiety substituted with at least one cyano group, and
the benzene moiety substituted with the at least one cyano group is not condensed with a neighboring ring, but is linked to a neighboring ring via a single bond.

18. The organic light-emitting device of claim 12, wherein
the second material comprises a compound represented by Formula E-1(1), a compound represented by Formula E-1 (2), a compound represented by Formula E-1(3), or a combination thereof: 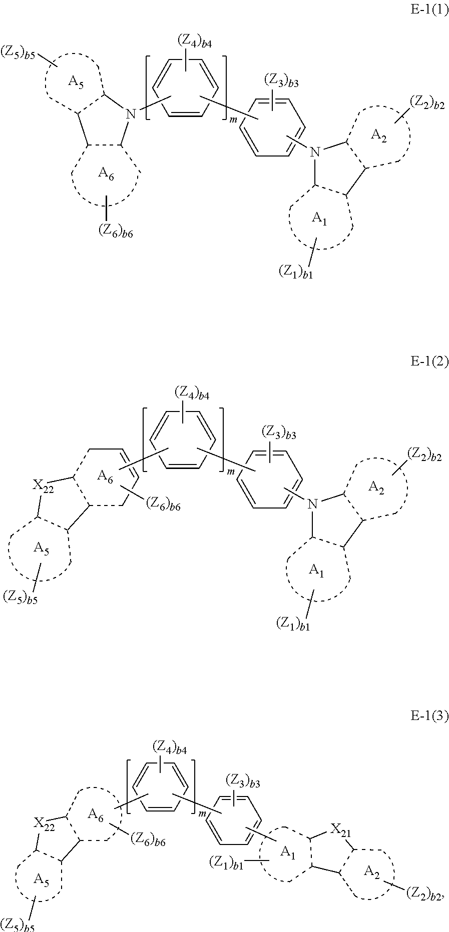
wherein, in Formulae E-1(1) to E-1(3),
rings A₁, A₂, A₅, and A₆ are each independently a benzene group, a naphthalene group, an anthracene group, a phenanthrene group, a triphenylene group, a pyrene group, a chrysene group, a cyclopentadiene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, or a phenanthroline group,
Z₁ to Z₆ are each independently:
a hydrogen, a deuterium, or a cyano group; or
a C₁-C₂₀ alkyl group, a phenyl group, a biphenyl group, a terphenyl group, a dibenzofuranyl group, or a dibenzothiophenyl group, each unsubstituted or substituted with deuterium, a cyano group, a C₁-C₂₀ alkyl group, a phenyl group, a biphenyl group, or a combination thereof,
b1 to b6 are each independently 1, 2, or 3,
wherein Z₁, Z₂, Z₃, Z₄, Z₅, R₆, or a combination thereof is a cyano group,
X₂₁ and X₂₂ are each independently O or S, and
m is 0 or 1.

19. The organic light-emitting device of claim 18, wherein,
in Formulae E-1(1) to E-1(3),
Z₁, Z₂, or a combination thereof is a cyano group,
Z₃, Z₄, or a combination thereof is a cyano group,
Z₅, Z₆, or a combination thereof is a cyano group,
Z₁, Z₂, or a combination thereof is a cyano group, and Z₃, Z₄, or a combination thereof is a cyano group,
Z₁, Z₂, or a combination thereof is a cyano group, and Z₅, Z₆, or a combination thereof is a cyano group,
Z₃, Z₄, or a combination thereof is a cyano group, and Z₅, Z₆, or a combination thereof is a cyano group, or
Z₁, Z₂, or a combination thereof is a cyano group, Z₃, Z₄, or a combination thereof is a cyano group, and Z₅, Z₆, or a combination thereof is a cyano group.

20. The organic light-emitting device of claim 1, wherein an amount of the thermally activated delayed fluorescence emitter is in a range of about 0.01 parts by weight to about 30 parts by weight based on 100 parts by weight of the host.
